(19) United States
(12) Patent Application Publication
(10) Pub. No.: US 2020/0063254 A1
(43) Pub. Date: Feb. 27, 2020

(54) HEATING ASSEMBLY

(71) Applicant: FINEVA. INC., Daejeon (KR)

(72) Inventor: Jung Hyung Kim, Daejeon (KR)

(21) Appl. No.: 16/466,240

(22) PCT Filed: Dec. 1, 2017
(86) PCT No.: PCT/KR17/14042

§ 371 Date: Jun. 3, 2019

(30) Foreign Application Priority Data
Dec. 1, 2016 (KR) 10-2016-0163081
Dec. 1, 2016 (KR) 10-2016-0163082
Dec. 1, 2016 (KR) 10-2016-0163083
Dec. 1, 2016 (KR) 10-2016-0163084
Mar. 24, 2017 (KR) 10-2017-0037876

(51) Int. Cl. C23C 14/26; C23C 14/24; C23C 14/54

(52) U.S. Cl. CPC C23C 14/26; C23C 14/54; C23C 14/243

(57) ABSTRACT

The present invention relates to a heating assembly, and a heating assembly for a deposition apparatus is provided, the heating assembly comprising: a crucible having a space, which is configured to accommodate a deposition material, formed therein and in which at least one or more nozzles configured to guide the deposition material to an outside are implemented, a coil disposed at an outer side of the crucible and around which a dynamic magnetic field is formed according to a flow of a coil current corresponding to high-frequency power applied to the coil, and a magnetic field focusing member disposed around the coil, wherein an induction current is formed at an outer wall of the crucible due to the dynamic magnetic field, and the crucible is heated by heat generated based on the induction current and an electrical resistance element of the crucible, and the dynamic magnetic field formed around the coil is focused by the magnetic field focusing member so that a quantity of heat generated in the crucible increases.

### TECHNICAL FIELD

The present invention relates to a heating assembly, and more particularly, to a heating assembly capable of focusing a magnetic field that inductively heats a crucible, thereby controlling a heat distribution in the crucible and improving the actual deposition efficiency.

### BACKGROUND ART

A crucible is a kind of container in which a space capable of containing a substance to be heated by a heating means is formed therein. The crucible is implemented so that, even when the crucible is heated by a heating means and reaches a high temperature, the crucible can withstand the high temperature. The quantity of heat that the crucible has due to being heated may be transferred to the substance contained in the crucible. Accordingly, the substance may be heated.

Such crucibles have been utilized in many ways for heating substances which have to be heated at high temperatures. The crucible has been used as a means of heating and refining a metal having a high melting temperature, a means of heating various metal materials in order to blend the metal materials, and the like. Particularly, in recent years, the crucible has been used as a means of, in the production of a panel for a display device or the like, heating a deposition material, which is to be deposited on a surface of the panel, to change a phase of the deposition material such that the deposition material is movable and guiding the deposition material to the surface of the panel.

However, when the deposition material contained in the crucible is heated to deposit the deposition material on a deposition target surface (or a target surface) such as a panel, the actual deposition efficiency at which a deposition material can be properly formed on the deposition target surface may be important. Therefore, in recent years, there has been a growing demand for an implementation technique of a crucible capable of improving the actual deposition efficiency.

### DISCLOSURE

### Technical Problem

The present invention is directed to providing a heating assembly in which thermal energy transferred to a deposition material placed in a crucible is high relative to energy supplied to a heating means for heating the crucible.

The present invention is also directed to providing a heating assembly capable of controlling a heat distribution in a crucible so that a deposition material is uniformly formed on a deposition target surface.

It should be noted that objects of the present invention are not limited to the above-described objects, and other unmentioned objects of the present invention will be clearly understood by those of ordinary skill in the art to which the present invention pertains from the present specification and the accompanying drawings.

### Technical Solution

According to an aspect of the present invention, a heating assembly for a deposition apparatus is provided, the heating assembly comprising: a crucible having a space, which is configured to accommodate a deposition material, formed therein and in which at least one or more nozzles configured to guide the deposition material to an outside are implemented, a coil disposed at an outer side of the crucible and around which a dynamic magnetic field is formed according to a flow of a coil current corresponding to high-frequency power applied to the coil, and a magnetic field focusing member disposed around the coil, wherein an induction current is formed at an outer wall of the crucible due to the dynamic magnetic field, and the crucible is heated by heat generated based on the induction current and an electrical resistance element of the crucible, and the dynamic magnetic field formed around the coil is focused by the magnetic field focusing member so that a quantity of heat generated in the crucible increases.

According to another aspect of the present invention, a heating assembly for a deposition apparatus is provided, the heating assembly comprising: a housing having a space formed therein; a crucible having a space, which is configured to accommodate a deposition material, formed therein and in which at least one or more nozzles configured to guide the deposition material to an outside are implemented; a coil disposed at an outer side of the crucible and around which a dynamic magnetic field is formed according to a flow of a coil current corresponding to high-frequency power applied to the coil; and a magnetic field focusing member disposed around the coil, wherein the crucible, the coil, and the magnetic field focusing member are disposed in an inner space of the housing, an induction current is formed at an outer wall of the crucible due to the dynamic magnetic field, and the crucible is heated by heat generated based on the induction current and an electrical resistance element of the crucible, and the dynamic magnetic field formed around the coil is focused by the magnetic field focusing member so that a quantity of heat generated in the crucible increases.

According to still another aspect of the present invention, an intensity distribution of an induction current which is induced to an outer wall of a crucible may be appropriately controlled so that a spatial distribution of a quantity of heat provided to a deposition material accommodated in an inner space of the crucible may be controlled to a predetermined distribution. For example, when a horizontal direction and a vertical direction are defined with respect to one heating surface of four heating surfaces of the crucible, the distribution of the induction current with respect to the one heating surface may be appropriately controlled in the horizontal direction or appropriately controlled in the vertical direction.

It should be noted that means for achieving the above objects of the present invention are not limited to the above-described means, and other unmentioned means will be clearly understood by those of ordinary skill in the art to which the present invention pertains from the present specification and the accompanying drawings.

### Advantageous Effects

According to the present invention, thermal energy transferred to a deposition material placed in a crucible can become high relative to energy supplied to a heating means for heating the crucible.

According to the present invention, it is possible to control a heat distribution in a crucible so that a deposition material is uniformly formed on a deposition target surface.

It should be noted that advantageous effects of the present invention are not limited to the above-described advantageous effects, and other unmentioned advantageous effects of the present invention will be clearly understood by those of ordinary skill in the art to which the present invention pertains from the present specification and the accompanying drawings.

### DESCRIPTION OF DRAWINGS

FIG. 1 is a block diagram illustrating a configuration of a deposition apparatus according to an embodiment of the present application.

FIG. 2 is a view illustrating a crucible according to an embodiment of the present application.

FIG. 3 is a view illustrating a protruding nozzle formed in the crucible according to an embodiment of the present application.

FIG. 4 is a view illustrating the shape of a coil according to an embodiment of the present application.

FIG. 5 is a view illustrating a crucible and a coil according to an embodiment of the present application.

FIG. 6 is a view illustrating an example in which a coil according to an embodiment of the present application is implemented.

FIG. 7 is a view illustrating a coil disposed in the vicinity of a protruding nozzle according to an embodiment of the present application.

FIG. 8 is a conceptual diagram illustrating a magnetic field generated by a coil according to an embodiment of the present application.

FIG. 9 is a conceptual diagram illustrating a magnetic field formed around a coil and a crucible according to an embodiment of the present application.

FIG. 10 is a view illustrating a ferrite placed in a magnetic field according to an embodiment of the present application.

FIG. 11 is a view illustrating a ferrite, a coil, and a magnetic field formed around a coil according to an embodiment of the present application.

FIG. 12 is a view illustrating a ferrite disposed in a heating assembly according to an embodiment of the present application.

FIG. 13 is a graph showing a distribution of intensity change values of a magnetic field according to an embodiment of the present application.

FIG. 14 is a cut side view illustrating a ferrite included in an outer wall of a crucible according to an embodiment of the present application.

FIG. 15 is a view illustrating a shape implemented by applying a ferrite to a deposition apparatus according to an embodiment of the present application.

FIG. 16 is a schematic diagram illustrating a heat distribution in a crucible according to an embodiment of the present application.

FIG. 17 is a schematic diagram illustrating a heat distribution in a crucible according to an embodiment of the present application.

FIG. 18 is a cut side view illustrating an example in which the shape of a crucible is varied according to an embodiment of the present application.

FIG. 19 is a cut side view illustrating examples in which a thickness of a crucible is varied according to an embodiment of the present application.

FIG. 20 is a view illustrating a coil formed at an outer side of a crucible according to an embodiment of the present application.

FIG. 21 is a view illustrating a coil formed at an outer side of a crucible according to an embodiment of the present application.

FIG. 22 is a conceptual diagram illustrating an example in which a coil implemented in a deposition apparatus is separately driven according to an embodiment of the present application.

FIG. 23 is a view conceptually illustrating a heat distribution in a crucible according to an embodiment of the present invention.

FIG. 24 is a view illustrating a ferrite inserted between coils according to an embodiment of the present application.

FIG. 25 is a view illustrating various shapes of a ferrite according to an embodiment of the present application.

FIG. 26 is a view illustrating a ferrite disposed in a form of covering a lower surface of a crucible according to an embodiment of the present application.

FIG. 27 is a view illustrating the shape of a ferrite according to an embodiment of the present application.

FIG. 28 is a cut side view illustrating a ferrite included in an outer wall of a crucible according to an embodiment of the present application.

FIG. 29 is a view illustrating a ferrite applied to a heating assembly according to an embodiment of the present application.

FIG. 30 is a view illustrating a state in which a ferrite is formed in a portion located near a nozzle of a crucible according to an embodiment of the present application.

FIG. 31 is a view illustrating a side surface of a crucible according to an embodiment of the present application.

FIG. 32 is a view related to design of a heating assembly in the Y-axis direction according to an embodiment of the present application.

FIG. 33 is a view related to design of a heating assembly in the Y-axis direction according to an embodiment of the present application.

FIG. 34 is a view related to design of a heating assembly in the Y-axis direction according to an embodiment of the present application.

FIG. 35 is a view related to design of a heating assembly in the Y-axis direction according to an embodiment of the present application.

FIG. 36 is a view illustrating a heating assembly implemented by combining embodiments in the Z-direction of a crucible according to an embodiment of the present application.

FIG. 37 is a view illustrating a heating assembly implemented by combining embodiments in the X-, Y-, and Z-directions of a crucible according to an embodiment of the present application.

FIG. 38 is a view illustrating a heat distribution in a crucible according to an embodiment of the present application.

FIG. 39 is a view illustrating a heat distribution in a crucible that is changed over time according to an embodiment of the present application.

FIG. 40 is a view illustrating a heating assembly in which a heat conduction suppressing element is formed according to an embodiment of the present application.

FIG. 41 is a graph showing controlled thermal equilibrium according to an embodiment of the present application.

FIG. 42 is a view illustrating a transformer, an input wire, and an output wire in an outer space according to an embodiment of the present application.

FIG. 43 is a view illustrating a moving heating assembly according to an embodiment of the present application.

FIG. 44 is a view illustrating a transformer, a vacuum box, and a heating assembly according to an embodiment of the present application.

FIG. 45 is a view illustrating a deposition apparatus according to an embodiment of the present application.

FIG. 46 is a view illustrating a deposition apparatus according to an embodiment of the present application.

FIG. 47 is a block diagram illustrating a configuration of a deposition apparatus according to an embodiment of the present application.

FIG. 48 is a view illustrating a crucible according to an embodiment of the present application.

FIG. 49 is a view illustrating a protruding nozzle formed in a crucible according to an embodiment of the present application.

FIG. 50 is a view illustrating a shape of a coil according to an embodiment of the present application.

FIG. 51 is a view illustrating a crucible and a coil according to an embodiment of the present application.

FIG. 52 is a view illustrating an example in which a coil is implemented according to an embodiment of the present application.

FIG. 53 is a view illustrating a coil disposed in the vicinity of a protruding nozzle according to an embodiment of the present application.

FIG. 58 is a conceptual diagram illustrating a magnetic field generated by a coil according to an embodiment of the present application.

FIG. 59 is a conceptual diagram illustrating a magnetic field formed in a coil and a crucible according to an embodiment of the present application.

FIG. 60 is a view illustrating a ferrite placed in a magnetic field according to an embodiment of the present application.

FIG. 61 is a view illustrating a ferrite, a coil, and a magnetic field formed around a coil according to an embodiment of the present application.

FIG. 62 is a view illustrating a ferrite disposed in a heating assembly according to an embodiment of the present application.

FIG. 63 is a graph showing a distribution of intensity change values of a magnetic field according to an embodiment of the present application.

FIG. 64 is a cut side view illustrating a ferrite included in an outer wall of a crucible according to an embodiment of the present application.

FIG. 65 is a view illustrating a shape implemented by applying a ferrite to a deposition apparatus according to an embodiment of the present application.

FIG. 66 is a schematic diagram illustrating a heat distribution in a crucible according to an embodiment of the present application.

FIG. 67 is a schematic diagram illustrating a heat distribution in a crucible according to an embodiment of the present application.

FIG. 68 is a cut side view illustrating an example in which the shape of a crucible is varied according to an embodiment of the present application.

FIG. 69 is a cut side view illustrating examples in which a thickness of a crucible is varied according to an embodiment of the present application.

FIG. 70 is a view illustrating a coil formed at an outer side of a crucible according to an embodiment of the present application.

FIG. 71 is a view illustrating a coil formed at an outer side of a crucible according to an embodiment of the present application.

FIG. 72 is a conceptual diagram illustrating an example in which a coil implemented in a deposition apparatus is separately driven according to an embodiment of the present application.

FIG. 73 is a view conceptually illustrating a heat distribution in a crucible according to an embodiment of the present invention.

FIG. 74 is a view illustrating a ferrite inserted between coils according to an embodiment of the present application.

FIG. 75 is a view illustrating various shapes of a ferrite according to an embodiment of the present application.

FIG. 76 is a view illustrating a ferrite disposed in a form of covering a lower surface of a crucible according to an embodiment of the present application.

FIG. 77 is a view illustrating a shape of a ferrite according to an embodiment of the present application.

FIG. 78 is a cut side view illustrating a ferrite included in an outer wall of a crucible according to an embodiment of the present application.

FIG. 79 is a view illustrating a ferrite applied to a heating assembly according to an embodiment of the present application.

FIG. 80 is a view illustrating a state in which a ferrite is formed in a portion located near a nozzle of a crucible according to an embodiment of the present application.

FIG. 81 is a view illustrating a side surface of a crucible according to an embodiment of the present application.

FIG. 82 is a view related to design of a heating assembly in the Y-axis direction according to an embodiment of the present application.

FIG. 83 is a view related to design of a heating assembly in the Y-axis direction according to an embodiment of the present application.

FIG. 84 is a view related to design of a heating assembly in the Y-axis direction according to an embodiment of the present application.

FIG. 85 is a view related to design of a heating assembly in the Y-axis direction according to an embodiment of the present application.

FIG. 86 is a view illustrating a heating assembly implemented by combining embodiments in the Z-direction of a crucible according to an embodiment of the present application.

FIG. 87 is a view illustrating a heating assembly implemented by combining embodiments in the X-, Y-, and Z-directions of a crucible according to an embodiment of the present application.

FIG. 88 is a view illustrating a heat distribution in a crucible according to an embodiment of the present application.

FIG. 89 is a view illustrating a heat distribution in a crucible that is changed over time according to an embodiment of the present application.

FIG. 90 is a view illustrating a heating assembly in which a heat conduction suppressing element is formed according to an embodiment of the present application.

FIG. 91 is a graph showing controlled thermal equilibrium according to an embodiment of the present application.

FIG. 92 is a view illustrating a transformer, an input wire, and an output wire in an outer space according to an embodiment of the present application.

FIG. 93 is a view illustrating a moving heating assembly according to an embodiment of the present application.

FIG. 94 is a view illustrating a transformer, a vacuum box, and a heating assembly according to an embodiment of the present application.

FIG. 95 is a view illustrating deposition apparatus according to an embodiment of the present application.

FIG. 96 is a view illustrating deposition apparatus according to an embodiment of the present application.

### MODES OF THE INVENTION

Because embodiments described herein are for clearly describing the idea of the present invention to one of ordinary skill in the art to which the present invention pertains, the present invention is not limited by the embodiments described herein, and the scope of the present invention should be construed as including modifications that do not depart from the idea of the present invention.

Terms used herein are currently widely used general terms that are selected in consideration of functions in the present invention, but the terms may vary depending on an intention and practice of one of ordinary skill in the art to which the present invention pertains or the advent of new technology. However, to the contrary, when a specific term is arbitrarily defined and used, a definition of the term will be separately given. Consequently, the terms used herein should be interpreted on the basis of substantial meanings thereof and entire content herein instead of being interpreted simply on the basis of the names of the terms.

The accompanying drawings are for facilitating description of the present invention. Because shapes illustrated in the drawings may be exaggerated as necessary to assist in understanding the present invention, the present invention is not limited by the drawings.

When detailed descriptions of known configurations or functions related to the present invention are deemed as having the possibility of blurring the gist of the present invention, the detailed descriptions thereof will be omitted as necessary.

According to an aspect of the present invention, a heating assembly for a deposition apparatus is provided, the heating assembly comprising: a crucible having a space, which is configured to accommodate a deposition material, formed therein and in which at least one or more nozzles configured to guide the deposition material to an outside are implemented, a coil disposed at an outer side of the crucible and around which a dynamic magnetic field is formed according to a flow of a coil current corresponding to high-frequency power applied to the coil, and a magnetic field focusing member disposed around the coil, wherein an induction current is formed at an outer wall of the crucible due to the dynamic magnetic field, and the crucible is heated by heat generated based on the induction current and an electrical resistance element of the crucible, and the dynamic magnetic field formed around the coil is focused by the magnetic field focusing member so that a quantity of heat generated in the crucible increases.

Also, the induction current formed at the outer wall of the crucible may change over time.

Also, a change amount of a magnetic flux density of the dynamic magnetic field may increase due to the magnetic field focusing member; and the increased quantity of heat in the crucible may be increased based on the increased change amount.

Also, an electric charge per unit time of the induction current may increase due to the magnetic field focusing member; and the increased quantity of heat in the crucible may be increased based on the increased electric charge per unit time.

Also, a change amount of a magnetic flux density of the dynamic magnetic field and an electric charge per unit time of the induction current may increase due to the magnetic field focusing member; and the increased quantity of heat in the crucible may be increased based on the increased change amount and the electric charge per unit time.

Also, the nozzle implemented in the crucible may have a form of protruding toward an outside of the crucible.

Also, the coil may be disposed so that a first coil and a second coil included in the coil are present at an outer side of the outer wall of the crucible.

Also, the heating assembly may be disposed inside a housing of the deposition apparatus.

Also, the magnetic field focusing member may be disposed in a space between the coil and an inner wall of the housing.

Also, the magnetic field focusing member may be implemented in a form of being applied.

Also, the magnetic field focusing member may be implemented in a plate shape, the magnetic field focusing member may include a first region and a second region, and a thickness of the first region of the magnetic field focusing member may be greater than a thickness of the second region thereof.

Also, a degree at which the dynamic magnetic field may be focused changes based on a thickness of the magnetic field focusing member.

Also, a region of the magnetic field focusing member may include a first region and a second region, and a distance between the first region and the housing may be greater than a distance between the second region and the housing.

Also, the magnetic field focusing member may include a first region and a second region, and the first region and the second region may be regions perpendicular to each other. According to another aspect of the present invention, a heating assembly for a deposition apparatus is provided, the heating assembly comprising: a housing having a space formed therein; a crucible having a space, which is configured to accommodate a deposition material, formed therein and in which at least one or more nozzles configured to guide the deposition material to an outside are implemented; a coil disposed at an outer side of the crucible and around which a dynamic magnetic field is formed according to a flow of a coil current corresponding to high-frequency power applied to the coil; and a magnetic field focusing member disposed around the coil, wherein the crucible, the coil, and the magnetic field focusing member are disposed in an inner space of the housing, an induction current is formed at an outer wall of the crucible due to the dynamic magnetic field, and the crucible is heated by heat generated based on the induction current and an electrical resistance element of the crucible, and the dynamic magnetic field formed around the coil is focused by the magnetic field focusing member so that a quantity of heat generated in the crucible increases.

Hereinafter, a heating assembly according to an embodiment of the present invention will be described.

Thin film manufacturing technology is a field of surface treatment technology and is classified into wet methods and dry methods.

Among the thin film manufacturing technologies, thin film manufacturing technologies using wet methods include: (1) an electrolytic method in which an object to be processed is electrolyzed by being placed at a positive electrode in order to oxidize the object to be processed so that a processing object is formed on a surface of the object to be processed; and (2) an electroless method using activation and sensitization processes on an object to be processed.

Thin film manufacturing technologies using dry methods include: (1) a physical vapor deposition (PVD) method in which a solid-phase processing object is evaporated in a high vacuum state so that the processing object is formed on a surface of an object to be processed; (2) a chemical vapor deposition (CVD) method in which a gas-phase processing object is changed to a plasma phase or the like in a high vacuum state so that the processing object is formed on a surface of an object to be processed; and (3) a spraying method in which a liquid-phase object to be processed is ejected to a surface of a processing object so that the object to be processed is coated on the surface of the processing object.

In the above-described thin film manufacturing technologies, a deposition apparatus 10000 which is implemented to heat a processing object (particularly, a deposition material) so that a phase of the processing object is changed and to guide the processing object to come into contact with a surface of an object to be processed may be important.

Therefore, a deposition apparatus 10000 according to the present invention will be described below.

<Heating Assembly with Improved Inducting Heating Efficiency Based on Magnetic Field Focusing Member>

### 1. Deposition Apparatus

Hereinafter, a deposition apparatus 10000 according to an embodiment of the present application will be described.

A deposition apparatus 10000 according to an embodiment of the present application is an apparatus capable of depositing a deposition material on a deposition target surface. A deposition apparatus 10000 according to the present application may increase a temperature of a crucible 13000 of a deposition apparatus 10000 using a predetermined heating means 15000 and change a phase of a deposition material contained in a crucible 13000. The phase-changed deposition material may be discharged to an outside of a crucible 13000.

A deposition apparatus 10000 according to an embodiment of the present application may be used for the above-described thin film manufacturing technologies. Furthermore, a deposition apparatus 10000 may also be used for simple heating instead of being used deposition according to the above-described thin film manufacturing technologies.

A configuration of a deposition apparatus 10000 will be described below.

1.1 Configuration of Deposition Apparatus

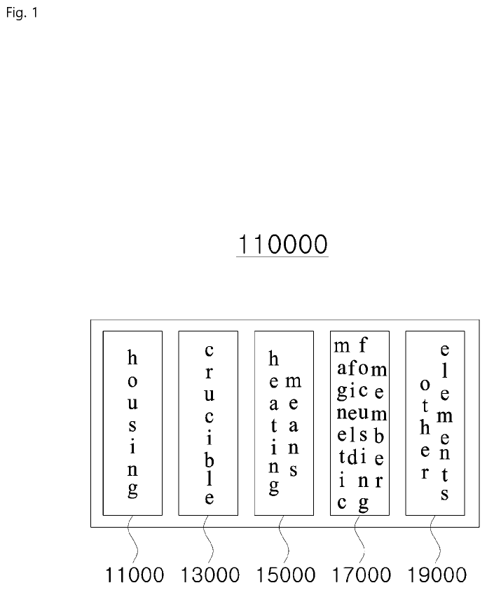

FIG. 1 is a block diagram illustrating a configuration of a deposition apparatus according to an embodiment of the present application.

Referring to FIG. 1, a deposition apparatus 10000 according to an embodiment of the present application may include a housing 11000, a crucible 13000, a heating means 15000, a magnetic field focusing member 17000, which is a heating aid, and other elements 19000.

A space may be formed inside the housing 11000 according to an embodiment of the present application. The crucible 13000, the heating means 15000, the heating aid, and the other elements 19000 may be implemented in the inner space of the housing 11000.

A deposition material, which is material to be deposited, may be provided in a space formed inside the crucible 13000 according to an embodiment of the present application. Also, the deposition material may be heated by receiving heat generated by the heating means 15000.

The heating means 15000 according to an embodiment of the present application may heat the crucible 13000 in order to change a phase of a deposition material placed inside the crucible 13000.

The heating aid according to an embodiment of the present application may aid the heating means 15000 in efficiently heating the crucible 13000. An example of the heating aid may include the magnetic field focusing member 17000.

The other elements 19000 according to an embodiment of the present application may include a passage of a conductive wire that is capable of supplying power, a power generation apparatus capable of providing power to the deposition apparatus 10000, or the like. However, in order to facilitate description, description on the other elements 19000 will be omitted herein. The deposition apparatus 10000 will be described along with the other elements 19000 only under special circumstances that require description of the deposition apparatus 10000 using the other elements 19000.

Meanwhile, the configurations of the aforementioned deposition apparatus 10000 including a crucible 13000, a heating means 15000, a magnetic field focusing member 17000, and/or other configurations that may be implemented may be collectively referred to as a heating assembly.

A heating assembly will be described in more detail below.

1.1.1 Crucible

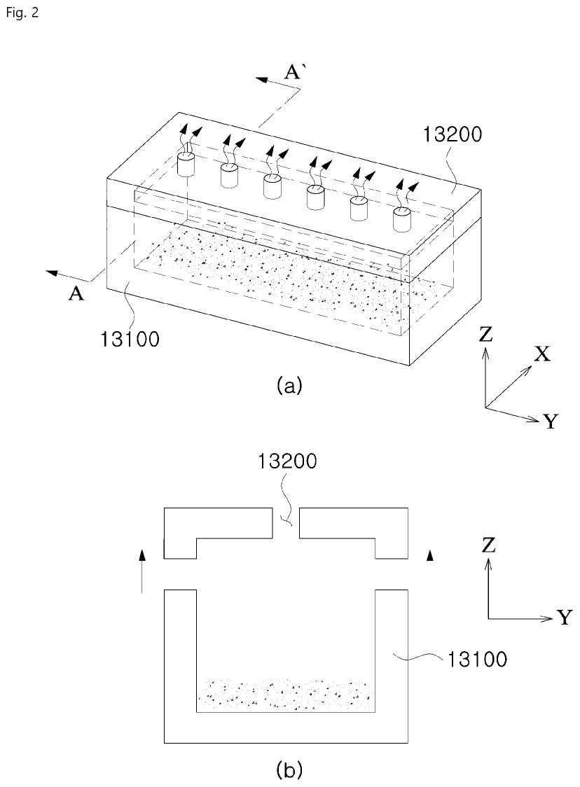

FIGS. 2(a) and 2(b) are views illustrating a crucible according to an embodiment of the present application.

A crucible 13000 according to an embodiment of the present application may include an outer wall 13100 and at least one or more nozzles 13200.

As illustrated in FIG. 2(b), an outer wall 13100 according to an embodiment of the present application may define a space inside a crucible 13000 (hereinafter referred to as “an inner space”). A deposition material to be deposited may be placed in the inner space.

A nozzle 13200 according to an embodiment of the present application may be a movement path of a deposition material. A deposition material placed in an inner space of the crucible 13000 may be phase-changed to a gas phase and/or a plasma phase by receiving a sufficient quantity of heat from a heating means 15000. The phase-changed deposition material may be discharged to an outside of a crucible 13000 via the nozzle 13200 as illustrated in FIG. 2(a).

The nozzle 13200 according to an embodiment of the present application may be formed with various design specifications in the crucible 13000.

For example, when a plurality of nozzles 13200 are formed, the plurality of nozzles 13200 may be formed at various intervals. The plurality of nozzles 13200 may be formed at equal intervals. Alternatively, the nozzles 13200 may be formed at intervals that gradually narrow toward a side of a surface of the crucible.

Also, a hole of the nozzle 13200 may have various shapes. The hole of the nozzle may be implemented in a circular shape as illustrated or may also be implemented in various other shapes such as quadrangular and elliptical.

Hereinafter, a crucible 13000 according to the present application will be described in more detail. In this case, for convenience of description, one surface on which the nozzle 13200 is formed will be referred to as an upper surface, a surface opposing the one surface will be referred to as a lower surface, and surfaces other than the upper surface and the lower surface will be referred to as “side surfaces.”

A crucible 13000 according to an embodiment of the present application may have various shapes. For example, referring to FIG. 2(a), a crucible 13000 may have a rectangular parallelepiped shape. Furthermore, a crucible 13000 according to the present application may be implemented in various other forms such as conical, spherical, hexagonal prismatic, cylindrical, and triangular prismatic. That is, a crucible 13000 according to an embodiment of the present application may be implemented in any form as long as the form is capable of containing a deposition material.

Also, according to an embodiment of the present application, various materials may be used in implementing the crucible.

The material of the crucible is not limited to any material, but preferably, the material constituting the crucible 3000 according to the present application may be a material having a property of allowing current to flow well therethrough.

Also, the material constituting the crucible 13000 may be selected in consideration of a temperature at which the crucible 13000 is heated by the heating means 15000. That is, the material of the crucible 13000 may be selected so that the crucible 13000 can function without melting even at a high temperature.

As illustrated in FIG. 2(b), in a crucible 13000 according to an embodiment of the present application, a structure capable of opening and closing a crucible 13000 may be formed.

A nozzle 13200 according to an embodiment of the present application may be implemented in a protruding shape that has a predetermined length toward an outside of the crucible 13000 (hereinafter referred to as “a protruding nozzle 13300”).

Such a protruding nozzle 13300 may be formed with various shapes and materials in the crucible 13000.

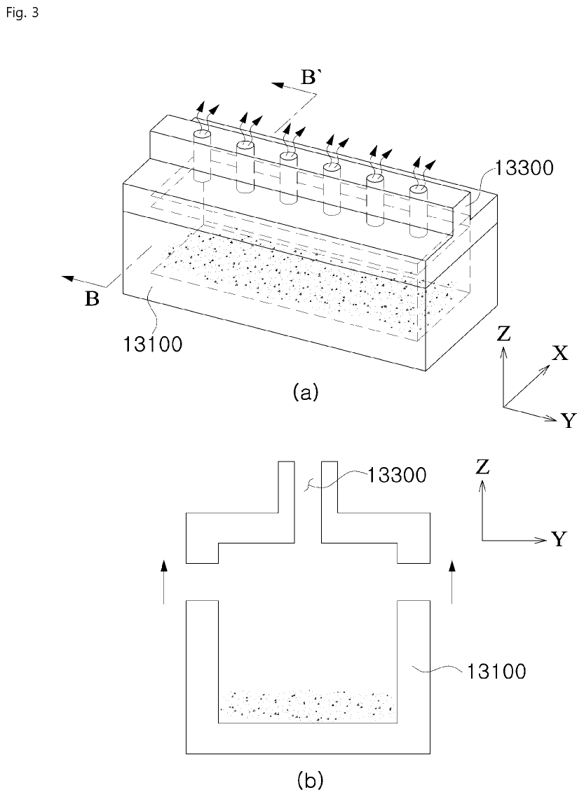

FIG. 3 is a view illustrating a protruding nozzle formed in a crucible according to an embodiment of the present application.

Referring to FIG. 3, as illustrated, the protruding nozzle 13300 may be formed in a rectangular parallelepiped shape. Also, for example, the shape of the protruding nozzle 13300 is not limited to the illustrated shape and may also be other shapes such as cylindrical, triangular prismatic, and conical.

Also, various materials may be selected to implement the protruding nozzle 13300. For example, the material of the protruding nozzle 13300 may be selected in consideration of the issue in which binding between the crucible 13000 and the protruding nozzle 13300 becomes unstable due to thermal expansion of the crucible 13000 upon heating of the crucible 13000. That is, the material of the protruding nozzle 13300 may be the same as that of the crucible 13000 so that the above issue does not occur since the materials of the protruding nozzle 13300 and the crucible 13000 have the same thermal expansion coefficient.

A heating assembly may be designed so that a deposition material is smoothly discharged via a protruding nozzle according to an embodiment of the present application.

For example, various materials may be selected as a material constituting a protruding nozzle according to an embodiment of the present application. A material having a property of low adhesiveness to the deposition material may be selected as a material constituting an inner surface of a passage of the protruding nozzle. Since adhesiveness between the passage of the protruding nozzle and the deposition material becomes low, a deposition material may move through the internal passage of a protruding nozzle without being adhered to a protruding nozzle and be smoothly discharged to the outside.

Also, a protruding nozzle according to an embodiment of the present application may be implemented in various shapes.

The internal passage of the protruding nozzle may have various shapes. For example, the internal passage of the protruding nozzle may be implemented to have a predetermined inclination.

1.1.2 Heating Means

A deposition apparatus 10000 according to an embodiment of the present application may include a heating means 15000 capable of increasing a temperature of a crucible 13000. The heating means 15000 may be implemented in various forms. For example, a heating means 15000 according to an embodiment of the present application may be: (1) a traditional heating means 15000 such as a pipe capable of supplying thermal vapor and a heating device using fossil fuels; or (2) the latest heating means 15000 such as a sputtering heating source that heats a target material through momentum transfer by ions or the like, an arc heating source that performs heating by an arc, and a resistance heating source that performs heating on the basis of an electrical resistance such as a conductive wire.

However, preferably, a coil 16000 may be selected as a heating means 15000 according to the present application. The coil 16000 may form therearound a dynamic magnetic field that varies temporally and spatially, on the basis of the high-frequency coil current flowing through a coil 16000. As a result, a magnetic field formed around the coil 16000 may induce current to a crucible 13000 and generate a quantity of heat in the crucible 13000, thereby heating the crucible 13000. An operation in which the crucible 16000 is heated by the coil will be described in detail below.

Hereinafter, a coil 16000 will be described in more detail.

The coil 16000 according to an embodiment of the present application may be implemented with various materials through which current may flow. For example, preferably, a conductor may be selected as a material constituting the coil 16000. The conductor may include a metal body, a semiconductor, a superconductor, a plasma, graphite, a conductive polymer, and the like. However, the material is not limited thereto, and various other materials may be selected as the material constituting the coil.

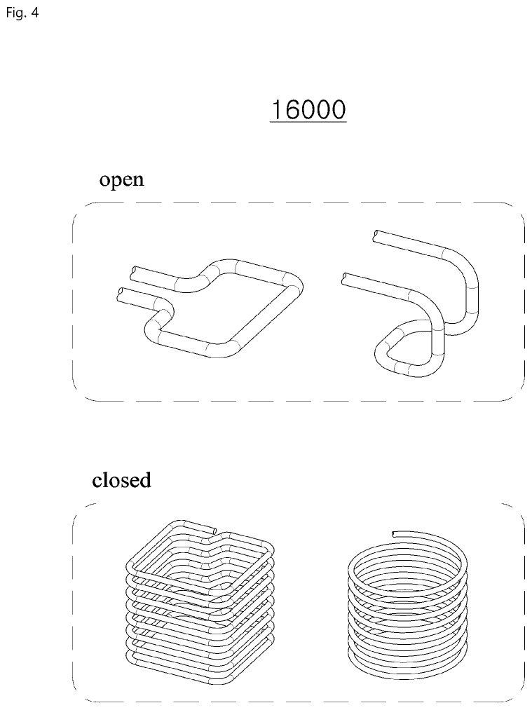

FIG. 4 is a view illustrating the shape of a coil according to an embodiment of the present application.

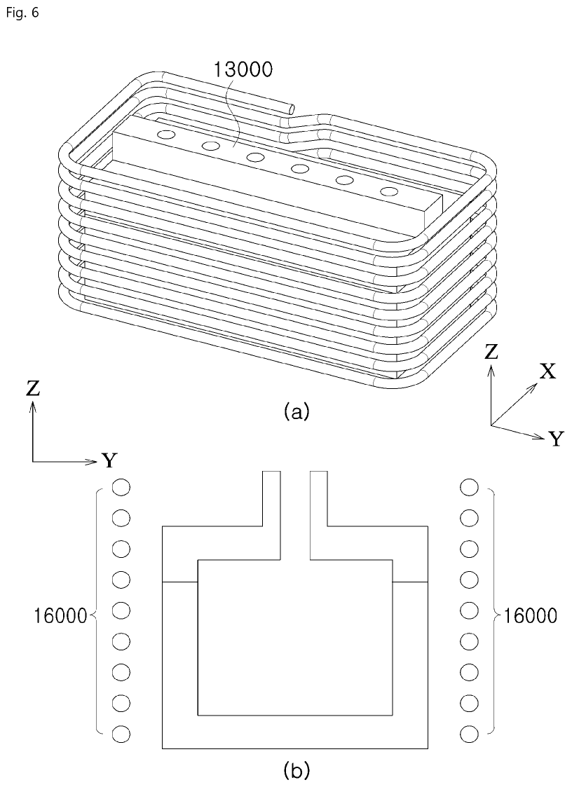

Referring to FIG. 4, a coil 16000 according to an embodiment of the present application may have various shapes. For example, the shape of the coil 16000 may include: (1) an open shape implemented as a single loop having a disc shape or a ring shape; and (2) a closed shape formed with a plurality of loops that constitute a hollow cylindrical shape. The shape of the coil 16000 is not limited to that illustrated in FIG. 6, and the coil 16000 may be implemented in any other shape as long as the shape is capable of generating a magnetic field.

Hereinafter, for convenience of description, a portion at which a plurality of windings constituting the coil 16000 are visible will be referred to as a side portion of a closed shape and a portion of a closed-shape coil 16000 that has a circular or quadrangular hole will be referred to as an upper portion or a lower portion of a coil 16000. The definitions related to the structure of a coil 16000 as described above may also apply to an open-shape coil 16000.

Windings through which current flows that constitute a coil 16000 according to an embodiment of the present application may have various forms. For example, a winding may be implemented in various outer shapes to have various shapes such as a round shape and a rectangular shape

Also, for example, the thickness of a winding may vary depending on the purpose.

Meanwhile, an empty space may be formed at an inner side of a winding constituting a coil 16000 according to an embodiment of the present application. For example, an empty space may be formed at an inner sides of a winding constituting the coil 16000 so that a fluid such as water that may serve as coolant flows through the empty space. The fluid flowing along the coil 16000 may have an effect of controlling a temperature of a coil 16000 so that the temperature does not rise above a predetermined temperature.

An aspect in which a coil 16000 according to an embodiment of the present application is disposed may vary depending on the shape of the coil.

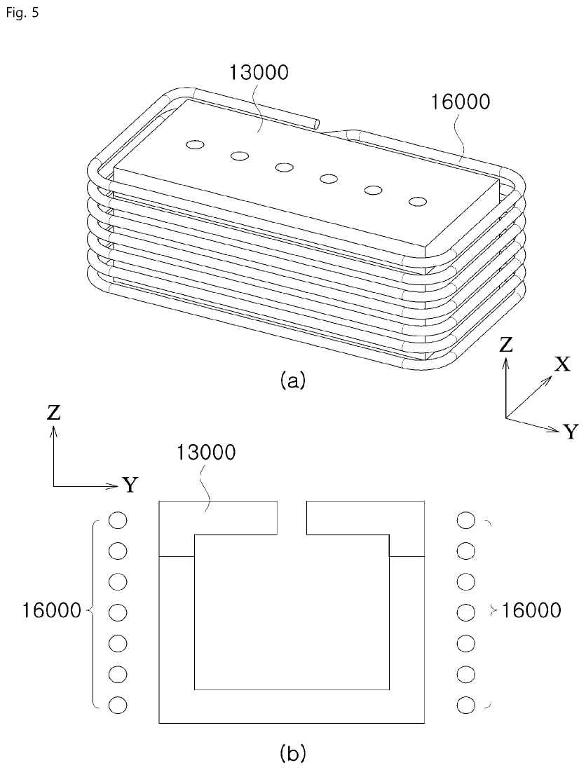

FIG. 5 is a view illustrating a crucible and a coil according to an embodiment of the present application.

Referring to FIG. 5, as one aspect in which a coil 16000 according to an embodiment of the present application is disposed, when the coil 16000 has a closed shape, the coil 16000 may be disposed so that the crucible 13000 is disposed at an inner side of the closed-shape coil 16000. Also, for example, other than the above-described disposition aspect, the closed-shape coil 16000 may be disposed so that an upper portion or a lower portion of the coil 16000 is disposed at an upper portion, a side portion, and/or a lower portion of the crucible 13000. Also, when the coil 16000 is the open-shape coil 16000, the above-described aspect in which the closed-shape coil 16000 is disposed may be applied, or, in the case of the open-shape coil 16000 formed of a single loop, the coil 16000 may be disposed in the crucible 13000 in the form in which the upper portion or the lower portion of the coil 16000 is folded.

Also, a coil 16000 according to an embodiment of the present application may be disposed corresponding to a structure and/or means in which the crucible 13000 is formed.

FIG. 6 is a view illustrating an example in which a coil according to an embodiment of the present application is implemented.

Referring to FIG. 6, when a nozzle 13200 is implemented to protrude from a crucible 13000, as illustrated, the coil 16000 may be disposed by being lifted up to a position corresponding to a protruding nozzle 13300. When the deposition material passing through the protruding nozzle 13300 is unable to receive a sufficient quantity of heat, the deposition material is unable to smoothly move through a passage of the protruding nozzle 13300. Therefore, when the coil is disposed around the protruding nozzle 13300 as described above, the coil 16000 may supply a sufficient quantity of heat so that the deposition material moving through the passage of the protruding nozzle 13300 can smoothly move to a deposition target surface.

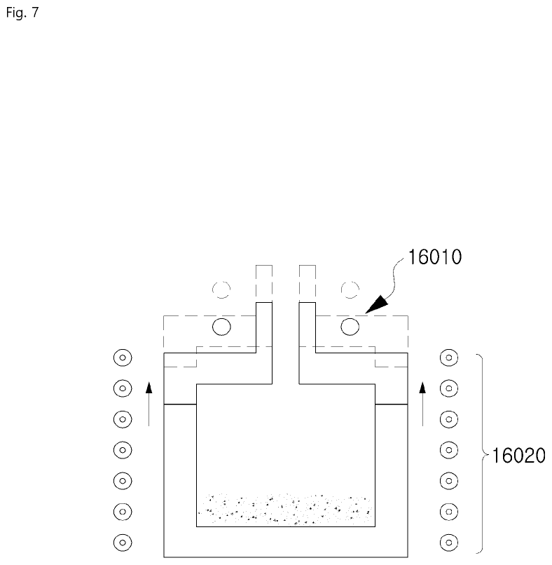

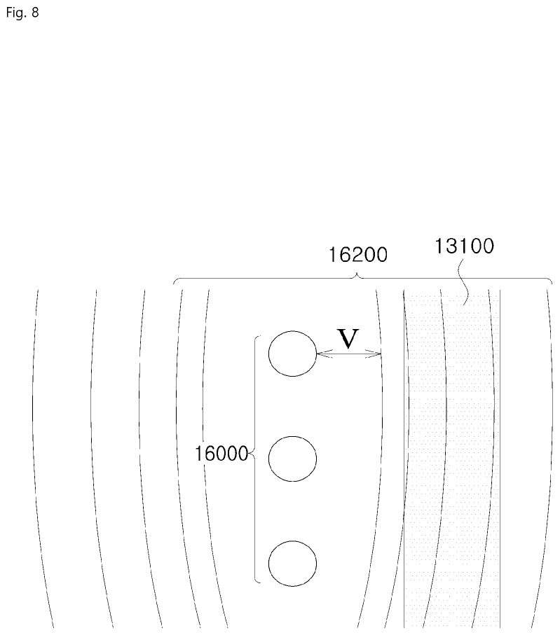

FIG. 7 is a view illustrating a coil disposed in the vicinity of a protruding nozzle according to an embodiment of the present application.

Referring to FIG. 7, a coil may be disposed in the vicinity of a protruding nozzle of a crucible according to an embodiment of the present application. A coil disposed in the vicinity of the protruding coil (hereinafter referred to as “a first coil”) may cause the quantity of heat generated in the protruding nozzle to be large so that a sufficient quantity of heat is supplied to a deposition material passing through a protruding nozzle. Accordingly, the deposition material may smoothly pass through the protruding nozzle. An attribute in which the quantity of heat generated in the protruding nozzle increases as the coil is disposed nearer to the protruding nozzle will be described in detail below.

Meanwhile, a coil disposed in the vicinity of the protruding nozzle may be separated from a coil disposed at a side surface of a crucible (hereinafter referred to as “a second coil”). That is, when the crucible is separated as illustrated in FIG. 7, the first coil and the second coil may be separated from each other.

Also, the above-described internal passage through which a fluid may flow may be formed at an inner portion of the second coil but not formed in the first coil. This may be to facilitate the separation between a first coil and a second coil.

Also, a power applied to a coil disposed in the vicinity of the nozzle and a power applied to a coil disposed at the side surface of the crucible may have the same attribute. For example, a power having the same attribute applied to the first coil and the second coil may be a power applied in parallel (hereinafter referred to as “a parallel power”). The parallel power may be connected to coils in the form in which a plurality of output wires output from a single power supply unit are present and each of the output wires is connected to each of coils. Also, a single output wire output from a power supply unit may be divided into a plurality of branches, and each of the branched pieces of the output wire may be connected to each of coils such that a power applied to the first coil and a power applied to the second coil are configured in parallel.

Alternatively, a power applied to coils may have different attributes. In such a case, the coils driven are referred to as separately driven coils. The separately driven coils will be described in detail below.

A variable power whose electrical attribute varies may be applied to a coil 16000 according to an embodiment of the present application. For example, such a variable power may be, preferably, high-frequency alternating-current (AC) power or, in some cases, may be low-frequency AC power.

As the above-described AC power is applied to a coil 16000, a current (hereinafter referred to as a coil current) may flow through a coil 16000 according to an embodiment of the present application. Electrical attribute of the coil current may include an intensity thereof, a direction thereof, or the like. Therefore, electrical attribute of the coil current may change corresponding to the AC power. An intensity, direction, or the like of the coil current may change every moment corresponding to the AC power.

According to an embodiment of the present application, a dynamic magnetic field is formed around a coil 16000, and the dynamic magnetic field forms an induction current in a crucible 13000 such that a quantity of heat is generated. Accordingly, as a result, the coil 16000 may inductively heat the crucible 13000. Hereinafter, attribute of a magnetic field formed by the coil 16000 according to an embodiment of the present application and attribute of an induction current formed in the crucible 13000 will be described.

1.1.2.1 Attributes of Magnetic Field

FIG. 8 is a conceptual diagram illustrating a magnetic field formed around a coil according to an embodiment of the present application.

Hereinafter, an intensity attribute of a magnetic field 16100 will be described.

An intensity attribute of a magnetic field 16100 according to an embodiment of the present application may satisfy the relation, B∝u₀·H (where B=magnetic flux density, u₀=magnetic permeability/proportional factor, H=intensity of magnetic field). In this case, according to magnetic permeability of a space in which the magnetic field 16100 is formed, an intensity value and a magnetic flux density value of the magnetic field 16100 may not match accurately. However, as can be seen from the relation, the intensity and the magnetic flux density of the magnetic field 16100 are proportional to each other. Therefore, on the basis of the proportional relationship, the magnetic flux density and the intensity of the magnetic field will be considered as substantially the same concept herein.

That is, even when not specifically mentioned in the description herein, the fact that the density of magnetic flux 16200 is high may mean that the intensity of the magnetic field is high, and the fact that the intensity of the magnetic field is high may mean that the density of magnetic flux is high.

Also, the intensity attribute of the magnetic field 16100 may change according to a distance relationship between the magnetic field 16100 and a place of origin of the magnetic field 16100. An amplitude attribute of the magnetic field 16100 may satisfy the relation,

$$H ∝ k \cdot \frac{I}{r}$$

(where H=intensity of magnetic field, k=proportional factor, I=current flowing through place of origin, r=distance from place of origin), which is a relation between the intensity of the magnetic field 16100 and the place of origin of the magnetic field 16100. According to the relation, the intensity of the magnetic field 16100 may decrease as the magnetic field 16100 is formed at a larger distance from the place of origin thereof. Specifically, the intensity of the magnetic field 16100 may decrease as the number of magnetic field lines passing through a predetermined area formed at a large distance from the place of origin decreases. Conversely, the intensity of the magnetic field 16100 may increase as the magnetic field 16100 is nearer to the coil 16000.

Hereinafter, a dynamic magnetic field formed around the coil 16000 according to an embodiment of the present application will be described.

Referring to FIG. 8, a magnetic field 16100 formed around a coil 16000 according to the present application may have a dynamic property.

For example, the direction and intensity attributes of the formed magnetic field 16100 according to the present application may suddenly change according to a time change in the time axis. According to the relation, \vec{H}∝\vec{I} (where H=intensity of magnetic field, I=coil current flowing through coil), the magnetic field 16100 formed around the coil 16000 may be dynamically formed corresponding to dynamic current flowing in the coil 16000 that suddenly changes according to time.

The dynamic magnetic field is a vector-related concept that includes not only the intensity attribute but also the direction attribute. Specifically, when one direction of a direction in which coil current flows along variable power applied to the coil 16000 is a positive (+) direction, the other direction opposite to the one direction may be a negative (−) direction. The direction of the coil current continuously changes from the positive (+) direction to the negative (−) direction and from the negative (−) direction to the positive (+) direction, and simultaneously, the intensity of the current also continuously changes. Therefore, as the direction of the coil current suddenly changes to the positive (+) direction or the negative (−) direction, the direction of the magnetic field 16100 may also suddenly change to the one direction or the other direction corresponding to the direction of the coil current. Also, simultaneously, the intensity attribute of the magnetic field 16100 may be set corresponding to an intensity attribute of the coil current.

As a result, as illustrated in FIG. 8, a dynamic magnetic field 16100 whose direction and intensity fluctuate may be formed around the coil 16000.

Hereinafter, an intensity change value of a dynamic magnetic field 16100 formed around the coil will be described.

The intensity change value of the dynamic magnetic field is a quantity-related concept. The intensity change value of the magnetic field is an intensity change amount of the magnetic field per unit time in which the direction of the magnetic field is taken into consideration. Specifically, while only the intensity change amount of the magnetic field is important for change values of magnetic fields formed in the same direction, change values of magnetic fields formed in different directions may be set according to the intensity change amount of the magnetic field in which the direction of the magnetic field is taken into consideration.

An intensity change value attribute of the dynamic magnetic field 16100 according to an embodiment of the present application may vary according to a distance thereof from the coil 16000. The above-described magnetic field 16100—forming attribute,

$$H ∝ k \cdot \frac{I}{r} ,$$

may apply to the intensity of the dynamic magnetic field 16100.

As the distance of the dynamic magnetic field 16100 from the coil 16000 becomes larger, the intensity of the magnetic field formed at the corresponding distance may become lower. Therefore, since a dynamic range of the intensity of the formed magnetic field also becomes smaller, the intensity change value of the magnetic field becomes smaller. On the other hand, as the distance of the dynamic magnetic field 16100 from the coil 16000 becomes smaller, the intensity change value of the dynamic magnetic field 16100 becomes larger.

Also, various shapes in which the coil 16000 is implemented may change the intensity change value of the dynamic magnetic field 16100. The intensity of the dynamic magnetic field 16100 may satisfy the relation, H∝N (where H=intensity of magnetic field, N=number of windings of coil per unit length). Accordingly, as the number of windings of the coil increases, the intensity of the magnetic field formed around the coil increases. As the intensity of the magnetic field increases, the intensity change value of the magnetic field also increases.

Attributes of an induction current induced to a crucible 13000 according to a magnetic field formed around a coil 16000 will be described below.

1.1.2.2 Attribute of Induction Current

A magnetic field formed according to an embodiment of the present application may form induction current in the crucible 13000.

For example, the formed induction current may satisfy the relation, \vec{F}=q\vec{v}×\vec{H} (where F=force acting on electrons of crucible, q=electric charge of electrons, v=velocity of electrons, H=intensity of magnetic field), which is a relation between electrons of the crucible 13000 and the magnetic field formed by the coil 16000. That is, an electrical force may be applied to the electrons of the crucible 13000 due to the dynamic magnetic field suddenly changing temporally and spatially that is generated by the coil 16000. As a result, the electrons move due to the electrical force such that induction current may be generated.

$$e ∝ \frac{d B}{dt}$$

Also, for example, the formed induction current may satisfy the relation, (where e=induced electromotive force, B=magnetic flux density, t=time), which is a relation between magnetic flux formed by the coil and an induced electromotive force generated in the crucible. That is, an induced electromotive force may be generated in the crucible 13000 due to the dynamic magnetic field generated by the coil 16000. The induction current may flow in the crucible 13000 according to the generated electromotive force.

According to an embodiment of the present application, a current path of an induction current may be formed in the crucible 13000.

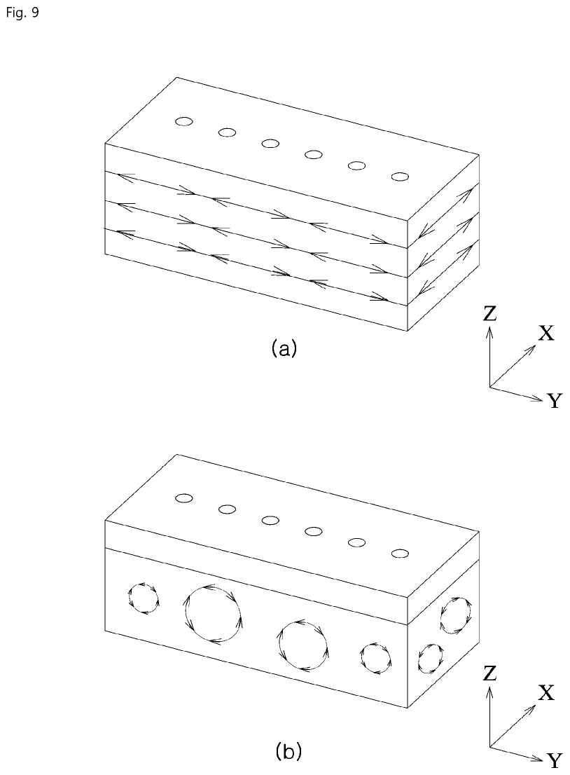

FIG. 9 is a conceptual diagram illustrating a magnetic field formed around a coil and a crucible according to an embodiment of the present application.

Referring to FIG. 9, a current path induced to the crucible 13000 according to an embodiment of the present application may be formed at the outer wall 13100 of the crucible 13000. Also, an example of a form of the induction current path may be a form of surrounding the outer wall 13100 of the crucible 13000. As another example of the form of the induction current path, a current path in a form of locally forming an eddy at the outer wall 13100 of the crucible 13000 may be formed.

Also, the crucible 13000 may have a current path having a form in which the above-described forms of paths are simultaneously combined. Furthermore, the form of the current path is not limited to those described above, and the current path may have various other forms corresponding to a change in the shape of the magnetic field generated by the coil 16000.

An induction current according to an embodiment of the present application may have various attributes according to the relationships between a coil 16000, a magnetic field formed around a coil 16000, and a crucible 13000. The attributes will be described below.

In this case, according to the mathematical equation,

$$I ∝ \frac{dQ}{dt} ,$$

the intensity of induction current mentioned herein may refer to an electric charge moving in the crucible 13000 per unit time. That is, note that the intensity of induction current mentioned herein is a quantity-related concept and is a concept that implies how much charge has moved.

Electrical attributes of an induction current induced to a crucible 13000 according to an embodiment of the present application may vary according to attributes of a dynamic magnetic field formed around a coil 16000.

For example, when the intensity of the dynamic magnetic field according to the present application and/or the intensity change value of the magnetic field increase, the intensity attribute of the formed induction current may increase. According to the above-described relations, (1) \vec{F}=q\vec{v}×\vec{H} and

$$e ∝ \frac{d B}{dt}$$

when the intensity change value of the dynamic magnetic field increases, a force applied to the electrons of the crucible 13000 may increase, and an electromotive force that affects motion of the electrons may increase. Accordingly, the amount of electrons that may move in the crucible 13000 increases, and thus the intensity attribute of the induction current increases.

Also, electrical attributes of an induction current inducted to a crucible 13000 according to an embodiment of the present application may vary according to the shape of a crucible 13000.

For example, the intensity of the induction current may vary corresponding to the thickness of the crucible. The intensity of the induction current may increase when the thickness of the crucible is large, and the intensity of the induction current may decrease when the thickness of the crucible is small. The amount of electrons in the crucible 13000 may change according to the thickness of the crucible 13000. The amount of electrons when the thickness of the crucible 13000 is large is greater than the amount of electrons when the thickness of the crucible 13000 is relatively smaller. Accordingly, since the amount of electrons that may move due to the formed magnetic field increases as the thickness of the crucible 13000 is larger, the intensity of the induction current may increase as the thickness of the crucible 13000 is larger.

Meanwhile, an induction current according to an embodiment of the present application may form an induction magnetic field in a crucible 13000 again according to the magnetic field formation attributes. Also, the induction magnetic field may secondarily form the induction current in the crucible 13000 according to induction current formation attributes. That is, in a crucible 13000 according to an embodiment of the present application, induction current formation and induction magnetic field formation events may serially occur.

1.1.2.3 Induction Heating

A quantity of heat may be generated using various methods in a crucible 13000 according to an embodiment of the present application.

A quantity of heat may be generated in a crucible 13000 according to an embodiment of the present application due to a combination of the induction current induced to the crucible 13000 and an electrical resistance component of the crucible 13000. The combination of the induction current and the electromagnetic component may satisfy the relation, P∝I²·R· [symbol] (where P=generated quantity of heat, I=induction current, R=resistance component of crucible, t=heating time). According to the relation, the induction current and/or an induction current path induced to the crucible 13000 may be converted to a quantity of heat due to the resistance component of the crucible 13000. In this case, it can be recognized that the quantity of heat generated in the crucible 13000 increases as the intensity of the induction current increases.

Also, a quantity of heat may be generated in the crucible 13000 according to a combination of the dynamic magnetic field formed around the coil 16000 and the electromagnetic component of the crucible 13000.

The quantity of heat generated in the crucible 13000 due to the induction current and/or the dynamic magnetic field may heat the crucible 13000. Since the crucible 13000 is heated by the induction current induced by the coil 16000 and the dynamic magnetic field, the heating of the crucible may be referred to as induction heating.

Although various methods exist as described above for an induction heating according to an embodiment of the present application, the following description will focus on the case in which the crucible 13000 is inductively heated according to the induction current formed in the crucible 13000 and the resistance component of the crucible 13000.

A coil 16000, which is an example of a heating means 15000 that may be implemented in a heating assembly, and various electrical attributes that occur depending on a coil 16000 have been described above. A magnetic field focusing member 17000 that may be disposed in a heating assembly according to an embodiment of the present application will be described below.

1.1.3 Magnetic Field Focusing Member

An aid for a heating means 15000 may be present in the heating assembly according to an embodiment of the present application. For example, when a heating means 15000 according to an embodiment of the present application is a coil 16000, the magnetic field focusing member 17000 configured to focus the magnetic field formed around the coil 16000 may be included as the heating aid in the heating assembly. In this case, “focusing” may be interpreted as focusing magnetic flux of a magnetic field to any one region.

Hereinafter, a ferrite 18000, which is an example of the magnetic field focusing member 17000, will be described. Although the ferrite 18000 is described herein as an example of the magnetic field focusing member 17000, note that the magnetic field focusing member 17000 is not limited thereto and any other means or material capable of focusing a magnetic field may be implemented as the magnetic field focusing member 17000 in the heating assembly.

A ferrite 18000 according to an embodiment of the present application may be implemented in various types and forms using various materials.

For example, the ferrite 18000 is an ionic compound having a spinel structure and may be formed by bonding various metal compounds to a main component, with iron oxide as the main component. The various metal compounds may be divalent metal ions such as Mn, Zn, Mg, Cu, Ni, and Co. However, a ferrite 18000 described herein is not limited to the above components and may be formed with materials formed of various other components capable of focusing a magnetic field.

Also, types of the ferrite 18000 may include: (1) a liquid type that may be present in a liquid phase at room temperature; and (2) a solid type that may have a predetermined shape at room temperature.

Also, the ferrite 18000 may have various shapes, such as a plate shape, a shape in which a convex protrusion is formed on at least one or more surfaces of the plate shape, a circular shape, an elliptical shape, and a spherical shape, to fit a purpose.

A magnetic field focusing attribute, which is an attribute of the ferrite 18000, and an effect in which efficiency of heating the crucible 13000 is improved according to the magnetic field focusing attribute will be described below.

1.1.3.1 Magnetic Field Focusing Attribute

Hereinafter, magnetic field focusing of a ferrite 18000, which is an example of a magnetic field focusing member 17000 according to an embodiment of the present application, will be described.

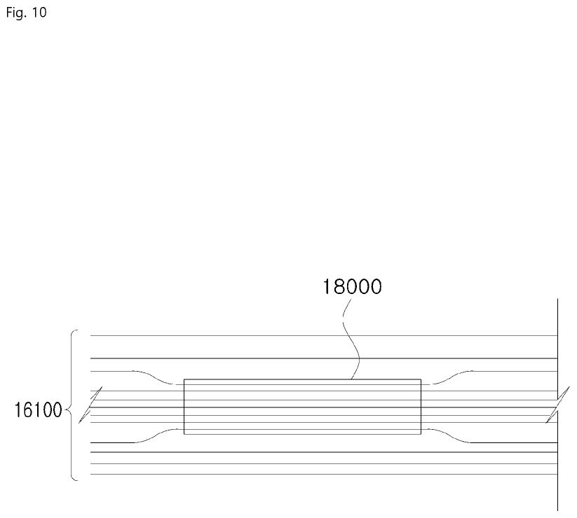

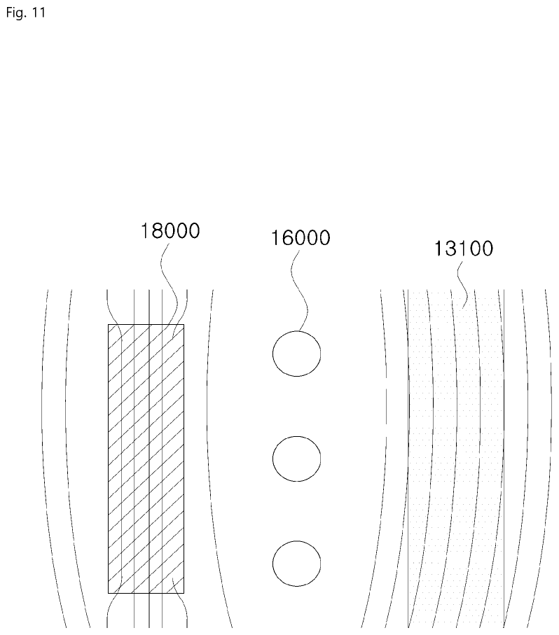

FIG. 10 is a view illustrating a ferrite placed in a magnetic field according to an embodiment of the present application.

Referring to FIG. 10, a ferrite 18000 placed in a magnetic field according to an embodiment of the present application may affect magnetic flux of a magnetic field. For example, the ferrite 18000 may act to draw the magnetic flux of the magnetic field formed around the ferrite 18000 toward the ferrite 18000 so that the density of magnetic flux of the magnetic field is high around the ferrite 18000.

In this case, the influence on the magnetic flux may vary according to a thickness of the ferrite 18000. As the thickness of the ferrite 18000 is larger, the amount of magnetic flux formed around the ferrite 18000 that may be affected may increase.

The ferrite 18000 may be disposed in a heating assembly according to the present application.

A ferrite 18000 disposed in a heating assembly according to an embodiment of the present application may have a magnetic field focusing attribute that increases an intensity change value of a dynamic magnetic field that affects the crucible 13000.

FIG. 11 is a view illustrating a ferrite, a coil, and a magnetic field formed around the coil according to an embodiment of the present application.

Referring to FIG. 11, when a ferrite 18000 according to the present application is disposed in the heating assembly, the ferrite 18000 may focus magnetic flux of a dynamic magnetic field so that the density of magnetic flux of the dynamic magnetic field is high at the outer wall 13100 of the crucible 13000.

The dynamic magnetic flux densely formed at the outer wall 13100 of the crucible 13000 may be due to the above-described attribute of the ferrite 18000. The ferrite 18000 disposed at an outer side of the coil 16000 may cause the density of magnetic flux to be high in the crucible 13000 by drawing the magnetic flux which is formed toward an inner side of the coil 16000 toward the ferrite 18000.

Alternatively, the dynamic magnetic flux densely formed at the outer wall 13100 of the crucible 13000 may be due to the magnetic field formation attribute as well as the attribute of the ferrite 18000. The ferrite 18000 disposed at the outer side of the coil 16000 may draw the magnetic flux which is formed toward the outer side of the coil 16000 toward the ferrite 18000 according to the attribute of the ferrite 18000. Simultaneously, according to the magnetic formation attribute in that magnetic fields are symmetrically formed around the coil 16000, the magnetic flux formed toward the inner side of the coil 16000 may also be drawn symmetrically toward the crucible 13000 and formed. Accordingly, the density of magnetic flux of the dynamic magnetic field is high at the outer wall 13100 of the crucible 13000.

Since the density of magnetic flux is high, the intensity in the positive (+) direction and the intensity in the negative (−) direction of the dynamic magnetic field around the coil 16000 that is formed at the outer wall of the crucible 13000 simultaneously increase. As the intensity of the magnetic field increases in both directions, the dynamic range of the intensity of the dynamic magnetic field that fluctuates also increases corresponding to the increase. That is, the intensity change value of the dynamic magnetic field generated at the outer wall 13100 of the crucible 13000 increases as compared with the case in which the ferrite 18000 is not disposed.

1.1.3.2 Improvement of Heating Efficiency

Hereinafter, improvement of the efficiency of heating a crucible 13000 that occurs when a ferrite 18000 is implemented in a heating assembly according to an embodiment of the present application will be described. The heating efficiency mentioned herein refers to a quantity of heat generated in the crucible 13000 relative to electrical energy input to the coil, which is the heating means 15000 according to the present application. That is, when the electrical energy input to the coil is the same, it can be said that the heating efficiency (or thermal efficiency) is higher as the quantity of heat generated in the crucible 13000 is larger.

An efficiency of heating a crucible 13000 may be improved in the case in which a ferrite 18000 is disposed in a heating assembly according to an embodiment of the present application, as compared with the case in which a ferrite 18000 is not disposed therein.

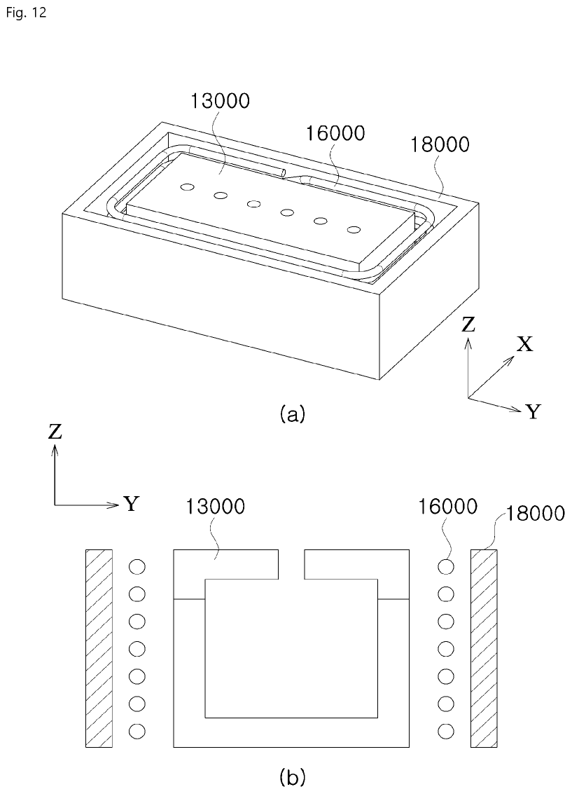

FIG. 12 is a view illustrating a ferrite disposed in a heating assembly according to an embodiment of the present application.

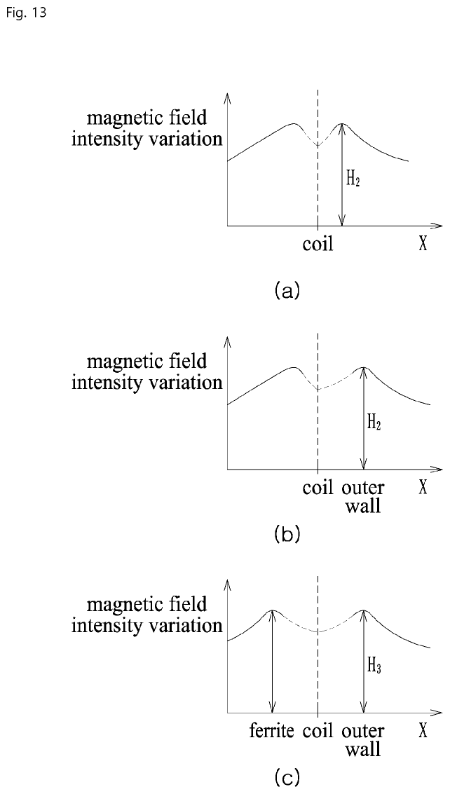

FIG. 13 is a graph showing a distribution of intensity change values of a magnetic field according to an embodiment of the present application.

Referring to FIGS. 12(a) and 12(b), a ferrite 18000 according to an embodiment of the present application may be formed in the form of surrounding a coil 16000 disposed at an outer side of a crucible 13000. For example, the ferrite 18000 which has a form corresponding to that of the coil 16000 disposed at the crucible 13000 may be disposed. Specifically, as illustrated in FIG. 12, corresponding to side portions of the closed-shape coil 16000 formed in a rectangular parallelepiped shape that is disposed at the outer side of the crucible 13000, the ferrite 18000 formed in a hollow rectangular parallelepiped shape may be disposed in which four surfaces opposite to each side portion are formed.

As illustrated in FIG. 12, when the ferrite 18000 is disposed at the outer side of the coil 16000, an efficiency of heating a crucible 13000 according to an embodiment of the present application may be improved. Referring to FIG. 13(b), a distribution of intensity change values of a dynamic magnetic field formed around a coil according to an embodiment of the present application may be changed due to a crucible disposed in a heating assembly. For example, the distribution of the intensity change values of the dynamic magnetic field formed toward the inner side of the coil may be shifted in a direction toward the outer wall of the crucible. However, the maximum size of the change value of the magnetic field satisfies H1≈H2, and the crucible 13000 being disposed may not cause a significant change in the distribution.

Meanwhile, referring to FIG. 13(c), the distribution of the intensity change values of the dynamic magnetic field formed around the coil may be changed due to the ferrite 18000 disposed in the heating assembly. For example, as illustrated in FIGS. 12(a) and 12(b), as the ferrite 18000 is disposed, a magnetic field may be focused to the outer wall of the crucible due to the ferrite 18000. Accordingly, the intensity in the positive (+) direction and the intensity in the negative (−) direction of the dynamic magnetic field around the coil 16000 formed at the outer wall of the crucible 13000 increase simultaneously. As the intensity of the magnetic field increases in both directions, the dynamic range of the intensity of the dynamic magnetic field that fluctuates also increases corresponding to the increase. That is, the intensity change value of the magnetic field satisfies H3>>H1,H2 and, when the ferrite 18000 is disposed, the intensity change value of the magnetic field may be higher at the outer wall as compared with when the ferrite 18000 is not disposed.

As the intensity change value of the magnetic field becomes higher as described above, the induction current intensity may further increase in the crucible 13000 in which the ferrite 18000 is disposed as compared with the crucible 13000 in which the ferrite 18000 is not disposed.

Due to the above-described induction heating attribute, as the induction current intensity increases as described above, the quantity of heat generated in the crucible 13000 may increase. As a result, a quantity of heat generated due to the coil 16000 in which the ferrite 18000 is disposed is larger than that generated due to the coil 16000 in which the ferrite 18000 is not disposed, and thus the efficiency of heating the crucible 13000 may be improved.

Hereinafter, an example of disposing a ferrite 18000 so that an efficiency of heating a crucible 13000 is improved will be described.

Referring to FIG. 12(b), a ferrite 18000 according to an embodiment of the present application may be implemented in a form of surrounding an upper portion and a lower portion of a coil 16000 disposed in a crucible 13000. For example, in the case of the closed-shape coil 16000 which is disposed so that the crucible 13000 is disposed at the inner portion thereof, the ferrite 18000 may be disposed up to the upper portion and the lower portion of the closed-shape coil 16000.

When a ferrite 18000 is implemented as described above according to an embodiment of the present application, an effect of focusing to a crucible 13000 even a dynamic magnetic flux exiting through an upper surface or a lower surface of a coil 16000 may be achieved. Since the dynamic magnetic field is focused to the crucible 13000, the efficiency of heating the crucible 13000 is improved.

Other than being disposed at an outer portion of a crucible 18000, a ferrite 18000 according to an embodiment of the present application may also be disposed in a form of being included in an inner portion of a crucible 13000 in order to improve an efficiency of heating a crucible 13000.

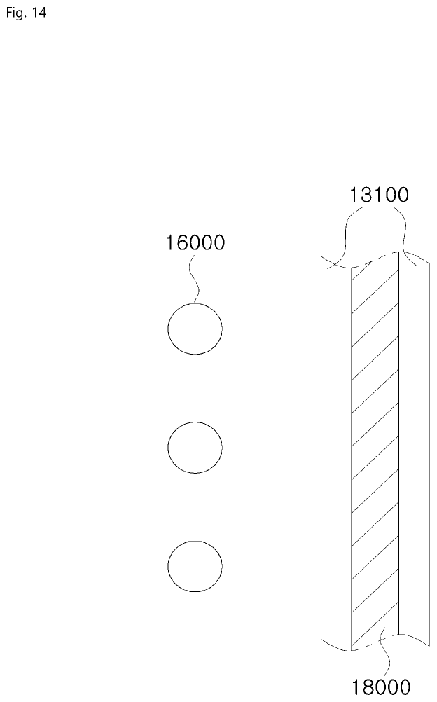

FIG. 14 is a cut side view illustrating a ferrite included in an outer wall of a crucible according to an embodiment of the present application.

As illustrated in FIG. 14, as the ferrite 18000 is formed at the outer wall 13100 of the crucible 13000, a dynamic magnetic field may be focused to the outer wall 13100 of the crucible 13000. As the dynamic magnetic field is focused, an effect of further improving the efficiency of heating the crucible 13000 may be achieved.

Also, in order to improve an efficiency of heating a crucible 13000, a ferrite 18000 according to an embodiment of the present invention may be implemented in a form of being applied to a crucible 13000.

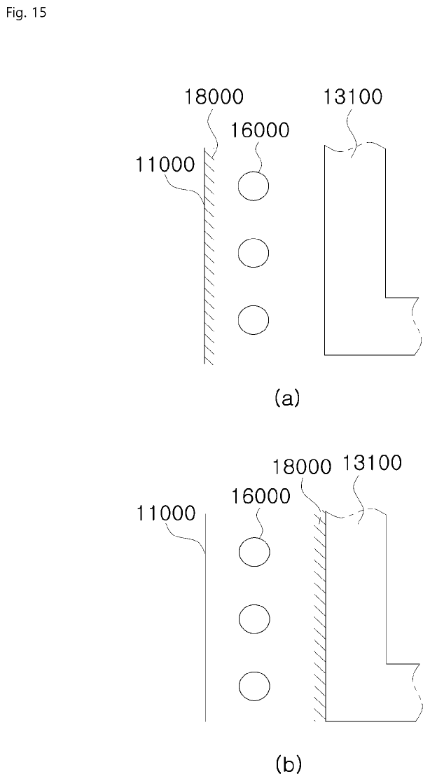

FIG. 15 is a view illustrating a shape implemented by applying a ferrite to a deposition apparatus 110000 according to an embodiment of the present application.

Referring to FIGS. 15(a) to 15(d), a ferrite 18000 according to an embodiment of the present application may be implemented in a form of being applied on a heating assembly and coated to a configuration of a heating assembly.

For example, a ferrite 18000 according to an embodiment of the present application may be applied to an inner surface of an outer wall of a housing 11000 surrounding the crucible 13000. Referring to FIG. 15(a), the ferrite 18000 may be applied on the inner surface of the outer wall of the housing 11000 which surrounds a side surface portion of the crucible 13000. A ferrite 18000 according to an embodiment of the present application may also be applied on a crucible 13000. As illustrated in FIG. 15(1b), the ferrite 18000 may be applied on the outer wall 13100 at a side surface of the crucible 13000.

Various thicknesses may be selected as a thickness of a ferrite 18000 applied to a heating assembly according to an embodiment of the present application, according to a design purpose.

When a ferrite 18000 is disposed in a heating assembly as described above according to an embodiment of the present application, a thermal efficiency of a crucible 13000 may be improved, and, as a result, a quantity of heat transferred from a crucible 13000 to a deposition material may increase. As a result, by the ferrite 18000 being disposed in the deposition apparatus 10000, the deposition apparatus 10000 may have high heat output relative to the same input energy, and thus an effect of allowing efficient energy use may be achieved. Also, since the deposition apparatus 10000 has sufficient energy that allows the deposition material to actively move according to the high heat output, the deposition apparatus 10000 may have an effect of increasing a success rate in which the deposition material is formed on a deposition target surface.

Hereinafter, a method of improving the actual deposition efficiency (or deposition success rate) of the deposition material by controlling a heat distribution in a crucible 13000 by varying the configuration of the deposition apparatus 10000 according to the present application will be described.

In this case, the actual deposition efficiency may refer to the efficiency at which the deposition material is formed at a uniform thickness or concentration on a deposition target surface as well as the efficiency at which the deposition material is properly formed on the deposition target surface.

### 2. Control of Heat Distribution in Crucible

For the deposition apparatus 10000 that deposits a deposition material on a deposition target surface, improving the actual deposition efficiency at which the deposition material is deposited on the deposition target surface may be an important issue. In order to improve the deposition success rate, a method of controlling a spatial distribution of quantities of heat provided to the deposition material accommodated in an inner space of the crucible 13000 may be used.

For example, (1) the quantities of heat distributed in each space of the crucible 13000 may be controlled to be different from each other. As a specific example, by relatively increasing the distribution of quantities of heat around the nozzle 13200 of the crucible 13000, the temperature of the deposition material passing through the nozzle 13200 may be increased. As a result, the deposition material is smoothly discharged via the nozzle 13200 to the deposition target surface and formed thereon, and the deposition apparatus 10000 may have an effect of improving the actual deposition efficiency.

Also, (2) the quantities of heat distributed in a space of the crucible 13000 may be controlled to be uniform. By causing the heat distribution in the crucible to be uniform, the heat distribution allows deposition materials discharged from each nozzle formed in the crucible to move together toward the deposition target surface. Accordingly, the deposition material may be uniformly formed on the deposition target surface, and the actual deposition efficiency may be improved.

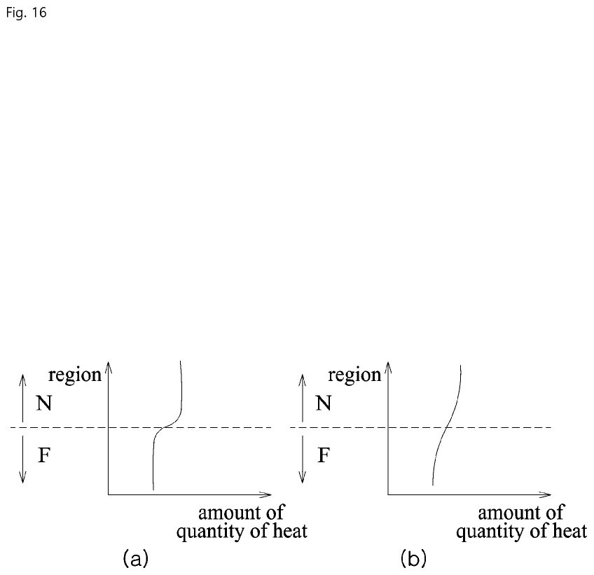

FIG. 16 is a schematic diagram illustrating a heat distribution in a crucible according to an embodiment of the present application.

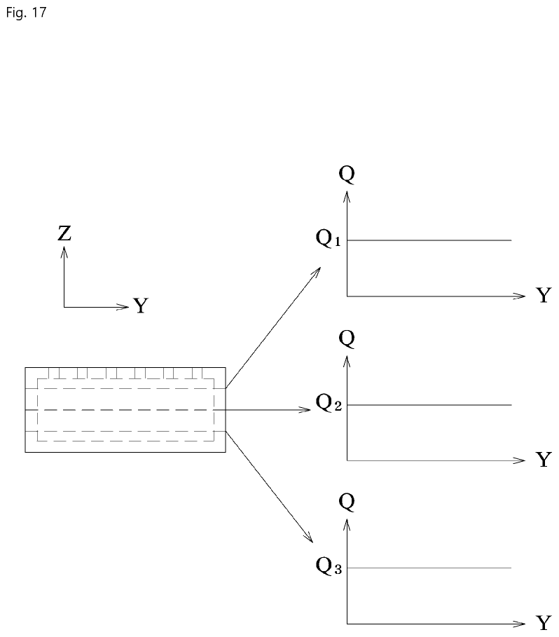

FIG. 17 is a schematic diagram illustrating a heat distribution in a crucible according to an embodiment of the present application.

For convenience of description, a region of a side surface relatively nearer to an upper surface of the crucible 13000 at which the nozzle 13200 is formed will be referred to as “N-region,” and a region relatively further from the upper surface will be referred to as “F-region.”

As described above, the heat distribution in the crucible 13000 to be achieved in the present invention may be a heat distribution in which a heat distribution of quantities of heat at the N-region of the side surface of the crucible 13000 is relatively higher than a heat distribution of quantities of heat at the F-region.

In the case of the heat distribution illustrated in FIG. 16(a), the deposition material may receive a sufficient quantity of heat from the N-region of the side surface of the crucible 13000 and smoothly pass through the nozzle 13200 to move to the deposition target surface.

In the case of the heat distribution illustrated in FIG. 16(b), when the deposition material moves toward the nozzle 13200 inside the crucible 13000, an effect in which the deposition material receives a quantity of heat with a natural heat distribution and smoothly moves to the deposition target surface may be achieved.

Controlling each configuration of the heating assembly so that a heat distribution in which a quantity of heat generated in the side surface of the crucible varies in the Z-axis direction is achieved has been described with reference to FIGS. 16(a) and 16(b). Also, implementing each configuration of the heating assembly so that, while the side surface of the crucible is divided in the Z-axis direction into the N-region near the nozzle and the F-region far from the nozzle, a heat distribution in which different quantities of heat are generated in each region is achieved has been described.

However, the heat distributions are merely examples, and the heat distribution in the crucible 13000 is not limited thereto. The configurations of the heating assembly may be implemented so that a heat distribution in which various quantities of heat are generated in different regions is achieved in the X-axis and Y-axis directions.

Also, the heat distribution in the crucible 13000 to be achieved in the present invention may be a heat distribution illustrated in FIG. 17 in which quantities of heat generated at the side surface of the crucible 13000 are uniform in the X-axis direction. In this case, the quantities of heat generated in the Z-axis direction may vary. The heat distribution in the crucible may satisfy Q1>>Q2>>Q3 so that a quantity of heat generated at the side surface of the crucible at which the nozzle is formed is large as described above. Also, the heat distribution in the crucible may be controlled to satisfy Q1≈Q2≈Q3 so that a quantity of heat generated in the Z-axis direction is uniform.

For the spatial distribution of quantities of heat provided to the deposition material accommodated in the inner space of the crucible 13000 to be controlled to a predetermined distribution as described above, a distribution of intensities of induction current induced to the outer wall 13100 of the crucible 13000 may be appropriately controlled. For example, when a horizontal direction and a vertical direction are defined with respect to one heating surface of four heating surfaces of the crucible 13000, the distribution of the induction current with respect to the one heating surface may be appropriately controlled in the horizontal direction or appropriately controlled in the vertical direction.

According to some embodiments of the present application, the crucible 13000 may be manufactured so that the induction current distribution is controlled using the shape of the outer wall 13100 of the crucible 13000.

According to some embodiments of the present application, the heating assembly may be manufactured so that the induction current distribution is controlled using a distance between the crucible 13000 and the coil 16000.

According to some embodiments of the present application, the heating assembly may be manufactured so that the induction current distribution is controlled using disposition or distribution of magnetic field focusing units.

According to some embodiments of the present application, the heating assembly may be manufactured so that the induction current distribution is controlled using independent control of the coil 16000.

Hereinafter, the above-described embodiments will be described in detail.

Meanwhile, although the nozzles 13200 are illustrated in the drawings and described below as being formed in an upward direction, this does not mean that the deposition apparatus is aupward type or downward type apparatus.

Also, although the crucible is illustrated in the drawings and described herein as having a rectangular parallelepiped shape in the longitudinal direction, this is merely an example as described above. The implementation examples described below may also apply to heating assemblies having crucibles of various other shapes.

2.1 Crucible

A method of controlling a heat distribution in a crucible 13000 in order to improve the actual deposition efficiency according to an embodiment of the present application may include a method of varying the shape of a crucible 13000. For example, the method may include a method of varying a distance between the side portion of the crucible 13000 and the coil 16000, a method of varying the thickness of the crucible 13000, and the like.

Hereinafter, embodiments in which a heat distribution in the crucible 13000 is controlled by varying the shape of the crucible 13000 will be described in detail.

2.1.1 Adjusting Distance Between Crucible and Coil

In order to control a heat distribution in a crucible 13000 according to an embodiment of the present application, a crucible 13000 may be formed to have various distance relationships with the coil 16000, which is the heating means 15000 formed.

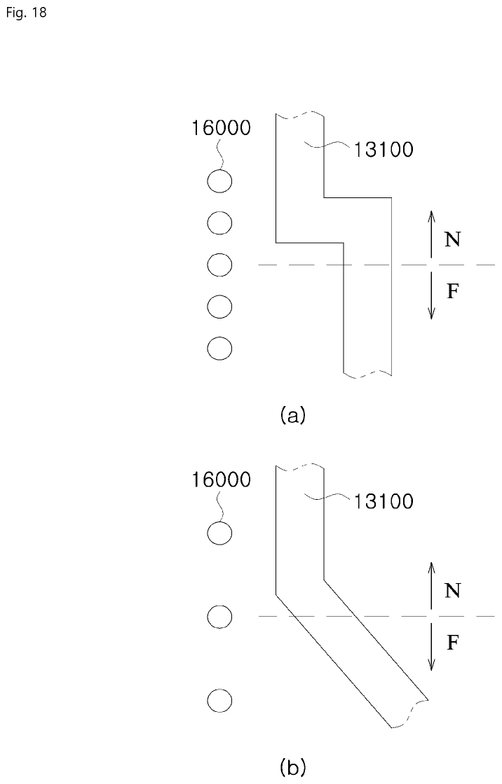

FIG. 18 is a cut side view illustrating an example in which the shape of a crucible is varied according to an embodiment of the present application.

Referring to FIGS. 18(a) and 18(b), the crucible 13000 may be implemented so that side portion regions included in the side surface of the crucible 13000 have different distance relationships with the coil 16000 disposed around the crucible 13000. Specifically, the crucible 13000 may be implemented so that a region of the side surface of the crucible 13000 relatively nearer to a lower surface of the crucible 13000 which is opposite to an upper surface thereof at which the nozzle 13200 is formed (hereinafter referred to as “F-region) is more depressed than a region of the side surface of the crucible 13000 relatively nearer to the upper portion of the crucible 13000 (hereinafter referred to as “N-region”).

Also, referring to FIG. 18(b), the region of the side surface of the crucible 13000 relatively nearer to the lower surface of the crucible 13000 may be formed to have a predetermined inclination. Specifically, the crucible 13000 may be formed so that the side surface of the crucible 13000 at the largest distance from the nozzle 13200 formed at the crucible 13000 may be at the largest distance from the coil 16000, and a side portion of the crucible 13000 relatively nearer to the nozzle 13200 is at a relatively smaller distance from the coil 16000 formed.

As described above according to an embodiment of the present application, the crucible 13000 may be controlled so that, when the crucible 13000 is implemented, a heat distribution is achieved in which a heat distribution of quantities of heat in the N-region of the side surface of the crucible 13000 is higher than a heat distribution of quantities of heat in the F-region thereof. According to the above-described magnetic field formation attribute

$$( H ∝ k \cdot \frac{I}{r}$$

which is described above), an intensity change value of a dynamic magnetic field may be larger in the N-region of the side surface of the crucible 13000 that is implemented nearer to the coil 16000 than the F-region of the side surface of the crucible 13000. Therefore, the intensity of induction current formed in the crucible 13000 that corresponds to the intensity change value of the magnetic field is higher at the N-region than at the F-region. Therefore, as a result, referring to FIG. 16(a), as described above, the crucible 13000 may be controlled so that, when the crucible 13000 is implemented, a heat distribution is achieved in which a heat distribution of quantities of heat in the N-region is higher than a heat distribution of quantities of heat in the F-region.

Accordingly, the quantity of heat generated at an upper end portion of the crucible 13000 increases, and a temperature at the upper end portion may become relatively higher than that at a lower end portion of the crucible 13000. As a result, an effect of allowing the deposition material, which is discharged from the crucible 13000, to move at a high velocity with high activation energy toward the deposition target surface via the nozzle 13200 of the crucible 13000 may be achieved.

Meanwhile, referring to FIG. 16(b), when the outer wall 13100 of the crucible 13000 is implemented to have an inclination in the F-region of the side surface of the crucible 13000, since a distance between the crucible 13000 and the coil 16000 continuously changes, a heat distribution in the crucible may be controlled to be more natural in the F-region.

Accordingly, when the deposition material moves toward the nozzle 13200 in the crucible 13000, the deposition material may naturally receive an increased quantity of heat. Therefore, as compared with when the deposition material discontinuously receives a quantity of heat, an effect of allowing the deposition material to naturally move toward the deposition target surface may be achieved.

2.1.2 Adjusting Thickness of Outer Wall of Crucible

A heat distribution in a crucible 13000 may be controlled by implementing the outer wall 13100 of a crucible 13000 according to an embodiment of the present invention to have various thicknesses.

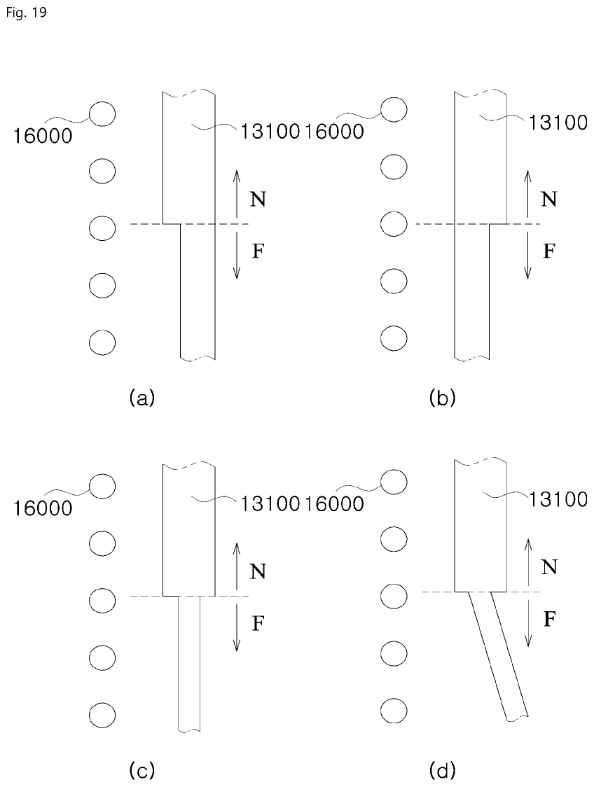

FIG. 19 is a cut side view illustrating examples in which a thickness of a crucible is varied according to an embodiment of the present application.

Referring to FIGS. 19(a) to (d), a crucible 13000 according to an embodiment of the present application may be formed so that regions having different thicknesses are present therein.

For example, in the crucible 13000, a portion relatively nearer to the nozzle 13200 formed in the crucible 13000 (N-region of the side surface of the crucible 13000) and a portion relatively further therefrom (F-region of the side surface of the crucible 13000) may be formed with different thicknesses. Specifically, the F-region of the side surface of the crucible 13000 may be formed with a smaller thickness. Referring to FIG. 19(a), an outer side of the F-region of the side surface of the crucible 13000 may be depressed toward the inner side of the crucible 13000 such that the thickness of the F-region is smaller than that of the N-region. Referring to FIG. 19(b), an inner wall of the F-region of the side surface of the crucible 13000 may be depressed toward the outer side of the crucible 13000 such that the thickness of the F-region is relatively smaller than the thickness of the N-region. Also, referring to FIG. 19(c), the F-region of the side surface of the crucible 13000 may have a form in which the above-described forms are combined, and the F-region may be depressed from the outer wall 13100 toward the inner side and from the inner wall toward the outer side such that the thickness of the F-region is relatively smaller than the thickness of the N-region.

As the thickness of the crucible 13000 is varied as described above, the distance between the crucible 13000 and the coil 16000 may also vary. Referring to FIGS. 19(a) and (c), since the F-region of the side surface of the crucible 13000 according to an embodiment of the present application is depressed toward the inner side from the outer side and has a relatively smaller thickness than the N-region, the distance between the crucible 13000 and the coil 16000 may also increase in the F-region.

As described above according to an embodiment of the present application, the crucible 13000 may be controlled so that, when the crucible 13000 is implemented, the heat distribution illustrated in FIG. 16(a) is achieved in which a heat distribution of quantities of heat in the N-region is higher than a heat distribution of quantities of heat in the F-region, due to the magnetic field formation attribute

$$( H ∝ k \cdot \frac{I}{r}$$

which is described above) or the induction current attribute (the thickness of the crucible 13000 which is described above). A dynamic magnetic field with a large magnetic field intensity change value may be formed in the N-region of the side surface of the crucible 13000. Corresponding to the magnetic field intensity change value, induction current with a relatively high intensity may flow in a side portion of the crucible 13000 with a relatively large thickness (the N-region). Since a quantity of heat generated in the N-region increases due to the induction current with a relatively high intensity, the heat distribution in the crucible 13000 may be controlled as described above.

Meanwhile, referring to FIG. 19(d), as an example in which the above-described shapes of the crucible 13000 are combined, a crucible 13000 according to an embodiment of the present application may have regions with different thicknesses that have a predetermined angle of inclination.

When the crucible 13000 is implemented as described above, the distance between the F-region of the side surface of the crucible 13000 and the coil 16000 may continuously change. Therefore, the crucible 13000 may be controlled so that a heat distribution is achieved in which a heat distribution of quantities of heat in the N-region is higher than a heat distribution of quantities of heat in the F-region while, as illustrated in FIG. 16(b), the heat distribution is more natural in the F-region.

When the crucible 13000 is implemented as described above, the quantity of heat supplied to the deposition material passing through the N-region increases, and the deposition material is smoothly guided to the deposition target surface such that it is possible to improve the actual deposition efficiency.

The method of controlling a heat distribution in the crucible 13000 by varying the implementation shape of the crucible 13000 according to an embodiment of the present application has been described above. A method of controlling a heat distribution in the crucible 13000 by varying a method of implementing the coil 16000 will be described below.

Meanwhile, although the crucible 13000 is illustrated in the drawings referenced above as being present at an inner portion of the closed-shape coil 16000 formed, embodiments may not be limited thereto.

2.2 Coil

A method of controlling a heat distribution in a crucible 13000 in order to improve the actual deposition efficiency according to an embodiment of the present application may include a method of varying the implementation of a coil 16000. For example, the method may include a method of adjusting the number of windings of the coil 16000, a method of varying the distance between the crucible 13000 and the coil 16000, and the like.

Embodiments in which the coil 16000 is implemented in various ways will be described below.

2.2.1 Adjusting Number of Windings of Coil

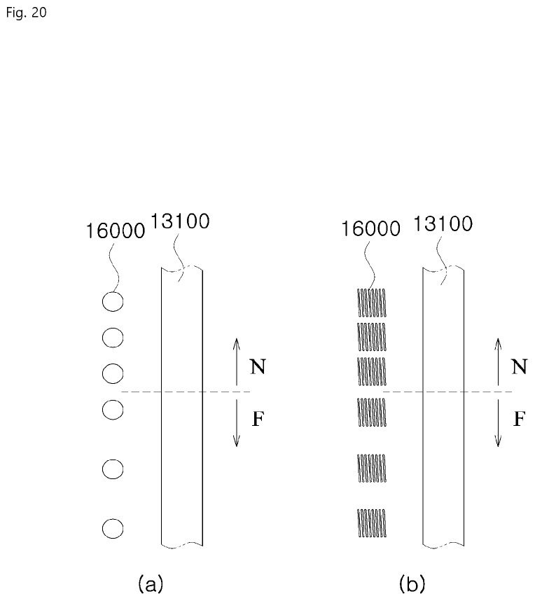

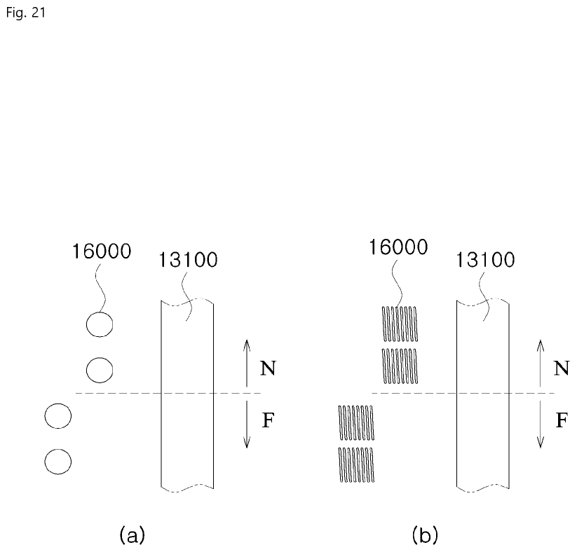

FIG. 20 is a view illustrating a coil formed at an outer side of a crucible according to an embodiment of the present application.

Referring to FIG. 20(a), the number of windings of a coil 16000 may be different in different regions of the side surface of a crucible 13000 according to an embodiment of the present application. For example, the number of windings of the closed-shape coil 16000 that affects the region of the side surface of the crucible 13000 (the N-region) present at a relatively smaller distance from the nozzle 13200 of the crucible 13000 may be larger than the number of windings of the coil 16000 formed at the region of the side surface of the crucible 13000 (the F-region) present at a relatively larger distance from the nozzle 13200.

Also, referring to FIG. 20(b), the crucible 13000 may be implemented so that upper portions or lower portions of a plurality of closed-shape coils 16000 are disposed in the N-region of the side surface of the crucible 13000. The number of windings of the coil 16000 disposed in the N-region may be larger than the number of windings of the coil 16000 disposed in the F-region.

When a coil 16000 is implemented as described above according to an embodiment of the present application, a crucible 13000 may be controlled so that a heat distribution is achieved in which a heat distribution of quantities of heat in the N-region is higher than a heat distribution of quantities of heat in the F-region. According to the above-described magnetic field formation attribute (H∝N which is described above), an intensity change value of a dynamic magnetic field formed in the N-region of the side surface of the crucible 13000 in which the number of windings of the coil 16000 is larger than that in the F-region may be larger than an intensity change value of a dynamic magnetic field formed in the F-region. As a result, an intensity of induction current formed in the crucible 13000 is also higher in the N-region than in the F-region. Therefore, as a result, referring to FIG. 16(a), as described above, the crucible 13000 may be controlled so that, when the crucible 13000 is implemented, a heat distribution is achieved in which a heat distribution of quantities of heat in the N-region is higher than a heat distribution of quantities of heat in the F-region.

Accordingly, the quantity of heat generated at the upper end portion of the crucible 13000 increases, and the temperature at the upper end portion may become relatively higher than that at the lower end portion of the crucible 13000. As a result, an effect of allowing the deposition material, which is discharged from the crucible 13000, to move at a high velocity with high activation energy toward the deposition target surface via the nozzle 13200 of the crucible 13000 may be achieved.

2.2.2 Adjusting Distance Between Coil and Crucible

A coil 16000 according to an embodiment of the present application may be implemented in various ways in terms of a positional relationship with the outer wall 13100 of a crucible 13000.

For example, a coil 16000 according to an embodiment of the present application may be disposed so that, as compared with a distance at which the coil 16000 is formed at one surface of a crucible 13000, a distance at which the coil 16000 is formed at another surface of the crucible 13000 is smaller.

FIG. 21 is a view illustrating a coil formed at an outer side of a crucible according to an embodiment of the present application.

Referring to FIG. 21(a), the coil 16000 may be disposed so that a distance between the crucible 13000 and the coil 16000 is different in each region of the side surface of the crucible 13000 according to an embodiment of the present application. For example, a distance between the crucible 13000 and the closed-shape coil 16000 that affects the region of the side surface of the crucible 13000 (the N-region) present at a relatively smaller distance from the nozzle 13200 of the crucible 13000 may be smaller than the distance between the crucible 13000 and the coil 16000 formed at the region of the side surface of the crucible 13000 (the F-region) present at a relatively larger distance from the nozzle 13200.

Also, referring to FIG. 21(b), for example, in an embodiment in which a coil 16000 are densely disposed, the crucible 13000 may be formed so that upper portions or lower portions of a plurality of closed-shape coils 16000 are disposed at a relatively smaller distance from the N-region of the side surface of the crucible 13000 than from the F-region of the side surface of the crucible 13000.

When a coil 16000 is implemented as described above according to an embodiment of the present application, a crucible 13000 may be controlled so that a heat distribution is achieved in which a heat distribution of quantities of heat in the N-region is higher than a heat distribution of quantities of heat in the F-region. According to the above-described magnetic field formation attribute

$$( H ∝ k \cdot \frac{I}{r}$$

which is described above), an intensity change value of a magnetic field formed in the N-region of the side surface of the crucible 13000 which is at a relatively smaller distance from the coil 16000 than the F-region may be larger than an intensity change value of a magnetic field formed in the F-region. As a result, an intensity of induction current formed in the crucible 13000 is also higher in the N-region than in the F-region. Therefore, as a result, referring to FIG. 21(a), as described above, the crucible 13000 may be controlled so that, when the crucible 13000 is implemented, a heat distribution is achieved in which a heat distribution of quantities of heat in the N-region is higher than a heat distribution of quantities of heat in the F-region.

The method of controlling a heat distribution in the crucible 13000 by varying the implementation shape of the coil 16000 according to an embodiment of the present application has been described above. A method of controlling a heat distribution in the crucible 13000 by disposing the magnetic field focusing member 17000 in the heating assembly will be described below.

2.2.3 Separately Driven Coils

A coil 16000 implemented in a deposition apparatus 10000 according to an embodiment of the present application may be separately driven in order to control a heat distribution in a crucible 13000.

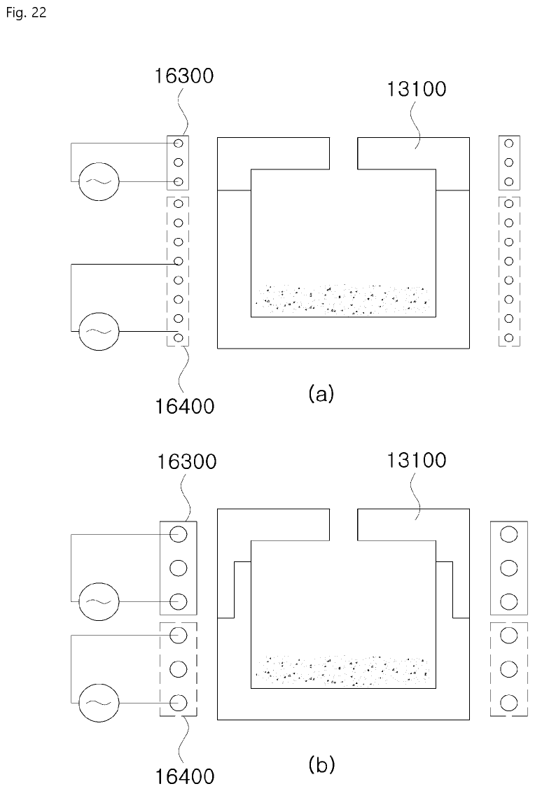

FIG. 22 is a conceptual diagram illustrating an example in which a coil implemented in a deposition apparatus 10000 are separately driven according to an embodiment of the present application.

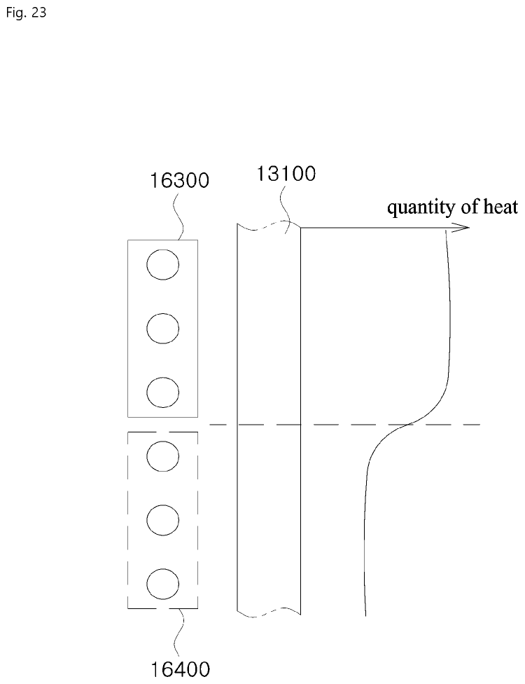

FIG. 23 is a view conceptually illustrating a heat distribution in a crucible according to an embodiment of the present invention.

Referring to FIG. 22, coils 16000 according to an embodiment of the present application may be separately driven. Attributes of variable power applied to separately driven coils 16300 and 16400 may be different from each other. The attributes of the variable power may include a frequency attribute, an intensity attribute, and the like of the power.

Powers having different attributes that are applied to the coil 16000 may be applied by power supply devices which are as many as the number of powers.

Alternatively, a plurality of powers whose attributes are different from each other that are applied to the coils 16300 and 16400 for each of the separately driven coils 16300 and 16400 may be applied by power supply devices, the number of which is less than the number of powers. When the power supply devices, the number of which is less than the number of plurality of powers, apply the powers, an electrical process of distributing output wires or the like may be required to supply powers having attributes different from each other to each of the separately driven coils 16300 and 16400.

Separately driven coils according to an embodiment of the present application may be disposed corresponding to various implementation examples of the crucible.

Referring to FIG. 22(a), the separately driven coils 16300 and 16400 may be disposed in different regions of the crucible. The crucible may be divided into an upper region and a lower region on the basis of a structure configured to separate the implemented crucible. A separately-driven first coil 16300 may be disposed in the upper region of the crucible, and a separately-driven second coil 16400 may be disposed in the lower region of the crucible. Accordingly, attributes of magnetic fields that affect each region of the crucible may vary, and thus quantities of heat generated in the upper region and the lower region of the crucible may be different from each other.

Also, as illustrated in FIG. 22(b), the structure configured to separate the crucible may be implemented in the crucible. As an implementation example of the structure configured to separate the crucible, the crucible may be divided into an upper region and a lower region on the basis of the structure configured to separate the crucible that is formed at an outer surface of the crucible. As described above, the separately driven coils 16300 and 16400 may be respectively disposed in the upper region and the lower region of the crucible.

In this case, in order to increase a quantity of heat generated in a portion of the crucible 13000 that is near the nozzle 13200, coils 16000 disposed in the above-described crucible 13000 according to an embodiment of the present application may be separately driven. A frequency and an intensity of power applied to the coil 16000 disposed at the portion near the nozzle 13200 may be relatively higher than those of power applied to the coil 16000 disposed at other portions of the crucible 13000.

When a frequency and/or an intensity of power applied to the separately-driven first coil 16300 are higher than a frequency and/or an intensity of power applied to the separately-driven second coil 16400, a quantity of heat generated in the crucible 13000 that corresponds to the separately-driven first coil 16300 may become higher than a quantity of heat generated in the crucible 13000 that corresponds to the separately-driven second coil 16400. According to the magnetic field formation attribute, the separately-driven second coil 16400 may form therearound a magnetic field with a relatively higher intensity than the separately-driven first coil 16300. Due to the magnetic field with a relatively higher intensity, the intensity of induction current formed at the portion of the crucible 13000 near the nozzle 13200 may increase. As a result, the separately driven coils 16300 and 16400 may be controlled so that the heat distribution in the crucible 13000 that is illustrated in FIG. 23 is achieved.

According to the heat distribution in the crucible 13000, the deposition material discharged via the nozzle 13200 of the crucible 13000 may receive a sufficient quantity of heat. Accordingly, the deposition material may be smoothly guided to a deposition target surface.

Meanwhile, when frequencies of powers applied to the coils 13000 vary as described above, magnetic fields generated around the separately driven coils 16300 and 16400 may interfere with, interrupt, and/or affect each other. Since the magnetic fields affect each other, the intensity of the magnetic field formed in the crucible 13000 may decrease. As a result, since the intensity of the induction current formed in the crucible 13000 decreases, an issue in that the efficiency of heating the crucible 13000 decreases may occur.

To address the issue that may occur, the separately driven coils 16300 and 16400 according to an embodiment of the present application may be implemented to not affect each other.

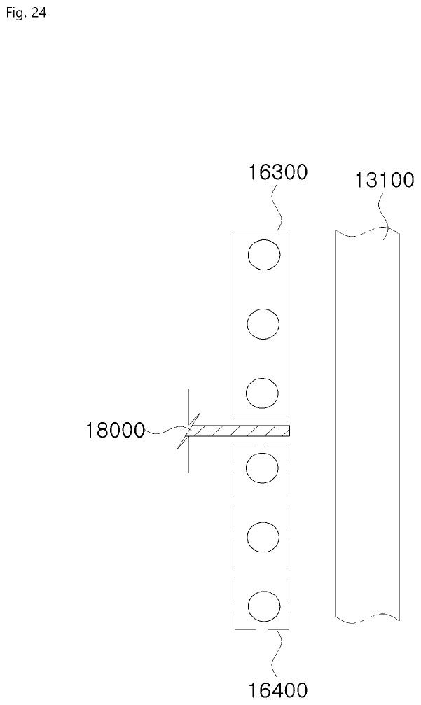

FIG. 24 is a view illustrating a ferrite inserted between coils according to an embodiment of the present application.

Referring to FIG. 24, in order to eliminate the mutual interference between separately driven coils 16300 and 16400 according to an embodiment of the present application, a ferrite 18000 may be inserted between the separately driven coils 16300 and 16400. Magnetic fields that interfere with each other may be magnetic fields formed between the separately driven coils 16300 and 16400. The magnetic fields formed between the separately driven coils 16300 and 16400 are formed toward other coils 16000 and affect magnetic fields formed in the other coils 16000. Therefore, by the ferrite 18000 being inserted between the coils 16300 and 16400, the magnetic fields formed between the separately driven coils may be focused to the ferrite 18000. By the magnetic fields being focused to the ferrite 18000, a kind of shielding effect in that a magnetic field cannot be formed toward another coil 16000 may occur. As a result, the inserted ferrite 18000 may eliminate the mutual interference between the separately driven coils 16300 and 16400.

2.3 Ferrite

A ferrite 18000 according to an embodiment of the present application may affect attributes of a magnetic field. For example, the ferrite 18000 may affect an intensity of a generated magnetic field. Specifically, the ferrite 18000 may affect an intensity of a magnetic field by affecting magnetic flux constituting the magnetic field, thereby increasing or decreasing the number of magnetic field lines passing through a predetermined area.

Hereinafter, as examples of a method of controlling a heat distribution in a crucible 13000 in order to improve the deposition efficiency according to an embodiment of the present application, various methods in which the ferrite 18000 is disposed in the heating assembly will be described. For example, the examples of the method may include a method of disposing the ferrite 18000 by varying the shape of the ferrite 18000, a method of disposing the ferrite 18000 at an inner portion of the outer wall 13100 of the crucible 13000, a method of applying the ferrite 18000, a method of disposing the ferrite 18000 in each region, a method of forming a window in the ferrite 18000, and the like.

Meanwhile, although the ferrite 18000 is described below and/or illustrated in the drawings as being implemented in a form having four sides, this is merely an example, and embodiments are not limited thereto. The ferrite 18000 may be implemented in various other forms such as a circular shape, an elliptical shape, or a spherical shape.

2.3.1 Varying Disposition of Ferrite

A ferrite 18000 according to an embodiment of the present application may be disposed in a crucible 13000 in various forms of surrounding a coil 16000.

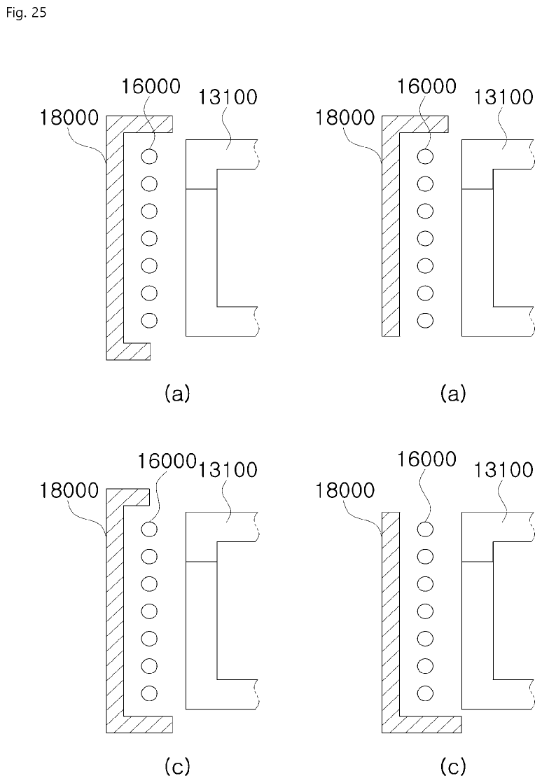

FIG. 25 is a view illustrating various shapes of a ferrite according to an embodiment of the present application.

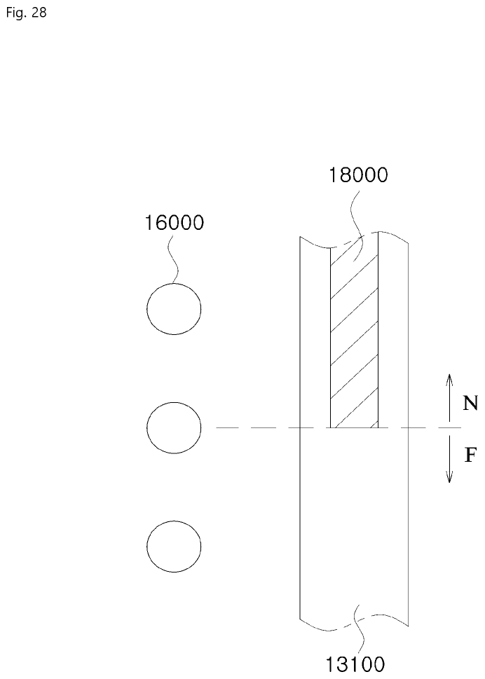

Referring to FIGS. 25(a) to (d), a ferrite 18000 according to an embodiment of the present application may be disposed to partially cover conductive wires at an upper portion and/or a lower portion of a closed-shape coil 16000. For example, as illustrated in FIGS. 25(a) and (b), the ferrite 18000 may be disposed so that the lower portion of the closed-shape coil 16000 is partially open. For example, as illustrated in FIGS. 28(c) and (d), the ferrite 18000 may be disposed so that the upper portion of the closed-shape coil 16000 is partially open.

When a ferrite 18000 is disposed in a heating assembly as described above according to an embodiment of the present application, a heat distribution may be achieved in which a heat distribution of quantities of heat in the N-region or the F-region of the side surface of a crucible 13000 is relatively higher. According to the above-described magnetic field focusing attribute, an intensity of a magnetic field formed in the N-region or the F-region of the side surface of the implemented crucible 13000 may increase. As a result, the intensity of induction current formed in the crucible 13000 may also be relatively higher in the N-region or the F-region. Therefore, as a result, when the ferrite 18000 is disposed in the heating assembly as described above, the crucible 13000 may be controlled so that the above-described heat distribution is achieved by a quantity of heat generated in the N-region, which is relatively nearer to the nozzle 13200, being larger than a quantity of heat generated in the F-region or the quantity of heat generated in the F-region being larger than a quantity of heat generated in the N-region.

Accordingly, the heat distribution in the crucible 13000, in which a heat distribution of quantities of heat in the N-region is higher than a heat distribution of quantities of heat in the F-region as described above, may have an effect of allowing the deposition material to move at a high velocity with high activation energy toward the deposition target surface via the nozzle 13200 of the crucible 13000 may be achieved. Meanwhile, the heat distribution in which a heat distribution of quantities of heat in the F-region is higher than a heat distribution of quantities of heat in the N-region may have an effect of allowing the deposition material to receive a sufficient quantity of heat so that a phase-change critical time is decreased.

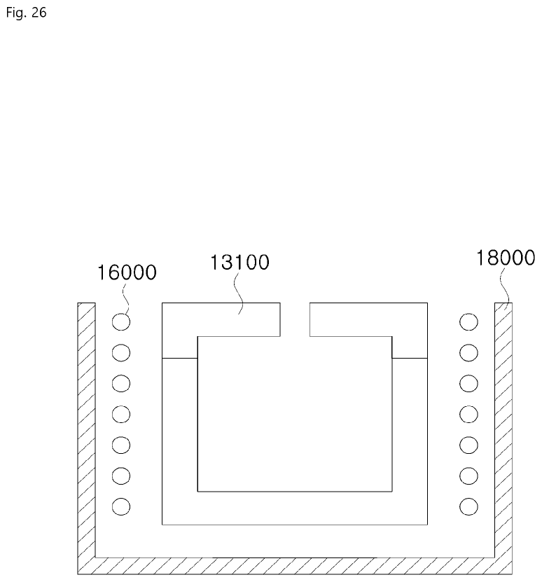

FIG. 26 is a view illustrating a ferrite disposed in a form of covering a lower surface of a crucible according to an embodiment of the present application.

Referring to FIG. 26, a ferrite 18000 according to an embodiment of the present invention may be disposed to completely cover a lower surface of a crucible 13000.

The above-described disposition of the ferrite 18000 may, according to the magnetic field focusing attribute of the ferrite 18000, allow a heat distribution to be achieved in which, in the crucible 13000, a quantity of heat at the lower surface of the crucible 13000 is relatively larger. Since the ferrite 18000 focuses a magnetic field to the lower surface of the crucible 13000, an intensity change value of a dynamic magnetic field generated at the lower surface of the crucible 13000 becomes relatively higher than that at other portions of the crucible 13000. In response to this, the intensity of induction current generated at the lower surface of the crucible 13000 also increases, and the quantity of heat generated according to the above-described induction heating attribute also increases. As a result, a heat distribution may be achieved in the crucible 13000 in which a quantity of heat generated at the lower surface of the crucible 13000 on which the deposition material is seated is relatively larger than quantities of heat generated at the upper surface and the side surface of the crucible 13000.

A ferrite 18000 according to an embodiment of the present application may be disposed so that a heat distribution is achieved in a crucible 13000 in which a heat distribution of quantities of heat in the N-region is higher than a heat distribution of quantities of heat in the F-region.

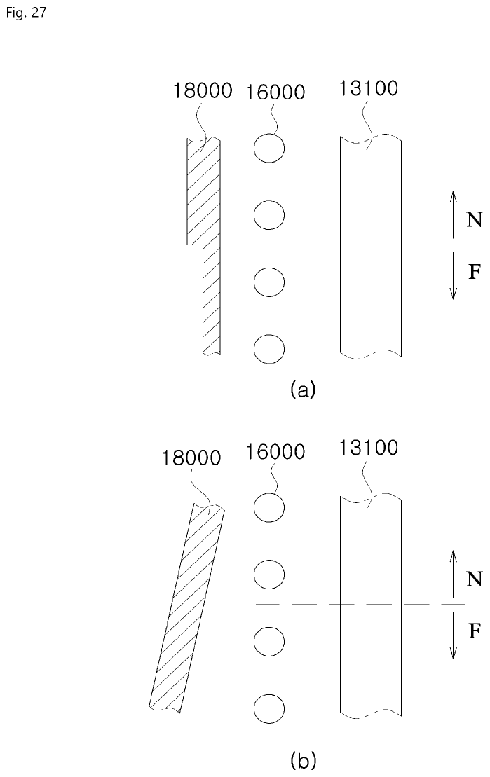

FIG. 27 is a view illustrating the shape of a ferrite according to an embodiment of the present application.

Referring to FIG. 27(a), a ferrite 18000 according to an embodiment of the present application may be disposed in a heating assembly by varying a thickness of the ferrite 18000. For example, the ferrite 18000 may be disposed so that the thickness of the ferrite 18000 is different for each region of the side surface of the crucible 13000. Specifically, the ferrite 18000 may be disposed so that a thickness of the ferrite 18000 disposed at a position corresponding to the N-region of the side surface of the crucible 13000 is relatively larger than a thickness of the ferrite 18000 disposed at a position corresponding to the F-region of the side surface of the crucible 13000.

The above-described disposition of the ferrite 18000 according to an embodiment of the present application may allow a heat distribution to be achieved in which, in the crucible 13000, a heat distribution of quantities of heat in the N-region is higher than a heat distribution of quantities of heat in the F-region. According to the magnetic field focusing attribute, an intensity change value of a magnetic field formed in the N-region may become relatively larger. Therefore, the intensity of induction current formed in the crucible 13000 also becomes relatively higher in the N-region than in the F-region. As a result, as illustrated in FIG. 16(a), according to the inducting heating attribute, a heat distribution may be achieved in which, in the crucible 13000, a heat distribution of quantities of heat is relatively higher in the N-region, in which the intensity of induction current is relatively higher, than in the F-region.

Meanwhile, although an example in which the thickness of the ferrite 18000 is varied in the case in which the ferrite 18000 is formed in a plate shape at an outer side of the closed-shape coil 16000 has been described above with reference to FIG. 27(a), the idea in that the thickness of the ferrite 18000 changes in a region of the crucible 13000 near the nozzle 13200 as described above may also apply to various other implementation examples such as an implementation example in which the ferrite 18000 is applied on the deposition apparatus 10000.

Also, referring to FIG. 27(b), the ferrite 18000 according to an embodiment of the present application may be disposed so that a distance between the crucible 13000 and the ferrite 18000 is different for each region of the side surface of the crucible 13000. For example, the ferrite 18000 may be disposed nearer to the N-region of the crucible 13000 than to the F-region thereof. For such disposition, the ferrite 18000 may be formed with a slight inclination so that the ferrite 18000 is near the portion of the crucible 13000 near the nozzle 13200 and is far from other portions of the crucible 13000.

Such disposition of the ferrite 18000 having the inclination according to an embodiment of the present application may allow a heat distribution to be achieved in which, in the crucible 13000, a heat distribution of quantities of heat is relatively higher in the N-region than in the F-region. According to the magnetic field focusing attribute of the ferrite 18000, the amount of magnetic flux focused to the N-region may become larger than the amount of magnetic flux focused to the F-region. Accordingly, an intensity change value of a magnetic field formed in the N-region may increase. As a result, the intensity of induction current formed in the crucible 13000 is also higher in the N-region than in the F-region. Therefore, referring to FIG. 16(a), when the crucible 13000 is implemented as described above, the crucible 13000 may be controlled so that a heat distribution is achieved in which a heat distribution of quantities of heat in the N-region, which is relatively nearer to the nozzle 13200, is higher than a heat distribution of quantities of heat in the F-region.

Although the ferrite 18000 has been described above as having a predetermined inclination so that the ferrite 18000 is formed relatively nearer to the portion of the crucible 13000 near the nozzle 13200, the shape of the ferrite 18000 is not limited, and the ferrite 18000 may have any shape other than that according to the embodiment in which the ferrite 18000 is implemented with an inclination as long as the shape allows the ferrite 18000 to be formed relatively nearer to the portion of the crucible 13000 near the nozzle 13200.

2.3.2 Varying Disposition of Ferrite at Inner Portion of Outer Wall of Crucible

A ferrite 18000 disposed in a form of being included inside a crucible 13000 according to an embodiment of the present application may be implemented so that the ferrite 18000 is disposed differently in each region inside the crucible 13000.

FIG. 28 is a cut side view illustrating a ferrite included in an outer wall of a crucible according to an embodiment of the present application.

Referring to FIG. 28, when a ferrite 18000 according to an embodiment of the present application is disposed in a form of being inserted into a side surface of a crucible 13000, the ferrite 18000 may be formed to be differently disposed in each region of the side surface. For example, the ferrite 18000 may be disposed in a form in which the ferrite 18000 is inserted into the N-region of the side surface of the crucible 13000.

As described above, a ferrite 18000 disposed according to an embodiment of the present invention may allow a heat distribution to be achieved in which, in a crucible 13000, a heat distribution of quantities of heat is higher in the N-region than in the F-region. According to the magnetic field focusing attribute of the ferrite 18000, the ferrite 18000 may cause an intensity change value of a dynamic magnetic field formed at the N-region of the side surface of the crucible 13000 to be relatively increased. As a result, the intensity of induction current formed in the crucible 13000 may also be higher in the N-region than in the F-region. Therefore, as illustrated in FIG. 16(a), the crucible 13000 may be controlled so that a heat distribution is achieved in which a quantity of heat in the N-region, which is relatively nearer to the nozzle 13200, is larger than a quantity of heat in the F-region.

2.3.3 Varying Application of Ferrite

When a ferrite is applied according to an embodiment of the present application, the ferrite may be implemented in a form in which the ferrite is applied only on a partial region of a heating assembly.

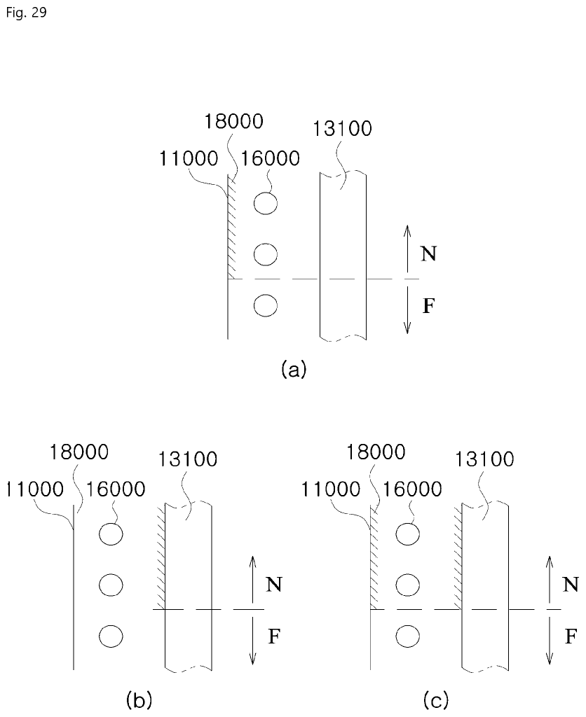

FIG. 29 is a view illustrating a ferrite 18000 applied to a heating assembly according to an embodiment of the present application.

Referring to FIGS. 29(a) to (c), in order to control a heat distribution in the crucible 13000, the ferrite 18000 may be applied only on partial regions of an inner surface of the outer wall of the housing 11000 and/or the outer wall 13100 of the crucible 13000. When the ferrite 18000 is applied only on the partial regions as described above, an intensity change value of a magnetic field may increase in partial regions of the crucible 13000 corresponding to positions at which the ferrite 18000 is applied. Accordingly, a distribution of intensities of current induced to the crucible 13000 may change, and by varying a quantity of heat generated in the crucible 13000, a heat distribution in the crucible 13000 may be controlled as illustrated in FIG. 16(a).

2.3.4 Disposing Ferrite Only in Partial Regions

A ferrite 18000 according to an embodiment of the present application may be disposed only in regions corresponding to portions of the side surface of a crucible 13000.

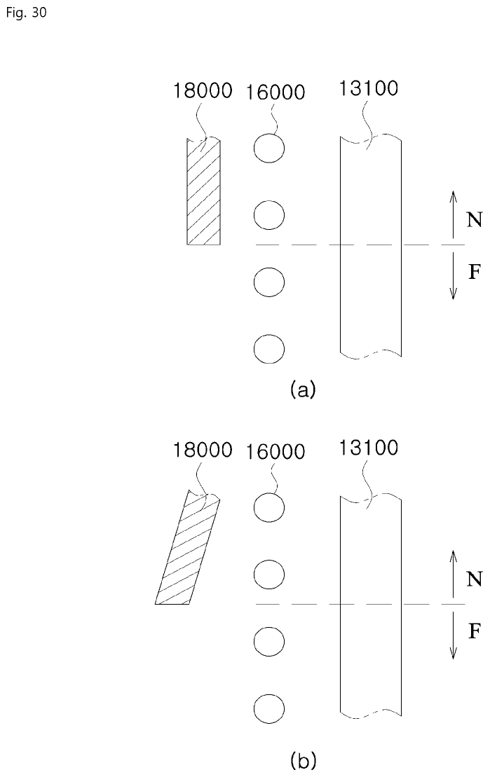

FIG. 30 is a view illustrating a state in which a ferrite is formed in a portion located near a nozzle of a crucible according to an embodiment of the present application.

Referring to FIG. 30(a), a ferrite 18000 according to an embodiment of the present application may be disposed only in a region corresponding to the N-region of the side surface of a crucible 13000. In this case, referring to FIG. 30(b), the ferrite 18000 may also be disposed with an inclination at a position corresponding to the N-region.

When the ferrite 18000 is disposed as described above, the ferrite 18000 may allow a heat distribution to be achieved in which, in the crucible 13000, a heat distribution of quantities of heat is higher in the N-region than in the F-region. According to the magnetic field focusing attribute of the ferrite 18000, the ferrite 18000 may cause an intensity change value of a magnetic field formed at the N-region to be relatively increased. Accordingly, the intensity of induction current formed in the crucible 13000 may also be higher in the N-region than in the F-region. Therefore, as a result, referring to FIG. 16, as described above, the crucible 13000 may be controlled so that, when the crucible 13000 is implemented, a heat distribution is achieved in which a heat distribution of quantities of heat is higher in the N-region, which is relatively nearer to the nozzle 13200, than in the F-region. Accordingly, as the heat distribution in the crucible 13000 is controlled as described above, it is possible to improve the actual deposition efficiency.

### 3. Combination Examples

As described above, in order to control a heat distribution in a crucible 13000 according to an embodiment of the present application, a heating assembly may have various implementation examples and/or disposition examples.

The technical ideas of the above-described implementation examples and/or disposition examples according to an embodiment of the present application may be combined and implemented in the heating assembly. In this case, the technical idea may refer to how the above-described examples will be specifically implemented and/or disposed. That is, the combinations of implementation examples may refer to applications of combinations of the implementation examples of the crucible 13000, the implementation examples of the coil 16000, and/or the disposition examples of the ferrite 18000, which are implemented in various shapes that have been described above in detail, to the heating assembly.

The various embodiments described above may be practiced in combination. Hereinafter, it will be described that the embodiments of the heating assembly design in the Z-axis direction which have been specifically described above can also apply in the X-axis and Y-axis directions.

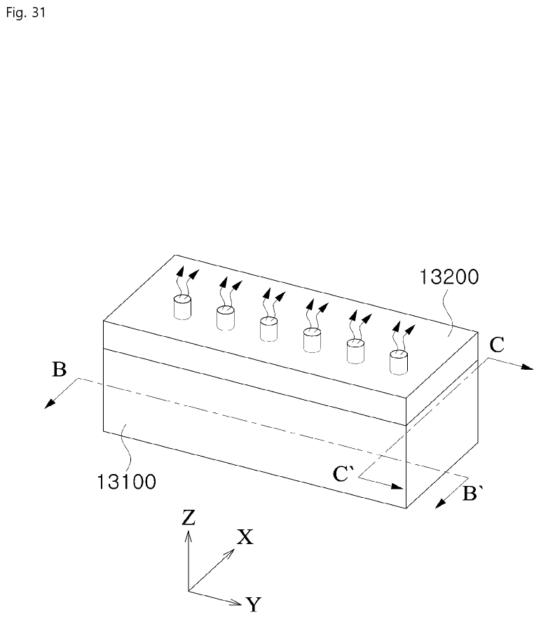

FIG. 31 is a view illustrating a side surface of a crucible according to an embodiment of the present application.

Referring to FIG. 31, the embodiments of the heating assembly in the Z-axis direction may also apply in the X-axis or Y-axis direction to implement the heating assembly.

For example, an example in which the heating assembly is implemented by applying the above-described embodiments in the Y-axis direction will be described.

A plurality of regions may be distinguished in the Y-axis direction of the crucible. The region of the crucible in the Y-axis direction may be divided into N regions, and each region will be referred to as a first Y-region to an Nth Y-region hereinafter.

For implementation of a heating assembly according to embodiments of the present application, the heating assembly may be designed on the basis of the various embodiments described above so that a heat distribution attribute is assigned to each of the first Y-region to the Nth Y-region.

Examples of the heating assembly design in the Y-axis direction will be described below.

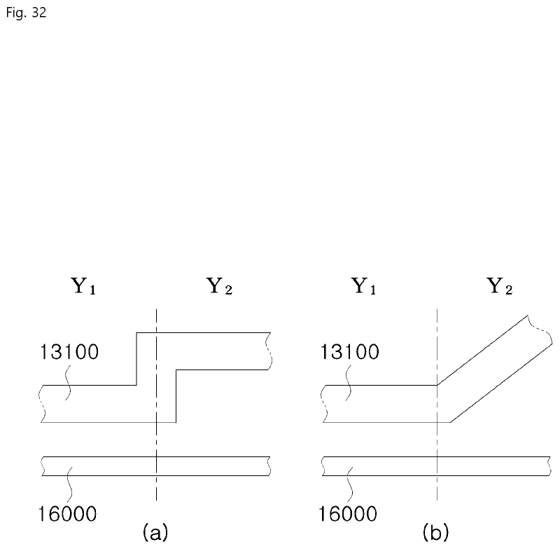

FIGS. 32 to 35 are views related to design of a heating assembly in the Y-axis direction according to an embodiment of the present application.

As illustrated in FIG. 32, the crucible may be implemented to protrude so that a side surface of the first Y-region is formed nearer to the coil than a side surface of the second Y-region.

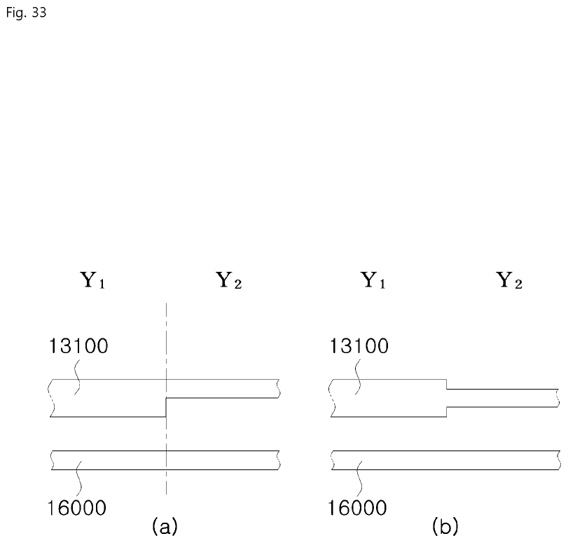

Also, referring to FIG. 33, the thickness of the outer wall of the crucible may be implemented to vary in the Y-direction so that the thickness of the outer wall of the crucible in the first Y-region is larger than the thickness of the outer wall of the crucible in the second Y-region. Also, as illustrated in FIG. 33(b), by the thickness of the outer wall of the crucible being adjusted in the second Y-region, a distance of the crucible from the coil may also increase.

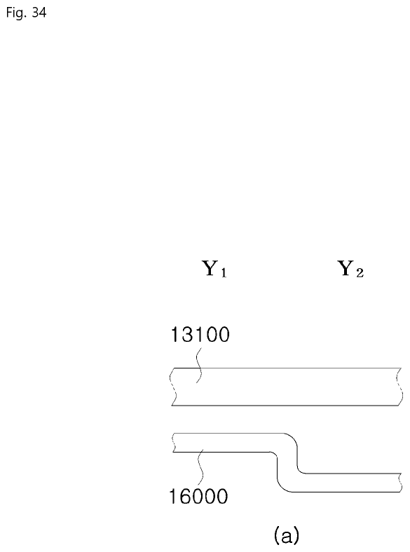

The coil disposed in the Y-direction may be disposed so that a distance thereof from the outer wall of the crucible varies. Referring to FIG. 34, the coil may be disposed near the outer wall of the crucible in the first Y-region and disposed far from the outer wall of the crucible in the second Y-region.

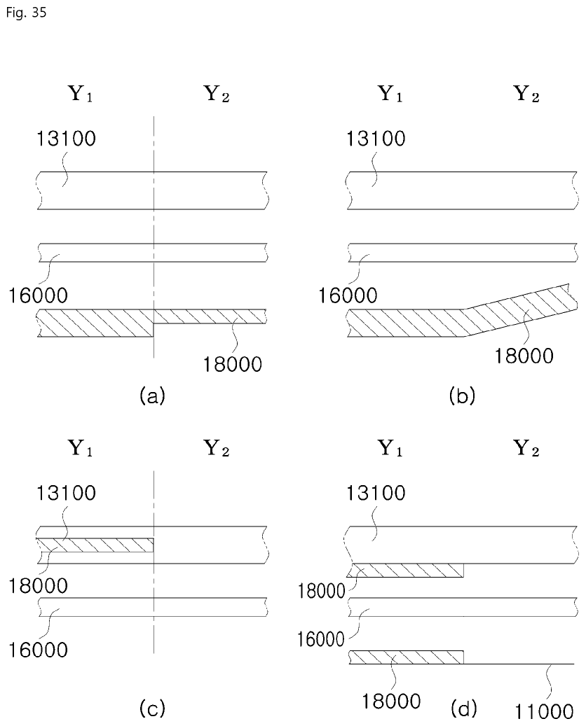

Referring to FIG. 35, the implementation example and/or disposition example of the ferrite disposed in the Y-direction may vary according to a Y-region. The thickness of the ferrite disposed in the first Y-region may be implemented to be larger than the thickness of the ferrite disposed in the second Y-region as illustrated in FIG. 35(a), and the inclination of the ferrite may be implemented so that the ferrite is relatively further from the first Y-region than the second Y-region as illustrated in FIG. 35(b). As illustrated in FIGS. 35(c) and (d), the ferrite may be applied or disposed only in a region corresponding to the first Y-region.

When the heating assembly is designed according to the above implementation examples, according to the above-described idea, an affected intensity change value of a magnetic field is larger at a side surface of the first Y-region of the crucible than at a side surface of the second Y-region of the crucible. Also, corresponding to the intensity change value of the magnetic field, an intensity of induction current may also be relatively higher at the side surface of the first Y-region of the crucible than in the second Y-region.

As a result, since a quantity of heat generated at the side surface of the first Y-region becomes relatively larger than a quantity of heat generated at the side surface of the second Y-region, the crucible may be designed so that a heat distribution is achieved in which a first heat distribution in the first Y-region is higher than a second heat distribution in the second Y-region.

Meanwhile, although the heating assembly has been described above as being designed in the Y-axis direction, embodiments are not limited thereto, and the above design examples may also be utilized in designing the heating assembly in a region in the X-axis direction.

Although examples in which the heating assembly is designed in order to control heat distributions only in two regions of the plurality of Y-regions have been described above, embodiments are not limited thereto, and the above-described design may be utilized in designing the heating assembly in order to control a heat distribution in each of the N regions. Meanwhile, the regions may be disposed at various intervals such as equal intervals, different intervals, or random intervals.

The designs described above may be applied solely or in combination to the heating assembly for each region along each axis. A deposition apparatus 110000 according to the present application may be implemented by combining all of the above-described implementation examples or implemented by combining only some of the above-described implementation examples in order to achieve an optimal implementation example.

Hereinafter, the heating assembly designed by combining the embodiments described above will be described.

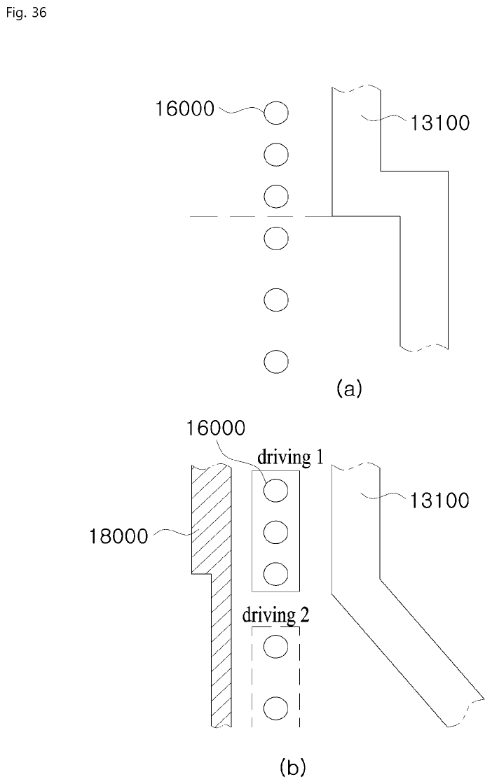

FIG. 36 is a view illustrating a heating assembly implemented by combining embodiments in the Z-direction of a crucible according to an embodiment of the present application.

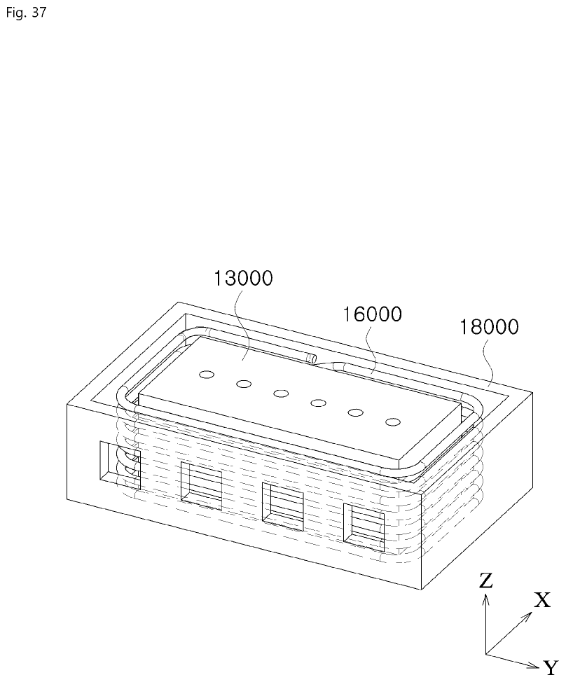

FIG. 37 is a view illustrating a heating assembly implemented by combining embodiments in the X-, Y-, and Z-directions of a crucible according to an embodiment of the present application.

Referring to FIG. 36(a), the implementation example of the crucible 13000 and the implementation example of the coil 16000 described above may be combined by being applied to a Z1 region and a Z2 region. In the Z1 region which is a region of the side surface of the crucible 13000 relatively nearer to the nozzle 13200, the side surface of the crucible 13000 may protrude further and the crucible 13000 may be implemented to be relatively nearer to the coil 16000 than in the Z2 region which is a region of the side surface of the crucible 13000 relatively further from the nozzle 13200. Also, the coil 16000 with a relatively larger number of windings may be disposed at a position corresponding to the Z1 region. Accordingly, a heat distribution may be achieved in which, in the crucible, a quantity of heat generated in the Z1 region, which is a region of the side surface of the crucible 13000 relatively nearer to the nozzle 13200, is relatively larger.

Also, as illustrated in FIG. 36(b), the deposition apparatus 10000 may be implemented by combining an implementation example in which separately driven coils 16000 are implemented, an implementation example of the coil 16000, and an implementation example of the ferrite 18000. The side surface of the crucible may further protrude in the Z1 region than in the Z2 region such that the crucible is implemented to be relatively nearer to the coil 16000 in the Z1 region than in the Z2 region, the coils 16000 disposed in the Z1 and Z2 regions of the crucible 13000 may be separately driven, and the ferrite 18000 may be disposed across the Z1 and Z2 regions so that the thickness of the ferrite 18000 disposed in the Y1 region is larger than the thickness of the ferrite 18000 disposed in the Z2 region. Accordingly, a heat distribution may be achieved in which, in the crucible, a heat distribution of quantities of heat generated in the Z1 region, which is a region of the side surface of the crucible 13000 relatively nearer to the nozzle 13200, is higher than a heat distribution of quantities of heat generated in the Z2 region.

Hereinafter, the heating assembly designed for each region in the three-dimensional X-, Y-, and Z-directions will be described.

When a crucible 13000 according to an embodiment of the present application is formed in a rectangular parallelepiped shape with the Y-direction as the longitudinal direction, a quantity of heat generated in the crucible 13000 may be larger at a side surface in the longitudinal direction. Therefore, quantities of heat generated in an X-axis region and a Y-axis region of the crucible 13000 may be different, and thus a heat distribution in the crucible may be a non-uniform heat distribution in which the heat distribution becomes lower at both ends in the longitudinal direction. Due to the non-uniform heat distribution in the crucible, the deposition material may be unable to receive a sufficient quantity of heat uniformly. Accordingly, since the deposition material is unable to move to be uniformly formed on a deposition target surface, the actual deposition efficiency may decrease as a result.

A ferrite 18000 according to an embodiment of the present application may be controlled so that a heat distribution in a crucible 13000 is uniform.

A heating assembly may be designed so that a ferrite 18000 according to an embodiment of the present application is disposed in partial regions of the Y-axis region and the Z-axis region and is disposed in the entire region of the X-axis region. As a result, as illustrated in FIG. 37, the ferrite 18000 having a window formed may be disposed at the side surface of the crucible in the longitudinal direction in the heating assembly.

An intensity change value of a magnetic field that affects a region of the side surface of the crucible 13000 in the Y-direction becomes smaller as compared with when the window is not formed. Accordingly, an intensity of induction current in the region of the side surface of the crucible 13000 in the Y-axis direction may be relatively decrease as compared with when the window is not formed. As a result, since a quantity of heat generated at the side surface of the crucible 13000 in the longitudinal direction decreases, as illustrated in FIG. 17, the crucible 13000 may be controlled so that a heat distribution in the side surface of the crucible 13000 in the Y-direction is uniform.

The heating assembly designed by combining various embodiments, which have been described above, has been described above. Meanwhile, implementation examples applied by being combined in order to implement a deposition apparatus 10000 according to an embodiment of the present application may be combined with various modifications thereof as long as the technical ideas of the implementation examples are not changed.

Various embodiments of implementing the deposition apparatus 10000 in order to improve the deposition success rate at which the deposition material is deposited on a deposition target surface, which is an important issue of the deposition apparatus 10000, has been described above.

### 4. Thermal Equilibrium Control in Crucible

Methods of controlling a heat distribution in each region of a crucible in the X-, Y-, and Z-directions by designing a heating assembly according to embodiments of the present application have been described above.

Hereinafter, a method of controlling thermal equilibrium in a crucible according to the present application will be described.

The thermal equilibrium in a crucible should be controlled so that a deposition material according to an embodiment of the present application is able to be smoothly discharged from the crucible.

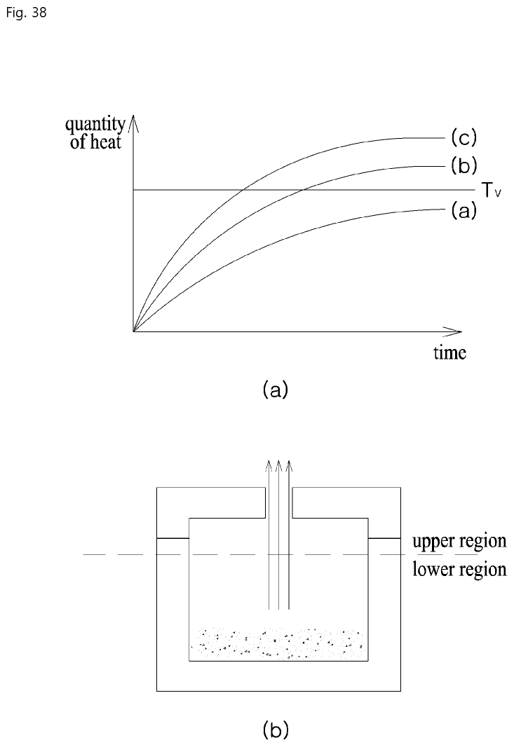

FIG. 38 is a view illustrating thermal equilibrium at a lower surface of a crucible according to an embodiment of the present application.

Referring to FIG. 38, the thermal equilibrium at the lower surface of the crucible may be achieved by quantities of heat having various numerical values. For example, as illustrated in (b) and (c), the thermal equilibrium may be achieved with a quantity of heat larger than a phase-change quantity of heat Tv of the deposition material, or, as illustrated in (a), the thermal equilibrium may be achieved with a quantity of heat smaller than the phase-change quantity of heat.

In this case, the thermal equilibrium may refer to a state in which a quantity of supplied heat and a quantity of discharged heat are equal and thus the same quantity of heat is maintained over time. Since, even in such a thermal equilibrium state, a quantity of heat is continuously supplied to the lower surface of the crucible and continuously discharged therefrom, the equilibrium state may also be referred to as, specifically, “dynamic equilibrium state.”

Referring back to FIG. 38, for the deposition material to change phase and move to the deposition target surface, the thermal equilibrium at the lower surface of the crucible should be achieved with a quantity of heat larger than the phase-change quantity of heat Tv of the deposition material as illustrated in (b) and (c). By the quantity of heat larger than the phase-change quantity of heat being continuously supplied to the deposition material, the deposition material may continuously change phase and move. Accordingly, since the phase-changed deposition material continuously moves to the deposition target surface, deposition may continuously occur.

However, when the thermal equilibrium at the lower surface of the crucible is achieved as illustrated in (c), a quantity of heat that is excessively larger than the phase-change quantity of heat Tv of the deposition material may be supplied. Accordingly, (1) since the deposition material is discharged with an excessively high velocity from the nozzle of the crucible, the deposition material which is deposited on the deposition target surface may not have sufficient time for being properly seated on the deposition target surface, and thus uniformity of deposition may be decreased. Also, (2) wasted energy may be increased. Therefore, when the thermal equilibrium is achieved as illustrated in (c), it can be said that the thermal equilibrium at the lower surface of the crucible has been controlled inefficiently.

That is, in the thermal equilibrium at the lower surface of the crucible, as illustrated in (b), the supplied quantity of heat may be moderately larger than the phase-change quantity of heat Tv of the deposition material. According to the above-described thermal equilibrium control in the crucible, the deposition material may be deposited on the deposition target surface by efficiently providing energy to the deposition material.

Meanwhile, in controlling the thermal equilibrium in the crucible, thermal equilibrium at an upper surface of the crucible may be a problem. This is because, in an operation of the deposition apparatus, the most controversial issue is whether the deposition material, which received a sufficient quantity of heat from the upper portion of the crucible, is able to be smoothly discharged from the nozzle of the crucible and be deposited on the deposition target surface.

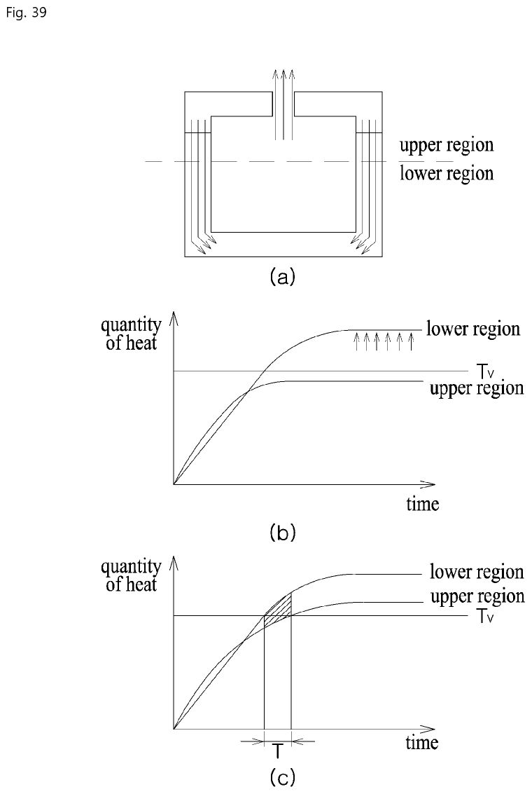

FIG. 39 is a view illustrating thermal equilibriums at an upper portion and a lower portion of a crucible according to an embodiment of the present application.

Referring to FIG. 39(a), regarding a quantity of heat generated at the upper portion of the crucible, (1) as the crucible is continuously heated, a large quantity of heat generated at the upper portion of the crucible may be conducted to the lower portion of the crucible and accumulated thereon, and (2) the large quantity of heat generated at the upper portion of the crucible may be discharged via the nozzle.

Since heat conduction continuously occurs at the lower portion and the upper portion of the crucible as described above, thermal equilibrium may be achieved at the lower portion and the upper portion of the crucible, with quantities of heat having different numerical values.

As illustrated in FIG. 39(b), a quantity of heat for achieving thermal equilibrium at the lower portion of the crucible may be larger than a quantity of heat for achieving thermal equilibrium that has been appropriately designed previously. Conversely, a quantity of heat for achieving thermal equilibrium at the upper portion of the crucible may be a quantity of heat smaller than the phase-change quantity of heat Tv of the deposition material since the quantity of heat at the upper portion is discharged to another space.

That is, even when the deposition material change phase and move by receiving a sufficient quantity of heat from the lower surface of the crucible, the deposition material may solidify or liquefy at the upper portion of the crucible at which the quantity of heat is smaller than the phase-change quantity of heat Tv of the deposition material. The solidified or liquefied deposition material may block the nozzle formed at the upper portion of the crucible, and thus a problem may occur in which the deposition material is unable to be smoothly discharged via the nozzle of the crucible.

Alternatively, as illustrated in FIG. 39(c), the above-described issue in that the nozzle of the crucible is blocked may occur even when thermal equilibrium is achieved in the crucible.

That is, although the deposition material at the lower surface of the crucible is able to change phase and move by receiving a sufficient quantity of heat in a T-section, since the quantity of heat at the upper surface of the crucible is smaller than the phase-change quantity of heat Tv of the deposition material, the deposition material may solidify or liquefy at the upper portion of the crucible. Accordingly, the problem occurs in which the solidified or liquefied deposition material blocks the nozzle formed at the upper portion of the crucible.

According to the thermal equilibrium achieved in the crucible, a configuration for addressing the problem in which the nozzle of the crucible is blocked may be disposed in the heating assembly.

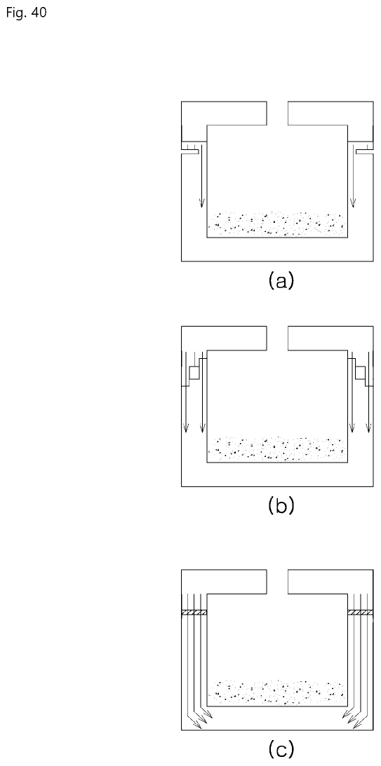

FIG. 40 is a view illustrating a heating assembly in which a heat conduction suppressing element is formed according to an embodiment of the present application.

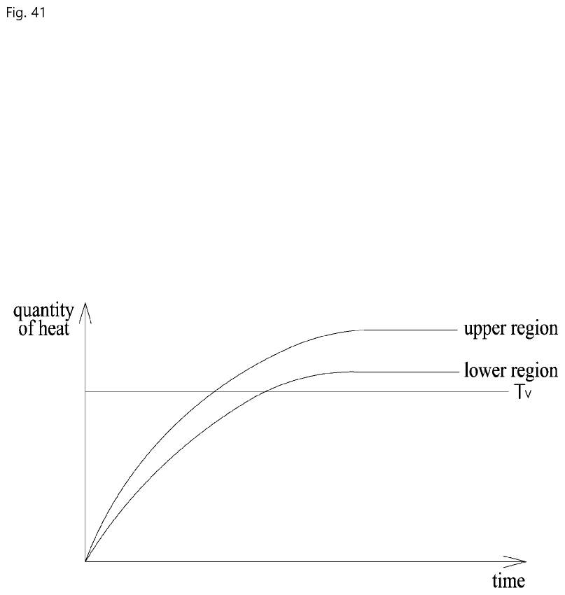

FIG. 41 is a graph showing thermal equilibrium controlled according to an embodiment of the present application.

In order to address the problem in which the nozzle is blocked, a heat conduction suppressing element may be formed in the heating assembly according to an embodiment of the present application.

A heat conduction suppressing configuration according to an embodiment of the present application may decrease a quantity of heat transferred from the upper portion of a crucible to the lower portion thereof. Accordingly, the quantity of heat accumulated on the lower surface of the crucible may decrease.

Referring to FIG. 40, a heat conduction suppressing configuration according to an embodiment of the present application may include a slit, a shielding space, an insulating material, or the like. However, the heat conduction suppressing configuration is not limited thereto and may include various other configurations.

Hereinafter, the heat conduction suppressing configuration will be described in detail.

Referring to FIG. 40(a), a slit may be formed in the outer wall of the crucible according to an embodiment of the present application.

By the slit being formed, a quantity of heat generated at the upper portion of the crucible is not able to be conducted to the lower portion of the crucible via the slit and is only able to be transferred to the lower portion of the crucible by radiation. That is, a path via which the heat accumulated on the upper portion of the crucible may be transferred to the lower portion of the crucible is reduced. As the heat transferred to the lower portion of the crucible is reduced, the quantity of heat accumulated on the lower portion of the crucible may be reduced.

The slit formed in the crucible may be preferably formed at a position in the vicinity of the structure configured to separate the crucible. However, embodiments are not limited thereto, and the slit may be formed in various other positions in the crucible. That is, a plurality of slits may be formed, and although, preferably, the plurality of slits may be formed in the vicinity of the structure configured to separate the crucible, the plurality of slits may be disposed in the outer wall of the crucible at various intervals.

Also, the slit may be designed in various shapes. Although a quadrangular slit may be formed in the crucible as illustrated, embodiments are not limited thereto, and the slit may be formed in various other shapes such as triangular, circular, elliptical, and rhombic. Also, the slit may be implemented to have various widths and lengths.

Also, the slit may be designed in various directions. The slit may be formed in a direction from an inner side of the crucible toward the outer surface thereof or may be formed in a direction from the outer side of the crucible to the inner surface thereof. Also, although the slit may be formed at an angle perpendicular to a surface of the crucible as illustrated, embodiments are not limited thereto, and the slit may be formed at various other angles.

Also, referring to FIG. 40(b), a shielding space may be formed at an inner portion of the outer wall of the crucible according to an embodiment of the present application. A quantity of heat generated at the upper portion of the crucible is not able to be conducted to the lower portion of the crucible via the shielding space formed at the inner portion of the outer wall of the crucible and is only able to be transferred to the lower portion of the crucible by radiation. That is, a path via which the heat accumulated on the upper portion of the crucible may be transferred to the lower portion of the crucible is reduced. As the heat transferred to the lower portion of the crucible is reduced, the quantity of heat accumulated on the lower portion of the crucible may be reduced.

The shielding space may be implemented in various forms at the inner portion of the outer wall of the crucible.

For example, referring to FIG. 40(b), the structure configured to separate the crucible may be formed so that, while the upper portion and the lower portion of the crucible fit well together when the upper portion and the lower portion of the crucible are assembled, the shielding space may be formed at the inner portion of the outer wall of the crucible. Accordingly, the shielding space may be implemented at the inner portion of the outer wall of the crucible.

The shielding space may be designed in various shapes. Although a quadrangular empty space may be formed in the crucible as illustrated, embodiments are not limited thereto, and the shielding space may be formed in various other shapes such as triangular, circular, elliptical, and rhombic.

The shielding space may be implemented to have various widths and lengths.

A plurality of shielding spaces may be present. The plurality of shielding spaces may be properly disposed at the inner portion of the outer wall of the crucible.

The above implementation example is merely an example, and embodiments are not limited thereto. Various other implementation examples in which the shielding space is formed at the outer wall of the crucible may be present.

Also, referring to FIG. 40(c), an insulating member capable of decreasing heat conduction may be formed at the outer wall of a crucible according to an embodiment of the present application. The insulating member decreases a quantity of heat conducted from the upper portion of the crucible to the lower portion thereof by being disposed therebetween. As the quantity of heat conducted to the lower portion of the crucible is reduced, the quantity of heat accumulated on the lower portion of the crucible may be reduced.

The insulating member may be implemented in various forms at the outer wall of the crucible.

For example, referring to FIG. 40(c), the insulating member may be implemented in a form of being inserted between the upper portion of the crucible and the lower portion of the crucible, wherein the crucible is divided on the basis of the structure configured to separate the crucible.

The insulating member may be designed in various shapes. Although a quadrangular member may be implemented in a form of being inserted into the outer wall of the crucible as illustrated, embodiments are not limited thereto, and the insulating member may be formed in various other shapes such as triangular, circular, elliptical, and rhombic.

A material with low heat conductivity may be selected as a material of the insulating member, and a material having a melting point that allows the insulating member to function without melting even when a quantity of heat in the heating assembly is at a high temperature may be selected.

The insulating member may be implemented to have various widths and lengths.

A plurality of insulating members may be present. The plurality of insulating members may be properly disposed at the inner portion of the outer wall of the crucible.

The above implementation example is merely an example, and embodiments are not limited thereto. Various other implementation examples in which the insulating member is formed at the outer wall of the crucible may be present.

Also, a heating assembly may be designed so that a quantity of heat is smoothly discharged from the lower surface of a crucible according to an embodiment of the present application.

For example, a heat dissipating fin, a heat dissipating body, or the like may be disposed at the lower surface of the crucible, or a heat dissipating paint may be applied on the lower surface of the crucible. Since the heat dissipating means have extremely high heat conductivity, a quantity of heat may be smoothly conducted. That is, a quantity of heat accumulated at the lower portion of the crucible may be smoothly discharged via the heat dissipating means implemented at the lower surface of the crucible.

Alternatively, by implementing the lower surface of the crucible to have a large surface area, a quantity of heat may be smoothly discharged via the large surface area. For example, the lower surface of the crucible may be implemented to be rough. The lower surface of the crucible that is implemented to be rough may have a larger surface area than the lower surface of the crucible that is implemented to be smooth.

Alternatively, a black body may be formed at an inner surface of the housing that is opposite to the lower surface of the crucible. The black body may absorb radiant heat radiated therearound. Accordingly, radiant heat discharged from the lower portion of the crucible via the inner surface of the housing may be absorbed into the black body, and the radiant heat may be smoothly discharged via the housing.

Meanwhile, the present invention is not limited to the embodiments described above, and there may be a method of controlling a heat distribution in a crucible over time. The method may be practiced by combining the embodiments described above related to maintaining a heat distribution in the crucible.

Referring to FIG. 41, thermal equilibrium in each region of the crucible may be appropriately controlled according to the above-described implementation example in which a quantity of heat conducted to the lower surface and the upper surface of the crucible is controlled. At the lower portion of the crucible, thermal equilibrium may be achieved with a quantity of heat that is moderately larger than the phase-change quantity of heat Tv of the deposition material. Meanwhile, at the upper portion of the crucible, thermal equilibrium may be achieved with a quantity of heat that is not only larger than the phase-change quantity of heat Tv of the deposition material but also larger than the quantity of heat at the lower portion of the crucible.

Accordingly, the crucible according to an embodiment of the present application is controlled so that, not only the effect of addressing the above-mentioned problem in which the nozzle is blocked is achieved, but also thermal equilibrium is achieved that allows the deposition material to be smoothly discharged from the upper portion of the crucible.

A transformer or a current transformer of a deposition apparatus 10000 and a disposition example of the transformer or the current transformer will be described below.

### 5. Transformer or Current Transformer

Hereinafter, a transformer or a current transformer according to an embodiment of the present application will be described.

In order to drive a coil of a heating assembly according to the present application, the transformer and/or the current transformer may output a high-frequency voltage or current whose direction and intensity change over time. For example, the transformer and/or the current transformer may receive direct-current (DC) power, convert the received DC power to AC power, and apply the AC power to the coil.

That is, the transformer or the current transformer is an apparatus that is essential in order to drive the deposition apparatus according to the present application. Hereinafter, for convenience of description, the transformer, among the transformer and the current transformer, will be described as an example.

Also, current of power applied to the coil by the transformer according to some embodiments of the present application may have a relatively higher value than current of DC power provided to the transformer. That is, power output by the transformer may have extremely high current. This is to heat the crucible by increasing a current value of induction current in the deposition apparatus according to embodiments of the present application that utilizes induction current whose direction and intensity suddenly changes over time at the outer wall of the crucible.

A conductive wire (hereinafter referred to as “output wire 19120”) for applying the high current to the coil and a conductive wire (hereinafter referred to as “input wire 19110”) for supplying external DT power to the transformer may be included in the transformer. Power output from the transformer may be provided to the coil via the output wire 19120. The DC power input to the transformer may be provided to the transformer via the input wire 19110.

However, as described above, high current may flow through the output wire 19120. In this case, the high current may combine with a resistance component of the output wire 19120 and generate heat such that a high heat emission phenomenon occurs in the output wire 19120. Accordingly, when the output wire 19120 is used in the deposition apparatus according to an embodiment of the present application, a problem may occur in which the output wire 19120 is broken. Therefore, in order to prevent the breakage of the output wire 19120, there is a need to suppress the high heat emission phenomenon, and accordingly, the output wire 19120 of the transformer is formed to have a large thickness in order to further decrease a resistance value of the output wire 19120.

Conversely, there is no need to further decrease a resistance value of the input wire 19110. Accordingly, since there is no need to implement the input wire 19110 to have a large thickness with high cost, the input wire 19110 is formed to be relatively thinner than the output wire 19120.

The transformer may be disposed in various spaces. This will be described below.

A space according to an embodiment of the present application may be separated into an outer space and an inner space. The outer space is a space differentiated from the inner space in which the deposition target surface, the heating assembly, and the like of the present application are disposed. The inner space may have a vacuum environment attribute. This is to eliminate impurities that may affect the process in which the phase-changed deposition material is deposited on the deposition target surface using the heating assembly. Since there is no need to eliminate impurities from the outer space differentiated from the inner space, unlike the inner space, the outer space is a space having a general air pressure attribute.

In the inner space of the deposition apparatus, the heating assembly and/or the deposition target surface move relative to each other such that a deposition operation is performed. The deposition operation refers to an operational process in which the deposition material is formed on the deposition target surface. The relative movement may refer to movement of the deposition target surface while the heating assembly is fixed, simultaneous movement of the deposition target surface and the heating assembly while velocities thereof are different, or movement of the heating assembly while the deposition target surface is fixed.

A transformer according to an embodiment of the present application may be disposed to be fixed to the outer space of a deposition apparatus.

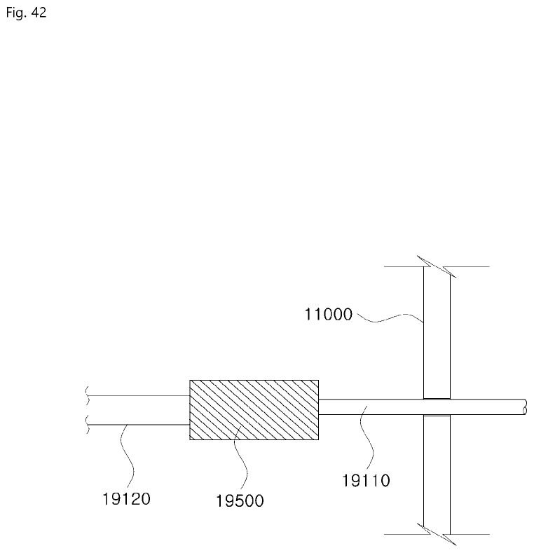

FIG. 42 is a view illustrating a transformer, an input wire, and an output wire in an outer space according to an embodiment of the present application.

Referring to FIG. 42, the transformer fixed to the outer space may supply AC power to a coil implemented in the inner space. The transformer fixed to the outer space may receive DC power generated by a DC power generation source included in the outer space via the input wire 19110. The transformer may convert the received DC power to high-frequency AC power. The high-frequency AC power is applied to the output wire 19120 of the transformer, and the output wire 19120 is connected to the coil via a partition or an outer wall that differentiates the outer space and the inner space from each other. In this way, the transformer provides the AC power to the coil via the output wire 19120.

When the transformer is disposed to be fixed to the outer space as described above, some problems may occur.

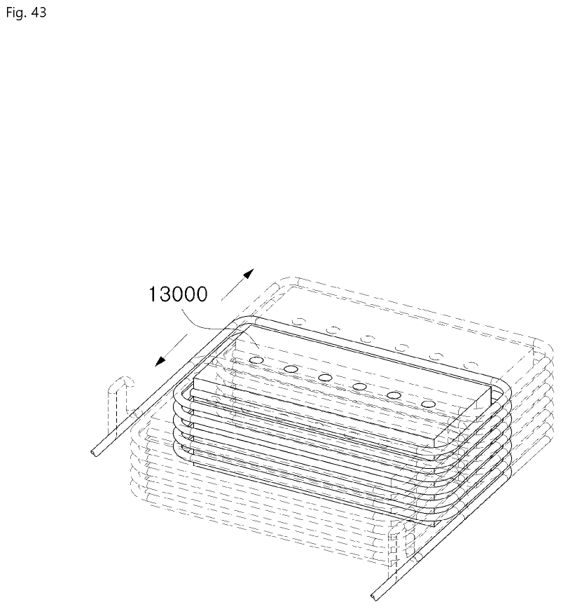

FIG. 43 is a view illustrating a moving heating assembly according to an embodiment of the present application.

Referring to FIG. 43, when the transformer is disposed in the outer space, a problem in that the output wire 19120 of the transformer is broken may also occur. Since the transformer is disposed to be fixed to the outer space, when the heating assembly moves as the deposition operation is performed in the inner space, the output wire 19120 connected to the coil may be deformed such as being extended or bent. The above-described output wire 19120 may wear out due to being continuously deformed due to the continued deposition operation. Due to the output wire 19120 being worn out continuously, a problem in that the output wire 19120 is broken may occur.

Meanwhile, to address the problem, a mover configured to move the transformer disposed in the outer space corresponding to movement of the heating assembly may be disposed in the outer space.

Even when the mover is disposed, referring back to FIG. 42, when the transformer is disposed in the outer space, a problem in that it is difficult to implement the outer wall that differentiates the inner space and the outer space from each other may also occur.

A structure in which the output wire 19120 may be disposed from the outer space to the inner space should be formed at the outer wall that differentiates the inner space and the outer space from each other. Meanwhile, the structure of the outer wall should be formed to be able to maintain the vacuum environment attribute of the inner space. However, the structure should be formed as a through-structure in which the outer space and the inner space communicate with each other and the output wire 19120 may be disposed from the outer space to the inner space, and the size of the through-structure should be selected in consideration of the output wire 19120 which is formed to have a large thickness as described above. Therefore, it is very difficult to implement in the outer wall a structure through which the output wire 19120 may pass while the vacuum environment attribute of the inner space is not eliminated.

Accordingly, implementing the mover, another driver for driving the mover, a power generation source, and through-structures of the outer wall in the outer space may cause a cost problem.

In order to address the above-described problems, some embodiments of the present application disclose a deposition apparatus in which: 1) a transformer according to the present application is disposed inside the deposition apparatus; and 2) a relative positional relationship between the crucible (heating assembly) and the transformer may be fixed.

In order to implement a deposition apparatus according to an embodiment of the present application, the transformer may be fixed to one side of the heating assembly.

In this way, the transformer may be installed inside the deposition apparatus together with the heating assembly while the positional relationship between the heating assembly and the transformer may be fixed. That is, when the heating assembly moves inside the deposition apparatus in order to implement movements of the heating assembly and the deposition target surface relative to each other, the transformer may move together according to the movement of the heating assembly.

In this case, since the positions of the transformer and the heating assembly relative to each other are fixed, the problem in which the output wire 19120 is broken does not occur anymore.

Meanwhile, since there is no problem in terms of implementing power, which is for supplying DC power to the transformer, to have flexibility, the problem in which the input wire 19110 is broken due to movement of the transformer may hardly occur.

However, in another embodiment, it is not essential for the transformer and the heating assembly to be fixed to each other.

For example, the deposition apparatus may be implemented so that, as the heating assembly moves, the transformer also moves in synchronization with the heating assembly. To this end, a driver which is separately configured from a driver for movement of the heating assembly may be included in the deposition apparatus.

Also, even when the transformer is disposed in the inner space, some little problems may remain. When the transformer is disposed in a high-vacuum environment, which is the inner space, a problem in that the vacuum environment is damaged due to the movement of the transformer may occur.

Therefore, according to some other embodiments of the present application, the deposition apparatus may further include a separate vacuum box for allowing the transformer to be disposed in the inner space.

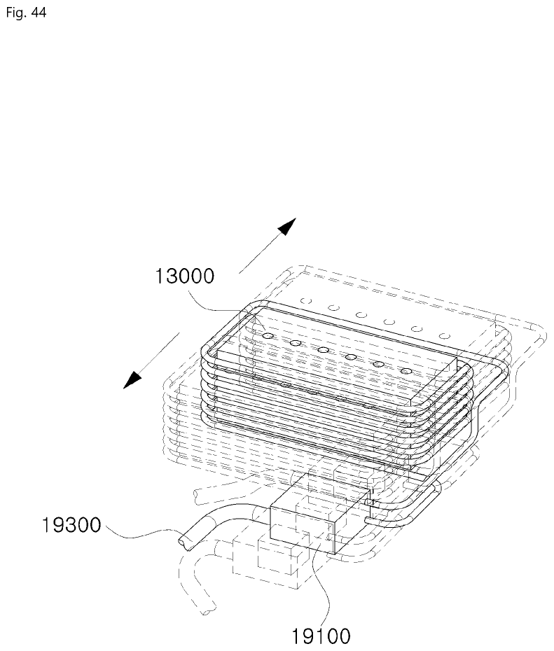

FIG. 44 is a view illustrating a transformer, a vacuum box, and a heating assembly according to an embodiment of the present application.

Referring to FIG. 44, the vacuum box in which the transformer is disposed may receive power from the driver included and move in synchronization with the heating assembly. Accordingly, since an inner space of the box is separated from the vacuum environment, the problem in that the coil is broken when the heating assembly moves as well as the problem in that the vacuum environment is damaged when the transformer moves may not occur.

Hereinafter, a deposition apparatus according to some embodiments of the present application will be described in detail below.

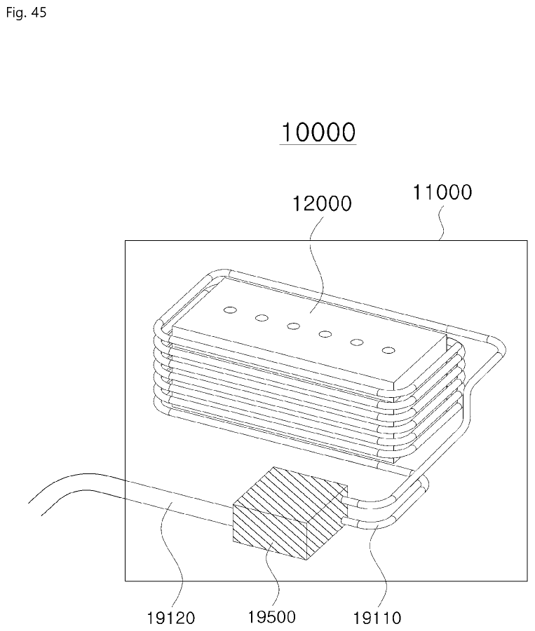

FIG. 45 is a view illustrating a deposition apparatus according to an embodiment of the present application.

Referring to FIG. 45, a deposition apparatus according to some embodiments of the present application may include a housing, a heating assembly, and a transformer.

The housing may provide a space in which configurations related to deposition may be implemented. The heating assembly, the transformer, and the like may be disposed in the space. The housing may have an outer wall with high sealability that is capable of differentiating an inner space and an outer space of the housing from each other. Thus, the housing may maintain the inner space of the housing in a high-vacuum environment state.

The heating assembly may heat the deposition material placed in the crucible by using a coil, thereby changing a phase of the deposition material and allowing the phase-changed deposition material to be deposited on the deposition target surface.

Although the heating assembly may have the above-described configuration of the heating assembly according to some embodiments of the present application, the heating assembly is not necessarily limited thereto.

The transformer may be disposed inside the housing and, as described above, may be fixed to one side of the heating assembly.

The transformer will be described in more detail below.

Since the output wire 19120 disposed in the transformer has a high stiffness as described above, the output wire 19120 may be connected to the coil while having a fixed shape. Also, since the transformer is present by being fixed to one side of the heating assembly, the output wire 19120 may also be connected to the coil such that, even while deposition of the deposition material is performed, the fixed shape is hardly changed.

Meanwhile, the input wire 19110 disposed in the transformer may extend from the transformer and be connected to external DC power in the outer space via a through-hole formed in the outer wall of the housing.

Since, as described above, relatively less power is applied to the input wire 19110 than to the output wire 19120, for the input wire 19110, it is not required to separately implement a thick conductive wire as for the output wire 19120, and a conductive wire disposed inside the housing may serve as the input wire 19110. Even when a conductive wire disposed in advance is not used as the input wire 19110, the input wire 19110 having a small thickness may be disposed in the housing via a small through-hole formed in advance. Also, corresponding to the case in which the transformer moves, the input wire 19110 may be implemented to have a long length.

In addition to being relatively easier to implement than the output wire 19120, since the input wire 19110 is more flexible than the output wire 19120 as described above, unlike the output wire 19120, the input wire 19110 may hardly cause a problem due to breakage.

Also, when the heating assembly moves by the driver as described above, the driver may be separately disposed, and the transformer may also move with the positional relationship of being fixed to one side of the heating assembly.

Hereinafter, a deposition apparatus including a vacuum box according to an embodiment of the present application will be described.

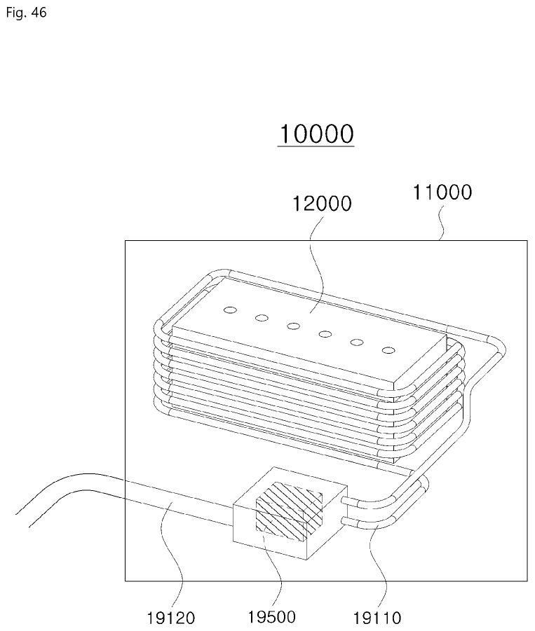

FIG. 46 is a view illustrating a deposition apparatus according to an embodiment of the present application.

Referring to FIG. 46, a deposition apparatus according to some embodiments of the present application may include a housing, a heating assembly, a transformer, and a vacuum box.

Repeated description of configurations which have been described above will be omitted.

The vacuum box may form a space therein. The space of the vacuum box may be a vacuum environment which is the same as the environment inside the housing.

Also, the vacuum box may include various kinds of drivers, conductive wires, connecting members, or the like.

According to the present embodiment, since movement of the transformer may destroy the vacuum environment inside the housing, the transformer may be disposed in the inner space of the vacuum box.

The output wire 19120 of the transformer may extend via a through-hole implemented in the vacuum box and be connected to the coil.

Alternatively, a bellows or an arm-shaped connecting member having a high stiffness corresponding to the stiffness of the output wire 19120 may be included in the vacuum box and allow the output wire 19120 to be connected to the coil. The connecting member may be implemented in a form of extending to the coil, and the output wire 19120 may be connected to the coil via the connecting member.

The input wire 19110 of the transformer may also extend via the through-hole implemented in the vacuum box and be connected to external power via the through-hole in the outer wall of the housing.

Alternatively, a connecting member having a low stiffness corresponding to the stiffness of the input wire 19110 may be disposed in the vacuum box and allow the input wire 19110 to communicate with the outer space. The connecting member may be implemented to have a sufficient length corresponding to movement of the heating assembly. Also, the connecting member may flexibly move due to having a low stiffness.

Therefore, the connecting member disposed in the vacuum box may have an inner space formed therein for a conductive wire to be disposed therein.

Also, when the heating assembly moves by the driver as described above, the driver may be separately disposed, and the vacuum box including the transformer may also move with the positional relationship of being fixed to one side of the heating assembly.

<Heating Assembly Including Plurality of Detachable Sub-Crucibles>

According to an aspect of the present invention, a heating assembly for depositing a material on a deposition target surface may be provided, the heating assembly comprising: a heating container including an outer wall configured to define an inner space, wherein the outer wall includes an upper portion and a lower portion, and a separating structure is formed at the outer wall to separate the upper portion and the lower portion from each other; a coil configured to form an induction current at the outer wall so as to heat the heating container; a power generator including a power supply wire for supplying power to the coil; and a coil connecting member configured to electrically connect the coil and the power generator to each other, wherein the coil includes a first coil and a second coil, the coil connecting member includes a first coil connecting member and a second coil connecting member, the power supply wire includes a first power supply wire and a second power supply wire, the first coil has a first positional relationship with the heating container, the second coil has a second positional relationship with the heating container, the first coil connecting member is connected to one side of the first coil, one side of the second coil, and the first power supply wire, the second coil connecting member is connected to the other side of the first coil and the other side of the second coil, an electrical detaching structure is formed between the first coil connecting member and at least one of the one side of the first coil, the one side of the second coil, or the first power supply wire, and an electrical detaching structure is formed between the second coil connecting member and at least one of the other side of the first coil or the other side of the second coil.

According to another aspect of the present invention, a heating assembly is provided, the heating assembly comprising: a heating container including an outer wall configured to define an inner space in which a deposition material is placed; a coil configured to form an induction current at the outer wall so as to heat the heating container; a power generator configured to generate driving power for driving the coil; and a coil connecting member configured to electrically connect the coil and the power generator to each other, wherein the outer wall of the heating container includes a first region and a second region, a separating structure is formed between the first region and the second region, the coil includes a first coil and a second coil, the first coil has a first positional relationship with the heating container, the second coil has a second positional relationship with the heating container, the coil connecting member includes a first coil connecting member and a second coil connecting member, and the first coil connecting member is electrically connected to one side of the first coil.

Also, an electrical detaching structure may be formed between the first coil connecting member and the first coil.

Also, a protruding nozzle may be formed in the first region of the heating container, the coil may include the first coil and the second coil, the first coil may be disposed near the protruding nozzle of the heating container, and the second coil may be disposed near the second region of the heating container.

Also, the power generator may further include a power supply wire, wherein the power supply wire may include a first power supply wire and a second power supply wire, and the first power supply wire may be connected to the first coil connecting member and the first coil.

Also, the second power supply wire may be connected to the second coil, and the second coil connecting member may be connected to the second coil.

Also, a physical shape of the first coil connecting member and a physical shape of the second coil connecting member may be different from each other.

Also, when the power generator generates power, a first driving power may be applied to the first coil, and a second driving power may be applied to the second coil, wherein the first driving power and the second driving power may be generated substantially simultaneously.

Also, an electrical attribute of the first driving power and an electrical attribute of the second driving power may be different from each other.

Hereinafter, a heating assembly according to an embodiment of the present invention will be described.

Thin film manufacturing technology is a field of surface treatment technology and is classified into wet methods and dry methods.

Among the thin film manufacturing technologies, thin film manufacturing technologies using wet methods include: (1) an electrolytic method in which an object to be processed is electrolyzed by being placed at a positive electrode in order to oxidize the object to be processed so that a processing object is formed on a surface of the object to be processed; and (2) an electroless method using activation and sensitization processes on an object to be processed.

Thin film manufacturing technologies using dry methods include: (1) a physical vapor deposition (PVD) method in which a solid-phase processing object is evaporated in a high vacuum state so that the processing object is formed on a surface of an object to be processed; (2) a chemical vapor deposition (CVD) method in which a gas-phase processing object is changed to a plasma phase or the like in a high vacuum state so that the processing object is formed on a surface of an object to be processed; and (3) a spraying method in which a liquid-phase object to be processed is ejected to a surface of a processing object so that the object to be processed is coated on the surface of the processing object.

In the above-described thin film manufacturing technologies, a deposition apparatus 10000 which is implemented to heat a processing object (particularly, a deposition material) so that a phase of the processing object is changed and to guide the processing object to come into contact with a surface of an object to be processed may be important.

Therefore, a deposition apparatus 10000 according to the present invention will be described below.

### 1. Deposition Apparatus

Hereinafter, a deposition apparatus 10000 according to an embodiment of the present application will be described.

A deposition apparatus 10000 according to an embodiment of the present application is an apparatus capable of depositing a deposition material on a deposition target surface. A deposition apparatus 10000 according to the present application may increase a temperature of a crucible 13000 of a deposition apparatus 10000 using a predetermined heating means 15000 and change a phase of a deposition material contained in a crucible 13000. The phase-changed deposition material may be discharged to an outside of a crucible 13000.

A deposition apparatus 10000 according to an embodiment of the present application may be used for the above-described thin film manufacturing technologies. Furthermore, a deposition apparatus 10000 may also be used for simple heating instead of being used deposition according to the above-described thin film manufacturing technologies.

A configuration of a deposition apparatus 10000 will be described below.

1.1 Configuration of Deposition Apparatus

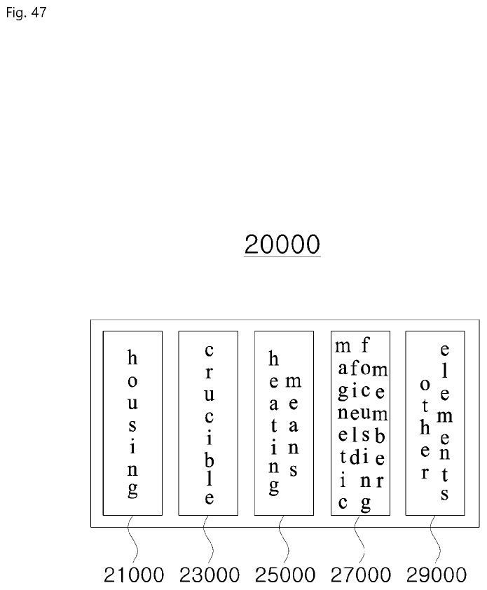

FIG. 47 is a block diagram illustrating a configuration of a deposition apparatus according to an embodiment of the present application.

Referring to FIG. 47, a deposition apparatus 20000 according to an embodiment of the present application may include a housing 21000, a crucible 23000, a heating means 25000, a magnetic field focusing member 27000, which is a heating aid, and other elements 29000.

A space may be formed inside the housing 21000 according to an embodiment of the present application. The crucible 23000, the heating means 25000, the heating aid, and the other elements 29000 may be implemented in the inner space of the housing 21000.

A deposition material, which is material to be deposited, may be provided in a space formed inside the crucible 23000 according to an embodiment of the present application. Also, the deposition material may be heated by receiving heat generated by the heating means 25000.

Various kinds of materials may be selected as a deposition material placed in the inner space of a crucible 23000.

The deposition material may be an organic material. The organic material refers to a compound based on carbon. The organic material may include: i) natural organic matter such as amino acid, protein, carbohydrate, penicillin, amoxicillin, and the like that may be obtained from animals or plants; ii) synthetic organic matter such as plastic artificially made by human beings; and iii) combinations of the above-mentioned organic matters. In the present application, the crucible 23000 may be heated to about 200° C. so that the organic material reaches a freely movable state.

Also, the deposition material may be a metal material. The metal material may include magnesium (Mg), silver (Ag), aluminum (Al), and the like. In the present application, the crucible 23000 may be heated to 1,000° C. or higher so that the metal material reaches a freely movable state.

The heating means 25000 according to an embodiment of the present application may heat the crucible 23000 in order to change a phase of a deposition material placed inside the crucible 23000.

The heating aid according to an embodiment of the present application may aid the heating means 25000 in efficiently heating the crucible 23000. An example of the heating aid may include the magnetic field focusing member 27000.

The other elements 29000 according to an embodiment of the present application may include a passage of a conductive wire that is capable of supplying power, a power generation apparatus capable of providing power to the deposition apparatus 20000, or the like. However, in order to facilitate description, description on the other elements 29000 will be omitted herein. The deposition apparatus 20000 will be described along with the other elements 29000 only under special circumstances that require description of the deposition apparatus 20000 using the other elements 29000.

Meanwhile, the configurations of the aforementioned deposition apparatus 20000 including a crucible 23000, a heating means 25000, a magnetic field focusing member 27000, and/or other configurations that may be implemented may be collectively referred to as a heating assembly.

A heating assembly will be described in more detail below.

1.1.1 Crucible

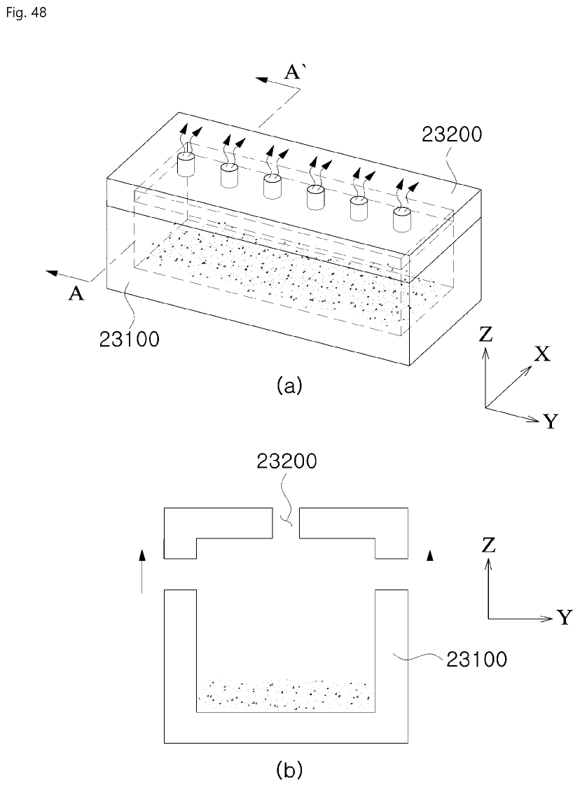

FIGS. 48(a) and (b) are views illustrating a crucible according to an embodiment of the present application.

A crucible 23000 according to an embodiment of the present application may include an outer wall 23100 and at least one or more nozzles 23200.

As illustrated in FIG. 48(b), an outer wall 23100 according to an embodiment of the present application may define a space inside a crucible 23000 (hereinafter referred to as “an inner space”). A deposition material to be deposited may be placed in the inner space.

A nozzle 23200 according to an embodiment of the present application may be a movement path of a deposition material. A deposition material placed in an inner space of the crucible 23000 may be phase-changed to a gas phase and/or a plasma phase by receiving a sufficient quantity of heat from a heating means 25000. The phase-changed deposition material may be discharged to an outside of a crucible 23000 via the nozzle 23200 as illustrated in FIG. 48(a).

The nozzle 23200 according to an embodiment of the present application may be formed with various design specifications in the crucible 23000.

For example, when a plurality of nozzles 23200 are formed, the plurality of nozzles 23200 may be formed at various intervals. The plurality of nozzles 23200 may be formed at equal intervals. Alternatively, the nozzles 23200 may be formed at intervals that gradually narrow toward a side of a surface of the crucible.

Also, a hole of the nozzle 23200 may have various shapes. The hole of the nozzle may be implemented in a circular shape as illustrated or may also be implemented in various other shapes such as quadrangular and elliptical.

Hereinafter, a crucible 23000 according to the present application will be described in more detail. In this case, for convenience of description, one surface on which the nozzle 23200 is formed will be referred to as an upper surface, a surface opposing the one surface will be referred to as a lower surface, and surfaces other than the upper surface and the lower surface will be referred to as “side surfaces.”

A crucible 23000 according to an embodiment of the present application may have various shapes. For example, referring to FIG. 48(a), a crucible 23000 may have a rectangular parallelepiped shape. Furthermore, a crucible 23000 according to the present application may be implemented in various other forms such as conical, spherical, hexagonal prismatic, cylindrical, and triangular prismatic. That is, a crucible 23000 according to an embodiment of the present application may be implemented in any form as long as the form is capable of containing a deposition material.

Also, according to an embodiment of the present application, various materials may be used in implementing the crucible.

The material of the crucible is not limited to any material, but preferably, the material constituting the crucible 23000 according to the present application may be a material having a property of allowing current to flow well therethrough.

Also, the material constituting the crucible 23000 may be selected in consideration of a temperature at which the crucible 23000 is heated by the heating means 25000. That is, the material of the crucible 23000 may be selected so that the crucible 23000 can function without melting even at a high temperature.

As illustrated in FIG. 48(b), in a crucible 23000 according to an embodiment of the present application, a structure capable of opening and closing a crucible 23000 may be formed.

A nozzle 23200 according to an embodiment of the present application may be implemented in a protruding shape that has a predetermined length toward an outside of the crucible 23000 (hereinafter referred to as “a protruding nozzle 23300”).

Such a protruding nozzle 23300 may be formed with various shapes and materials in the crucible 23000.

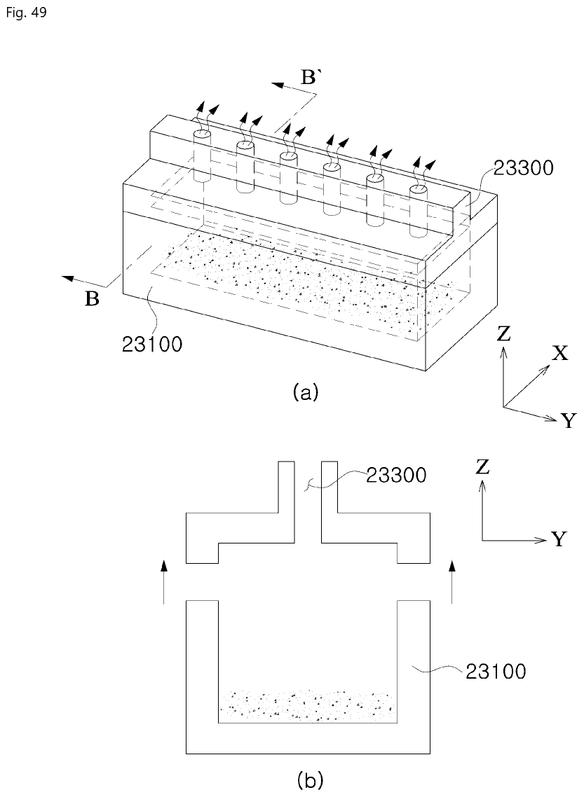

FIG. 49 is a view illustrating a protruding nozzle formed in a crucible according to an embodiment of the present application.

Referring to FIG. 49, as illustrated, the protruding nozzle 23300 may be formed in a rectangular parallelepiped shape. Also, for example, the shape of the protruding nozzle 23300 is not limited to the illustrated shape and may also be other shapes such as cylindrical, triangular prismatic, and conical.

Also, various materials may be selected to implement the protruding nozzle 23300. For example, the material of the protruding nozzle 23300 may be selected in consideration of the issue in which binding between the crucible 23000 and the protruding nozzle 23300 becomes unstable due to thermal expansion of the crucible 23000 upon heating of the crucible 23000. That is, the material of the protruding nozzle 23300 may be the same as that of the crucible 23000 so that the above issue does not occur since the materials of the protruding nozzle 23300 and the crucible 23000 have the same thermal expansion coefficient.

A heating assembly may be designed so that a deposition material is smoothly discharged via a protruding nozzle according to an embodiment of the present application.

For example, various materials may be selected as a material constituting a protruding nozzle according to an embodiment of the present application. A material having a property of low adhesiveness to the deposition material may be selected as a material constituting an inner surface of a passage of the protruding nozzle. Since adhesiveness between the passage of the protruding nozzle and the deposition material becomes low, a deposition material may move through the internal passage of a protruding nozzle without being adhered to a protruding nozzle and be smoothly discharged to the outside.

Also, a protruding nozzle according to an embodiment of the present application may be implemented in various shapes.

The internal passage of the protruding nozzle may have various shapes. For example, the internal passage of the protruding nozzle may be implemented to have a predetermined inclination.

1.1.2 Heating Means

A deposition apparatus 20000 according to an embodiment of the present application may include a heating means 25000 capable of increasing a temperature of a crucible 23000.

The heating means 25000 may be implemented in various forms. For example, a heating means 25000 according to an embodiment of the present application may be: (1) a traditional heating means 25000 such as a pipe capable of supplying thermal vapor and a heating device using fossil fuels; or (2) the latest heating means 25000 such as a sputtering heating source that heats a target material through momentum transfer by ions or the like, an arc heating source that performs heating by an arc, and a resistance heating source that performs heating on the basis of an electrical resistance such as a conductive wire.

However, preferably, a coil 26000 may be selected as a heating means 25000 according to the present application. The coil 26000 may form therearound a dynamic magnetic field that varies temporally and spatially, on the basis of the high-frequency coil current flowing through a coil 26000. As a result, a magnetic field formed around the coil 26000 may induce current to a crucible 23000 and generate a quantity of heat in the crucible 23000, thereby heating the crucible 23000. An operation in which the crucible 26000 is heated by the coil will be described in detail below.

Hereinafter, a coil 26000 will be described in more detail.

The coil 26000 according to an embodiment of the present application may be implemented with various materials through which current may flow. For example, preferably, a conductor may be selected as a material constituting the coil 26000. The conductor may include a metal body, a semiconductor, a superconductor, a plasma, graphite, a conductive polymer, and the like. However, the material is not limited thereto, and various other materials may be selected as the material constituting the coil.

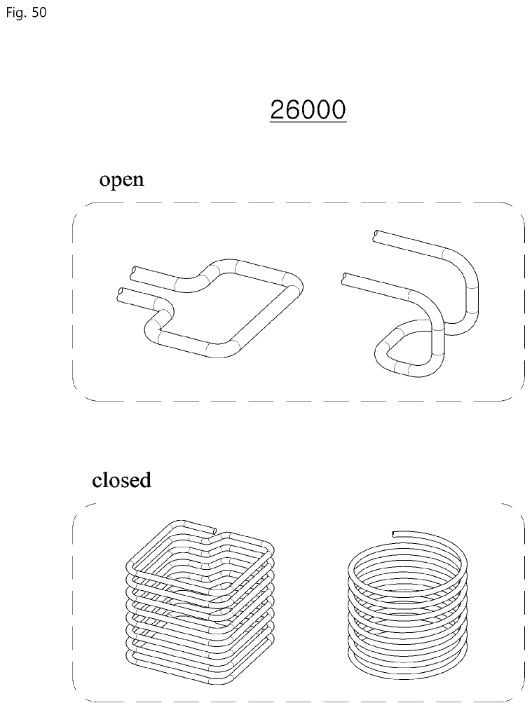

FIG. 50 is a view illustrating the shape of a coil according to an embodiment of the present application.

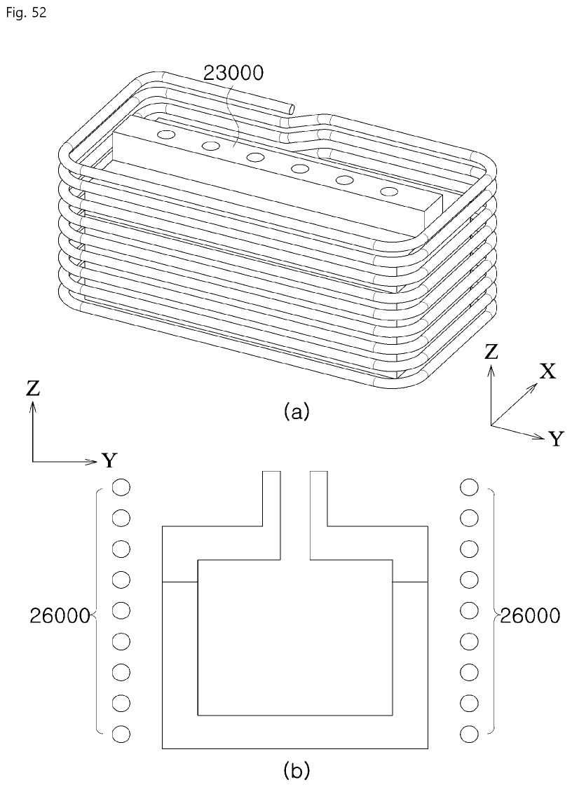

Referring to FIG. 50, a coil 26000 according to an embodiment of the present application may have various shapes. For example, the shape of the coil 26000 may include: (1) an open shape implemented as a single loop having a disc shape or a ring shape; and (2) a closed shape formed with a plurality of loops that constitute a hollow cylindrical shape. The shape of the coil 26000 is not limited to that illustrated in FIG. 52, and the coil 26000 may be implemented in any other shape as long as the shape is capable of generating a magnetic field.

Hereinafter, for convenience of description, a portion at which a plurality of windings constituting the coil 26000 are visible will be referred to as a side portion of a closed shape and a portion of a closed-shape coil 26000 that has a circular or quadrangular hole will be referred to as an upper portion or a lower portion of a coil 26000. The definitions related to the structure of a coil 26000 as described above may also apply to an open-shape coil 26000.

Windings through which current flows that constitute a coil 26000 according to an embodiment of the present application may have various forms. For example, a winding may be implemented in various outer shapes to have various shapes such as a round shape and a rectangular shape

Also, for example, the thickness of a winding may vary depending on the purpose.

Meanwhile, an empty space may be formed at an inner side of a winding constituting a coil 26000 according to an embodiment of the present application. For example, an empty space may be formed at an inner sides of a winding constituting the coil 26000 so that a fluid such as water that may serve as coolant flows through the empty space. The fluid flowing along the coil 26000 may have an effect of controlling a temperature of a coil 26000 so that the temperature does not rise above a predetermined temperature.

An aspect in which a coil 26000 according to an embodiment of the present application is disposed may vary depending on the shape of the coil.

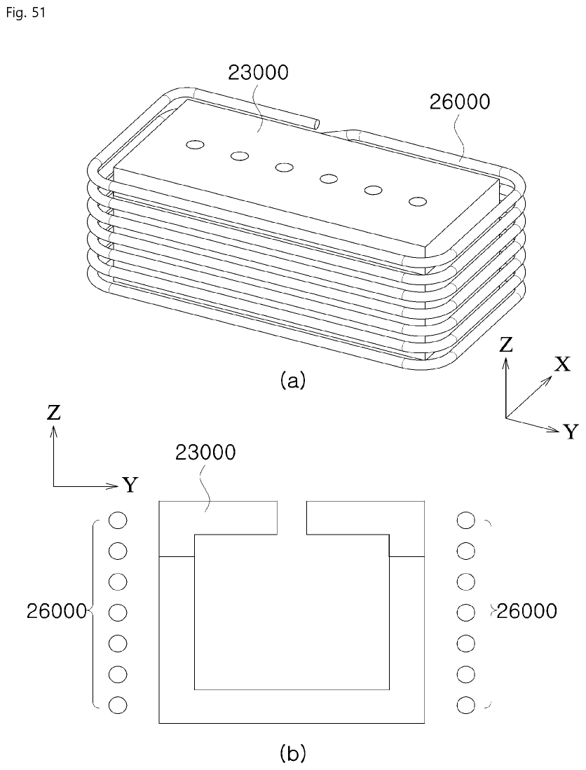

FIG. 51 is a view illustrating a crucible and a coil according to an embodiment of the present application.

Referring to FIG. 51, as one aspect in which a coil 26000 according to an embodiment of the present application is disposed, when the coil 26000 has a closed shape, the coil 26000 may be disposed so that the crucible 23000 is disposed at an inner side of the closed-shape coil 26000. Also, for example, other than the above-described disposition aspect, the closed-shape coil 26000 may be disposed so that an upper portion or a lower portion of the coil 26000 is disposed at an upper portion, a side portion, and/or a lower portion of the crucible 23000. Also, when the coil 26000 is the open-shape coil 26000, the above-described aspect in which the closed-shape coil 26000 is disposed may be applied, or, in the case of the open-shape coil 26000 formed of a single loop, the coil 26000 may be disposed in the crucible 23000 in the form in which the upper portion or the lower portion of the coil 26000 is folded.

Also, a coil 26000 according to an embodiment of the present application may be disposed corresponding to a structure and/or means in which the crucible 23000 is formed.

FIG. 52 is a view illustrating an example in which a coil according to an embodiment of the present application is implemented.

Referring to FIG. 52, when a nozzle 23200 is implemented to protrude from a crucible 23000, as illustrated, the coil 26000 may be disposed by being lifted up to a position corresponding to a protruding nozzle 23300. When the deposition material passing through the protruding nozzle 23300 is unable to receive a sufficient quantity of heat, the deposition material is unable to smoothly move through a passage of the protruding nozzle 23300. Therefore, when the coil is disposed around the protruding nozzle 23300 as described above, the coil 26000 may supply a sufficient quantity of heat so that the deposition material moving through the passage of the protruding nozzle 23300 can smoothly move to a deposition target surface.

A heating assembly 22000 according to an embodiment of the present application may include a first coil 26010 and a second coil 26020.

The first coil 26010 and the second coil 26020 may be present in a state of being separated from each other, but may also be connected to each other electrically or physically. For convenience of description, description will be given below by assuming that the first coil 26010 and the second coil 26020 are connected to each other.

The number of windings of the first coil 26010 and the number of windings of the second coil 26020 may be selected so that the number of windings of the first coil 26010 and the number of windings of the second coil 26020 are different from each other. For example, the number of windings of the second coil 26020 may be larger than the number of windings of the first coil 26010. A coil magnetic field and induction current formed in the crucible 23000 which are on the basis of the number of windings of the first coil 26010 and the second coil 26020 will be described in detail below.

The forms in which the first coil 26010 and the second coil 26020 are implemented may be different from each other. The above-described inner path may not be formed in at least one of the first coil 26010 and the second coil 26020. That is, while the above-described inner path through which a fluid may flow may be formed at an inner portion of the second coil 26020, the inner path may not be formed at an inner portion of the first coil 26010. This is to facilitate physical separation between the first coil 26010 and the second coil 26020 when the first coil 26010 and the second coil 26020 are physically separated. When the inner path is formed at both the first coil 26010 and the second coil 26020, the inner paths may be separated when the first coil 26010 and the second coil 26020 are separated. When the inner paths are separated, materials that have been contained in the inner paths may permeate into a deposition environment. The materials which permeate into the deposition environment may cause problems in that the efficiency of heating the heating assembly 22000 is decreased and the durability of the heating assembly 22000 is degraded. Conversely, when the inner path is formed at the second coil 26020 while the inner path is not formed in the first coil 26010, the above-described problems may not occur.

The first coil 26010 and the second coil 26020 may have different positional relationships with the crucible 23000. That is, when the first coil 26010 has a first positional relationship with the crucible 23000, the second coil 26020 may have a second positional relationship with the crucible 23000. Hereinafter, the positional relationships of the first coil 26010 and the second coil 26020 which are different from each other will be described.

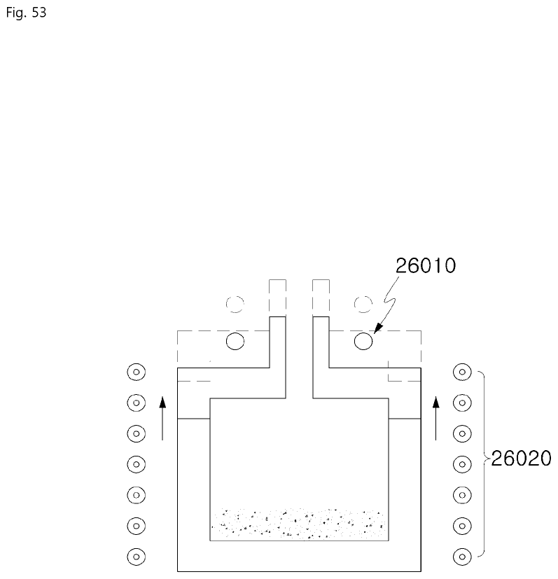

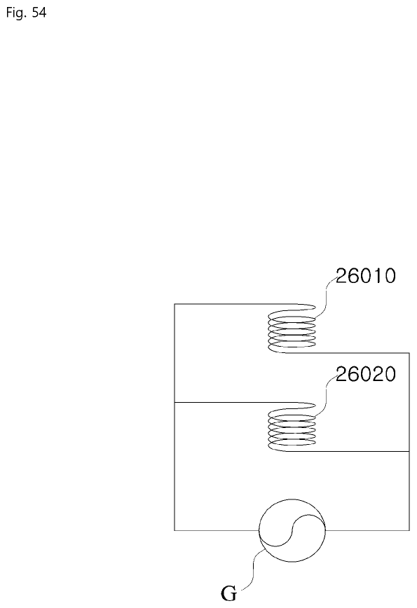

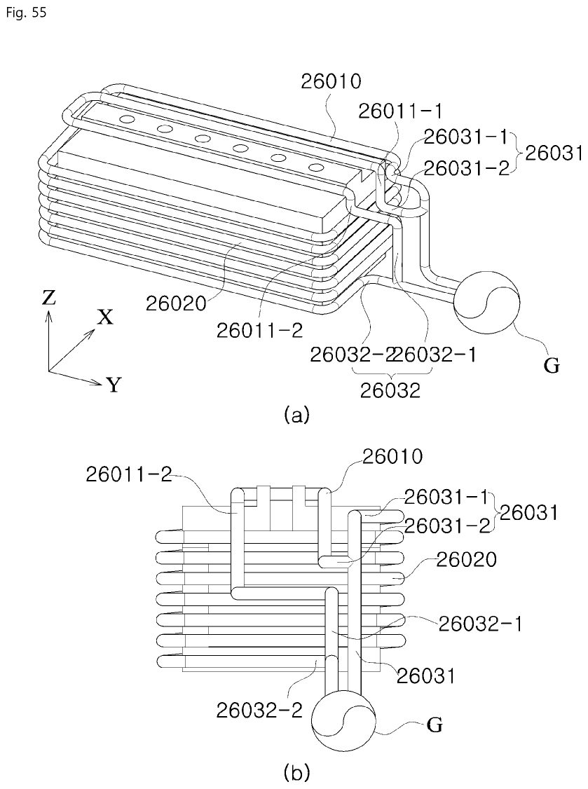

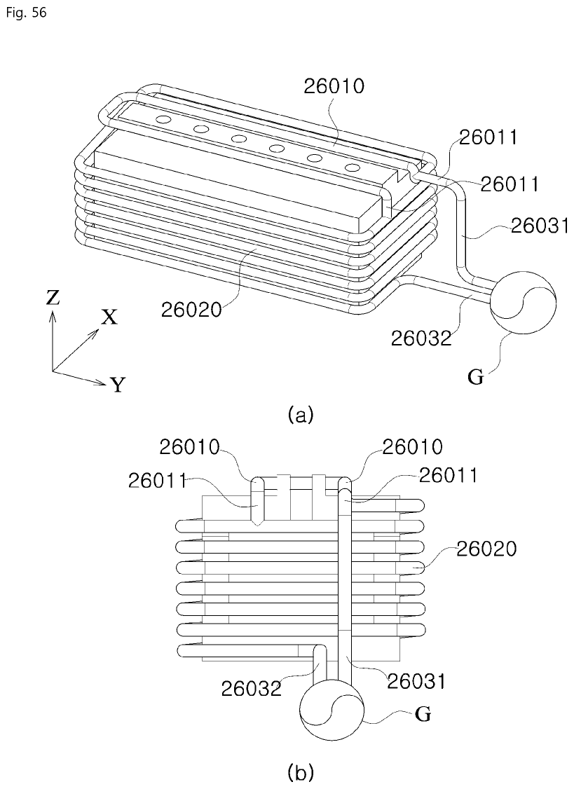

FIG. 53 is a view illustrating a coil disposed in the vicinity of a protruding nozzle according to an embodiment of the present application Referring to FIG. 53, the first coil 26010 may be disposed to be near the protruding nozzle of the crucible 23000, and the second coil 26020 may be disposed at a side surface portion of the crucible 23000. As compared with the case in which the coil is disposed to be far from the protruding nozzle of the crucible 23000, the first coil 26010 disposed to be near the protruding nozzle may cause a relatively larger quantity of heat to be generated in the protruding nozzle of the crucible 23000. The quantity of heat generated by the coil being disposed near the protruding nozzle will be described in detail below. On the basis of the quantity of heat, a deposition material passing through the protruding nozzle of the crucible 23000 may receive a sufficient quantity of heat and smoothly pass through the protruding nozzle. When the deposition material is stuck in the protruding nozzle due to a low temperature of the protruding nozzle, the deposition material may move again by induction heating of the first coil 26010. That is, the phase of the deposition material stuck in the protruding nozzle may be changed to a gas phase, which allows the deposition material to smoothly move, on the basis of a quantity of heat generated in the protruding nozzle by the first coil 26010.

The first coil 26010 and the second coil 26020 may be separated from each other electrically or physically. For example, when the upper portion of the crucible 23000 is moved to be separated from the crucible 23000 as illustrated in FIG. 53, the first coil 26010 may be moved together with the upper portion of the crucible 23000. Accordingly, the first coil 26010 which has been physically connected to the second coil 26020 may be moved to be separated from the second coil 26020. As the upper portion of the crucible 23000 is coupled to the crucible 23000 again, the separated first coil 26010 may be re-coupled to the second coil 26020. The electrical or physical separation or re-coupling between the first coil 26010 and the second coil 26020 may be easily performed by a coil connecting member 26011 which will be described below. This will be described in detail below.

The first coil 26010 and the second coil 26020 may be implemented to have attributes different from each other.

The first coil 26010 and the second coil 26020 may be implemented so that electrical attributes of the first coil 26010 and the second coil 26020 are different from each other. When the first coil 26010 has a first resistance and the second coil 26020 has a second resistance, the first resistance and the second resistance may have values different from each other. By making the first resistance of the first coil 26010 lower than the second resistance, it is possible to make electrical conductivity of the first coil 26010 higher than electrical conductivity of the second coil 26020. Alternatively, the first coil 26010 and the second coil 26020 may be implemented to have a first inductance and a second inductance, respectively. For the first coil 26010 and the second coil 26020 to have electrical attributes as described above, an implementation material for implementing the first coil 26010 and the second coil 26020 may be appropriately selected.

The above-described first coil 26010 and the second coil 26020 may receive power for induction heating from a power generator 26030. The first coil 26010 and the second coil 26020 may receive power from the same power generator 26030. By supplying power to the first coil 26010 and the second coil 26020 using the single power generator 26030, as compared with the case in which separate power generators for driving each coil are included, the present application may have an effect of simplifying the configuration of the heating assembly 22000.

The first coil 26010 and the second coil 26020 may be connected in parallel to the power generator 26030. The first coil 26010, the second coil 26020, and the power generator 26030 which are connected in parallel will be referred to as “parallel application module.” Hereinafter, the parallel application module will be described. To facilitate the description, an example will be described in which, in the parallel application module, the first coil 26010 is disposed to be near the protruding nozzle of the crucible 23000 and the second coil 26020 is disposed to be near a side portion of the crucible 23000.

FIG. 54 is a circuit diagram of a parallel application module according to an embodiment of the present application.

FIG. 55 is a view illustrating a first coil 26010, a second coil 26020, and a power generator 26030 which are connected in parallel according to an embodiment of the present application.

Referring to FIG. 54, the parallel application module may include the first coil 26010, the second coil 26020, the coil connecting member 26011, the power generator 26030, and power supply wire 26032.

The technical features of the first coil 26010 and the second coil 26020 are the same as those described above.

The coil connecting member 26011 may be a connecting member configured to physically or electrically connect at least two or more of the first coil 26010, the second coil 26020, and the power generator 26030. For the physical or electrical connection, the coil connecting member 26011 may be disposed between the first coil 26010, the second coil 26020, and the power generator 26030.

The power generator 26030 may generate power for driving the first coil 26010 and the second coil 26020.

The power supply wire may include a first power supply wire 26031 and a second power supply wire 26032. Power generated by the power generator 26030 may be transmitted to the first coil 26010 or the second coil 26020.

When the first coil 26010 and the second coil 26020 are electrically connected in parallel as described above, attributes of powers applied to the first coil 26010 and the second coil 26020 may be substantially the same. Meanwhile, although the attributes of powers applied to the first coil 26010 and the second coil 26020 are substantially the same, electrical attributes of the first coil 26010 and the second coil 26020 may be different from each other. For example, when power having an attribute A is identically applied to the first coil 26010 and the second coil 26020, if a resistance of the first coil 26010 is a first resistance, and a resistance of the second coil 26020 is a second resistance, currents flowing through the first coil 26010 and the second coil 26020 may be different from each other on the basis of the resistances.

Hereinafter, the actual first coil 26010, second coil 26020, and power generator 26030 which are connected in parallel will be described in detail.

As illustrated in FIG. 55, the first coil 26010, the second coil 26020, the coil connecting member 26011, the power generator 26030, and the power supply wire 26032 may be actually included in the heating assembly 22000.

The power supply wire 26032 may include the first power supply wire 26031 and the second power supply wire 26032. By the first power supply wire 26031 and the second power supply wire 26032, the first coil 26010, the second coil 26020, and the power generator 26030 may have the relationship of being electrically connected in parallel.

The first power supply wire 26031 and the second power supply wire 26032 may be output from the power generator 26030. The first power supply wire 26031 and the second power supply wire 26032 may be included in the parallel application module so that the first power supply wire 26031 may apply power to the first coil 26010 and the second power supply wire 26032 may apply power to the second coil 26020.

The first power supply wire 26031 may include a first-first power supply wire 26031-1 and a first-second power supply wire 26031-2. The first-first power supply wire 26031-1 and the first-second power supply wire 26031-2 may be implemented by being branched from the first power supply wire 26031. The first-first power supply wire 26031-1 may be connected to one side of the first coil 26010, and the first-second power supply wire 26031-2 may be connected to the other side of the first coil 26010. The second power supply wire 26032 may include a second-first power supply wire 26032-1 and a second-second power supply wire 26032-2. Likewise, the second-first power supply wire 26032-1 and the second-second power supply wire 26032-2 may be implemented by being branched from the second power supply wire 26032. The second-first power supply wire 26032-1 may be connected to one side of the second coil 26020, and the second-second power supply wire 26032-2 may be connected to the other side of the first coil 26010.

The one side refers to one region of the windings of the coil, and the other side refers to a region of the windings of the coil other than the one side.

As a result, according to the connection relationships, the first coil 26010, the second coil 26020, and the power generator 26030 may have the relationship of being electrically connected in parallel as illustrated in FIG. 54.

The parallel connection module may further include the coil connecting member 26011. The coil connecting member 26011 may be disposed between the coil and the power supply wire 26032 included in the parallel connection module so that the coil and the power supply wire 26032 are electrically connected.

The coil connecting member 26011 may be implemented using the same material as that of the coil included in the parallel connection module, but embodiments are not limited thereto, and the coil connecting member 26011 may also be implemented using various other materials. The coil connecting member 26011 may be implemented using members having a lower resistance than the coil. Since the coil connecting member 26011 are implemented using the material having a lower resistance than the coil, the coil connecting member 26011 may efficiently transmit power to the coil connected to the coil connecting member 26011.

An electrically-separable structure may be formed between configurations connected to the coil connecting member 26011. The separable structure may include a predetermined separation groove, a binding structure, and the like. For example, when the coil connecting member 26011 are connected to one side of the first coil, a separation groove which may be connected and separated between the one side of the first coil and the coil connecting member 26011 may be formed;

Accordingly, the coil connecting member 26011 may be connected to the coil and the power supply wire 26032 and separated from the coil and the power supply wire 26032.

The coil connecting member 26011 may be implemented in various shapes. Hereinafter, examples of the various shapes will be described.

Referring back to FIG. 54, the coil connecting member 26011 may include a first coil connecting member 26011-1 and a second coil connecting member 26011-2. The first coil connecting member 26011-1 may be disposed between the first coil 26010 and the power supply wire 26032 so that the first coil 26010 and the power supply wire 26032 may be electrically connected to each other. That is, the coil connecting member 26011 may allow one side of the first coil 26010 to be electrically connected to the first-first power supply wire 26031-1 branched from the first power supply wire 26031. The second coil connecting member 26011-2 may be disposed between the first coil 26010 and the power supply wire 26032 so that the first coil 26010 and the power supply wire 26032 may be electrically connected to each other. That is, the coil connecting member 26011 may allow the other side of the first coil 26010 to be electrically connected to the second-first power supply wire 26032-1 branched from the second power supply wire 26032.

As a result, according to the connection relationships, the first coil 26010, the second coil 26020, and the power generator 26030 may have the relationship of being electrically connected in parallel as illustrated in FIG. 54.

By the coil connecting member 26011 being included in the parallel application module, the present application may have an effect of facilitating physical or electrical separation or connection between the first coil 26010, the second coil 26020, and the power supply wire 26032. When the coil connecting member 26011 are not present, the first coil 26010, the second coil 26020, and the power supply wire 26032 should have predetermined shapes for the separated first coil 26010, second coil 26020, and power supply wire 26032 to be connected. That is, the first coil 26010, the second coil 26020, and the power supply wire 26032 should be twisted in various directions or have unique shapes such as protruding shapes. The first coil 26010, the second coil 26020, and the power supply wire 26032 having a predetermined shape may increase complexity of the configuration of the parallel application module. The increased complexity of the configuration of the parallel application module may hinder connection between the configurations of the parallel application module. Conversely, when the coil connecting member 26011 are included in the parallel application module, the first coil 26010, the second coil 26020, and the power supply wire 26032 may be implemented in simple shapes without being required to be implemented in unique shapes. The coil connecting member 26011 may be disposed between the first coil 26010, the second coil 26020, and the power supply wire 26032, which are implemented in simple shapes, and may connect at least two or more of the first coil 26010, the second coil 26020, and the power supply wire 26032, thereby facilitating the connection between the configurations of the parallel connection module.

Also, when the configurations of the parallel connection module are separated, the configurations may be easily separated. For example, when the first coil 26010 illustrated in FIG. 9 has to be separated from the power supply wire 26032, the first coil 26010 and the power supply wire 26032 may be easily separated by simply detaching the coil connecting member 26011, which have been physically or electrically connecting the first coil 26010 and the power supply wire 26032 to each other.

However, the physical or electrical connection relationships in the parallel connection module illustrated in FIG. 9 may require the power supply wire 26032 to have an excessively long length. When the power supply wire 26032 output from the power generator 26030 has an excessively long length, a problem may occur in which the deposition operation is hindered. This is because movement of the heating assembly 22000 for the deposition operation may be restricted due to the elongated power supply wire 26032. Also, since the power supply wire 26032 has an excessively long length, the present application may have a problem in which loss of power supplied via the power supply wire 26032 is sharply increased.

Modifications of the parallel application module for addressing the problems may be present. While the physical or electrical connections in the above-described parallel application module refers to connecting each of the first coil 26010 and the second coil 26020 to the power supply wire 26032, the modification to be described below relates to a parallel application module in which the first coil 26010 and the second coil 26020 are connected to each other.

FIG. 56 is a view illustrating a first coil 26010, a second coil 26020, and a power generator 26030 according to an embodiment of the present application.

FIG. 57 is a view illustrating a first coil 26010, a second coil 26020, and a power generator 26030 according to an embodiment of the present application.

Referring to FIG. 56, a first coil 26010, a second coil 26020, and a coil connecting member 26011 according to an embodiment of the present application may be physically or electrically connected to each other.

The second coil 26020 may include a first winding and a second winding.

The first coil connecting member 26011-1 may be connected to the first winding and connected to one side of the first coil 26010. The second coil connecting member 26011-2 may be connected to the second winding and connected to the other side of the second coil 26020. As illustrated in FIG. 56, at least one of the first winding and the second winding may protrude to be connected to the coil connecting member 26011. Unlike this, the coil connecting member 26011 may have a bent shape so that the coil connecting member 26011 are connected to at least one of the first winding and the second winding.

Although the first winding and the second windings have been described above as being present in the coil as illustrated in FIG. 56, the first winding and the second winding may not be limited thereto.

Referring to FIG. 56, the first power supply wire 26031 may be connected to one side of the second coil 26020, and the second power supply wire 26032 may be connected to the other side of the second coil 26020.

Accordingly, power generated by the power generator 26030 may be transmitted to the second coil 26020 via the power supply wire 26032, and power transmitted to the second coil 26020 may be transmitted from the second coil 26020 to the first coil 26010.

The physical or electrical connection relationship between the first coil 26010 and the second coil 26020 may not be a parallel relationship in a strict sense but may be a parallel relationship in a broad sense since attributes of power applied to the first coil 26010 is based on the power of the second coil 26020.

The modification will be further described below.

Referring to FIG. 57, a first coil 26010, a second coil 26020, and a power generator 26030 according to an embodiment of the present application may be electrically or physically connected to each other.

The first coil connecting member 26011-1 may be connected to one side of the first coil 26010, and the second coil connecting member 26011-2 may be connected to the other side of the first coil 26010. The first coil connecting member 26011-1 may be connected to the one side of the second coil 26020 and the first power supply wire 26031, and the second coil connecting member 26011-2 may be connected to a winding of the second coil 26020. The second power supply wire 26032 may be connected to the other side of the second coil 26020. Power generated from the power generator 26030 may be applied to the first coil 26010 and the second coil 26020.

According to the parallel application module illustrated in FIGS. 56 and 57, the present application may have the following effects.

By detaching the first coil connecting member 26011-1 and the second coil connecting member 26011-2 from each other, the above-described first coil 26010 and the second coil 26020 may be easily separated from each other. In addition, the first coil 26010, the second coil 26020, and the power supply wire 26032 may have simple shapes. Also, since the first coil 26010 and the second coil 26020 are connected to each other, there is no need to separately apply power to the first coil 26010 and the second coil 26020, and thus the power supply wire 26032 may not be required to have an excessively long length.

Meanwhile, a coil not driven by a single power generator will be referred to as “a separately driven coil.” The separately driven coil will be described in detail below.

A variable power whose electrical attribute varies may be applied to a coil 26000 according to an embodiment of the present application. For example, such a variable power may be, preferably, high-frequency alternating-current (AC) power such as RF, or, in some cases, may be low-frequency AC power.

As the above-described AC power is applied to a coil 26000, a current (hereinafter referred to as a coil current) may flow through a coil 26000 according to an embodiment of the present application. Electrical attribute of the coil current may include an intensity thereof, a direction thereof, or the like. Therefore, electrical attribute of the coil current may change corresponding to the AC power. An intensity, direction, or the like of the coil current may change every moment corresponding to the AC power.

According to an embodiment of the present application, a dynamic magnetic field is formed around a coil 26000, and the dynamic magnetic field forms an induction current in a crucible 23000 such that a quantity of heat is generated. Accordingly, as a result, the coil 26000 may inductively heat the crucible 23000. Hereinafter, attribute of a magnetic field formed by the coil 26000 according to an embodiment of the present application and attribute of an induction current formed in the crucible 23000 will be described.

1.1.2.1 Attributes of Magnetic Field

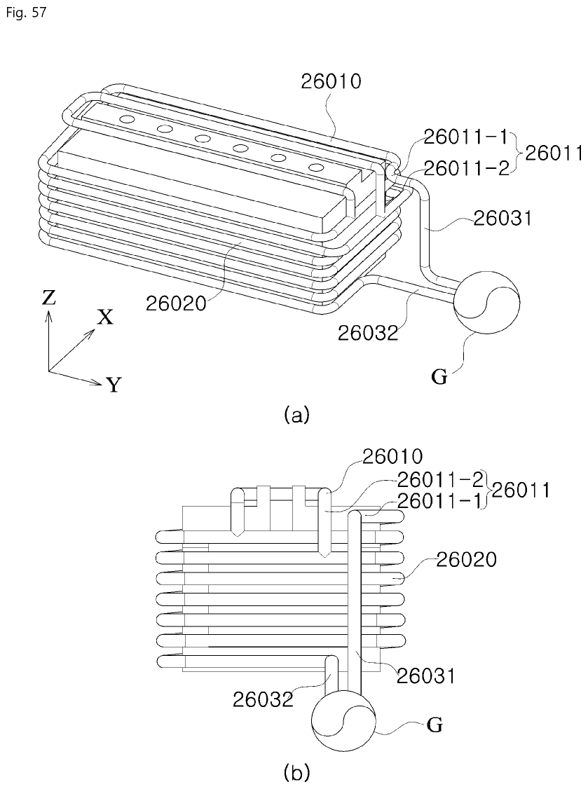

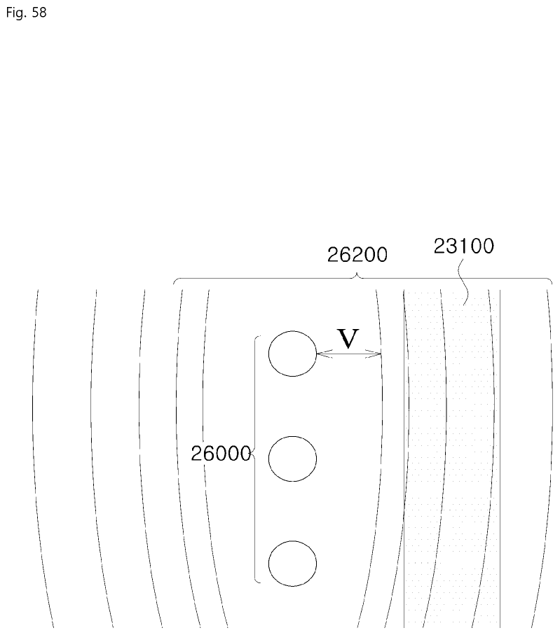

FIG. 58 is a conceptual diagram illustrating a magnetic field formed around a coil according to an embodiment of the present application.

Hereinafter, an intensity attribute of a magnetic field 26100 will be described.

An intensity attribute of a magnetic field 26100 according to an embodiment of the present application may satisfy the relation, B∝u₀·H (where B=magnetic flux density, u₀=magnetic permeability/proportional factor, H=intensity of magnetic field). In this case, according to magnetic permeability of a space in which the magnetic field 26100 is formed, an intensity value and a magnetic flux density value of the magnetic field 26100 may not match accurately. However, as can be seen from the relation, the intensity and the magnetic flux density of the magnetic field 26100 are proportional to each other. Therefore, on the basis of the proportional relationship, the magnetic flux density and the intensity of the magnetic field will be considered as substantially the same concept herein.

That is, even when not specifically mentioned in the description herein, the fact that the density of magnetic flux 26200 is high may mean that the intensity of the magnetic field is high, and the fact that the intensity of the magnetic field is high may mean that the density of magnetic flux is high.

Also, the intensity attribute of the magnetic field 26100 may change according to a distance relationship between the magnetic field 26100 and a place of origin of the magnetic field 26100. An amplitude attribute of the magnetic field 26100 may satisfy the relation,

$$H ∝ k \cdot \frac{I}{r}$$

(where H=intensity of magnetic field, k=proportional factor, I=current flowing through place of origin, r=distance from place of origin), which is a relation between the intensity of the magnetic field 26100 and the place of origin of the magnetic field 26100. According to the relation, the intensity of the magnetic field 26100 may decrease as the magnetic field 26100 is formed at a larger distance from the place of origin thereof. Specifically, the intensity of the magnetic field 26100 may decrease as the number of magnetic field lines passing through a predetermined area formed at a large distance from the place of origin decreases. Conversely, the intensity of the magnetic field 26100 may increase as the magnetic field 26100 is nearer to the coil 26000.

Hereinafter, a dynamic magnetic field formed around the coil 26000 according to an embodiment of the present application will be described.

Referring to FIG. 58, a magnetic field 26100 formed around a coil 26000 according to the present application may have a dynamic property.

For example, the direction and intensity attributes of the formed magnetic field 26100 according to the present application may suddenly change according to a time change in the time axis. According to the relation, \vec{H}∝\vec{I} (where H=intensity of magnetic field, I=coil current flowing through coil), the magnetic field 26100 formed around the coil 26000 may be dynamically formed corresponding to dynamic current flowing in the coil 26000 that suddenly changes according to time.

The dynamic magnetic field is a vector-related concept that includes not only the intensity attribute but also the direction attribute. Specifically, when one direction of a direction in which coil current flows along variable power applied to the coil 26000 is a positive (+) direction, the other direction opposite to the one direction may be a negative (−) direction. The direction of the coil current continuously changes from the positive (+) direction to the negative (−) direction and from the negative (−) direction to the positive (+) direction, and simultaneously, the intensity of the current also continuously changes. Therefore, as the direction of the coil current suddenly changes to the positive (+) direction or the negative (−) direction, the direction of the magnetic field 26100 may also suddenly change to the one direction or the other direction corresponding to the direction of the coil current. Also, simultaneously, the intensity attribute of the magnetic field 26100 may be set corresponding to an intensity attribute of the coil current.

As a result, as illustrated in FIG. 58, a dynamic magnetic field 26100 whose direction and intensity fluctuate may be formed around the coil 26000.

Hereinafter, an intensity change value of a dynamic magnetic field 26100 formed around the coil will be described.

The intensity change value of the dynamic magnetic field is a quantity-related concept. The intensity change value of the magnetic field is an intensity change amount of the magnetic field per unit time in which the direction of the magnetic field is taken into consideration. Specifically, while only the intensity change amount of the magnetic field is important for change values of magnetic fields formed in the same direction, change values of magnetic fields formed in different directions may be set according to the intensity change amount of the magnetic field in which the direction of the magnetic field is taken into consideration.

An intensity change value attribute of the dynamic magnetic field 26100 according to an embodiment of the present application may vary according to a distance thereof from the coil 26000. The above-described magnetic field 26100—forming attribute,

$$H ∝ k \cdot \frac{I}{r} ,$$

may apply to the intensity of the dynamic magnetic field 26100.

As the distance of the dynamic magnetic field 26100 from the coil 26000 becomes larger, the intensity of the magnetic field formed at the corresponding distance may become lower. Therefore, since a dynamic range of the intensity of the formed magnetic field also becomes smaller, the intensity change value of the magnetic field becomes smaller. On the other hand, as the distance of the dynamic magnetic field 26100 from the coil 26000 becomes smaller, the intensity change value of the dynamic magnetic field 26100 becomes larger.

Also, various shapes in which the coil 26000 is implemented may change the intensity change value of the dynamic magnetic field 26100. The intensity of the dynamic magnetic field 26100 may satisfy the relation, H∝N (where H=intensity of magnetic field, N=number of windings of coil per unit length). Accordingly, as the number of windings of the coil increases, the intensity of the magnetic field formed around the coil increases. As the intensity of the magnetic field increases, the intensity change value of the magnetic field also increases.

Attributes of an induction current induced to a crucible 23000 according to a magnetic field formed around a coil 26000 will be described below.

1.1.2.2 Attribute of Induction Current

A magnetic field formed according to an embodiment of the present application may form induction current in the crucible 23000.

For example, the formed induction current may satisfy the relation, \vec{F}=q\vec{v}×\vec{H} (where F=force acting on electrons of crucible, q=electric charge of electrons, v=velocity of electrons, H=intensity of magnetic field), which is a relation between electrons of the crucible 23000 and the magnetic field formed by the coil 26000. That is, an electrical force may be applied to the electrons of the crucible 23000 due to the dynamic magnetic field suddenly changing temporally and spatially that is generated by the coil 26000. As a result, the electrons move due to the electrical force such that induction current may be generated.

Also, for example, the formed induction current may satisfy the relation,

$$e ∝ \frac{d B}{dt}$$

(where e=induced electromotive force, B=magnetic flux density, t=time), which is a relation between magnetic flux formed by the coil and an induced electromotive force generated in the crucible. That is, an induced electromotive force may be generated in the crucible 23000 due to the dynamic magnetic field generated by the coil 26000. The induction current may flow in the crucible 23000 according to the generated electromotive force.

According to an embodiment of the present application, a current path of an induction current may be formed in the crucible 23000.

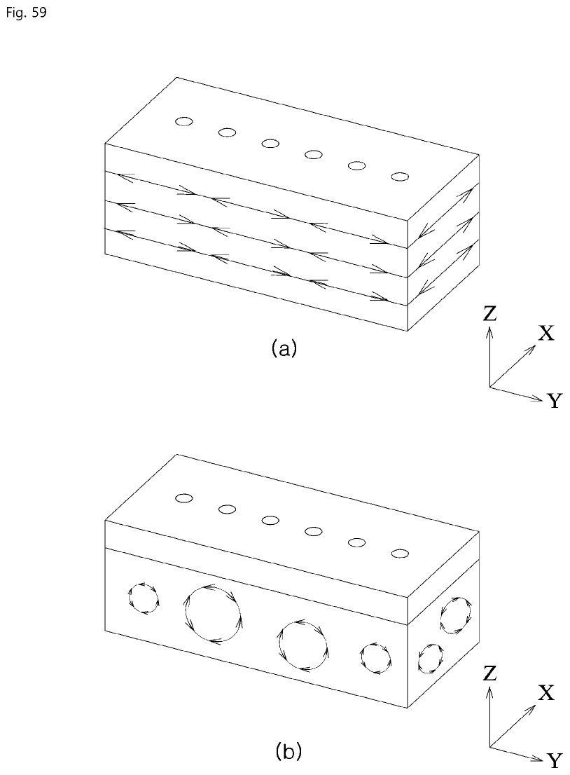

FIG. 59 is a conceptual diagram illustrating a magnetic field formed around a coil and a crucible according to an embodiment of the present application.

Referring to FIG. 59, a current path induced to the crucible 23000 according to an embodiment of the present application may be formed at the outer wall 23100 of the crucible 23000. Also, an example of a form of the induction current path may be a form of surrounding the outer wall 23100 of the crucible 23000. As another example of the form of the induction current path, a current path in a form of locally forming an eddy at the outer wall 23100 of the crucible 23000 may be formed.

Also, the crucible 23000 may have a current path having a form in which the above-described forms of paths are simultaneously combined. Furthermore, the form of the current path is not limited to those described above, and the current path may have various other forms corresponding to a change in the shape of the magnetic field generated by the coil 26000.

An induction current according to an embodiment of the present application may have various attributes according to the relationships between a coil 26000, a magnetic field formed around a coil 26000, and a crucible 23000. The attributes will be described below.

In this case, according to the mathematical equation,

$$I ∝ \frac{dQ}{dt} ,$$

the intensity of induction current mentioned herein may refer to an electric charge moving in the crucible 23000 per unit time. That is, note that the intensity of induction current mentioned herein is a quantity-related concept and is a concept that implies how much charge has moved.

Electrical attributes of an induction current induced to a crucible 23000 according to an embodiment of the present application may vary according to attributes of a dynamic magnetic field formed around a coil 26000.

For example, when the intensity of the dynamic magnetic field according to the present application and/or the intensity change value of the magnetic field increase, the intensity attribute of the formed induction current may increase. According to the above-described relations, (1) \vec{F}=q\vec{v}×\vec{H} and

$$e ∝ \frac{d B}{dt} , \qquad ( 2 )$$

when the intensity change value of the dynamic magnetic field increases, a force applied to the electrons of the crucible 23000 may increase, and an electromotive force that affects motion of the electrons may increase. Accordingly, the amount of electrons that may move in the crucible 23000 increases, and thus the intensity attribute of the induction current increases.

Also, electrical attributes of an induction current inducted to a crucible 23000 according to an embodiment of the present application may vary according to the shape of a crucible 23000.

For example, the intensity of the induction current may vary corresponding to the thickness of the crucible. The intensity of the induction current may increase when the thickness of the crucible is large, and the intensity of the induction current may decrease when the thickness of the crucible is small. The amount of electrons in the crucible 23000 may change according to the thickness of the crucible 23000. The amount of electrons when the thickness of the crucible 23000 is large is greater than the amount of electrons when the thickness of the crucible 23000 is relatively smaller. Accordingly, since the amount of electrons that may move due to the formed magnetic field increases as the thickness of the crucible 23000 is larger, the intensity of the induction current may increase as the thickness of the crucible 23000 is larger.

Meanwhile, an induction current according to an embodiment of the present application may form an induction magnetic field in a crucible 23000 again according to the magnetic field formation attributes. Also, the induction magnetic field may secondarily form the induction current in the crucible 23000 according to induction current formation attributes. That is, in a crucible 23000 according to an embodiment of the present application, induction current formation and induction magnetic field formation events may serially occur.

1.1.2.3 Induction Heating

A quantity of heat may be generated using various methods in a crucible 23000 according to an embodiment of the present application.

A quantity of heat may be generated in a crucible 23000 according to an embodiment of the present application due to a combination of the induction current induced to the crucible 23000 and an electrical resistance component of the crucible 23000. The combination of the induction current and the electromagnetic component may satisfy the relation, P∝I²·R· [symbol] (where P=generated quantity of heat, I=induction current, R=resistance component of crucible, t=heating time). According to the relation, the induction current and/or an induction current path induced to the crucible 23000 may be converted to a quantity of heat due to the resistance component of the crucible 23000. In this case, it can be recognized that the quantity of heat generated in the crucible 23000 increases as the intensity of the induction current increases.

Also, a quantity of heat may be generated in the crucible 23000 according to a combination of the dynamic magnetic field formed around the coil 26000 and the electromagnetic component of the crucible 23000.

The quantity of heat generated in the crucible 23000 due to the induction current and/or the dynamic magnetic field may heat the crucible 23000. Since the crucible 23000 is heated by the induction current induced by the coil 26000 and the dynamic magnetic field, the heating of the crucible may be referred to as induction heating.

Although various methods exist as described above for an induction heating according to an embodiment of the present application, the following description will focus on the case in which the crucible 23000 is inductively heated according to the induction current formed in the crucible 23000 and the resistance component of the crucible 23000.

A coil 26000, which is an example of a heating means 25000 that may be implemented in a heating assembly, and various electrical attributes that occur depending on a coil 26000 have been described above. A magnetic field focusing member 27000 that may be disposed in a heating assembly according to an embodiment of the present application will be described below.

1.1.2 Magnetic Field Focusing Member

An aid for a heating means 25000 may be present in the heating assembly according to an embodiment of the present application. For example, when a heating member 25000 according to an embodiment of the present application is a coil 26000, the magnetic field focusing member 27000 configured to focus the magnetic field formed around the coil 26000 may be included as the heating aid in the heating assembly. In this case, “focusing” may be interpreted as focusing magnetic flux of a magnetic field to any one region.

Hereinafter, a ferrite 28000, which is an example of the magnetic field focusing member 27000, will be described. Although the ferrite 28000 is described herein as an example of the magnetic field focusing member 27000, note that the magnetic field focusing member 27000 is not limited thereto and any other means or material capable of focusing a magnetic field may be implemented as the magnetic field focusing member 27000 in the heating assembly.

A ferrite 28000 according to an embodiment of the present application may be implemented in various types and forms using various materials.

For example, the ferrite 28000 is an ionic compound having a spinel structure and may be formed by bonding various metal compounds to a main component, with iron oxide as the main component. The various metal compounds may be divalent metal ions such as Mn, Zn, Mg, Cu, Ni, and Co. However, a ferrite 28000 described herein is not limited to the above components and may be formed with materials formed of various other components capable of focusing a magnetic field.

Also, types of the ferrite 28000 may include: (1) a liquid type that may be present in a liquid phase at room temperature; and (2) a solid type that may have a predetermined shape at room temperature.

Also, the ferrite 28000 may have various shapes, such as a plate shape, a shape in which a convex protrusion is formed on at least one or more surfaces of the plate shape, a circular shape, an elliptical shape, and a spherical shape, to fit a purpose.

A magnetic field focusing attribute, which is an attribute of the ferrite 28000, and an effect in which efficiency of heating the crucible 23000 is improved according to the magnetic field focusing attribute will be described below.

1.1.1.1 Magnetic Field Focusing Attribute

Hereinafter, magnetic field focusing of a ferrite 28000, which is an example of a magnetic field focusing member 27000 according to an embodiment of the present application, will be described.

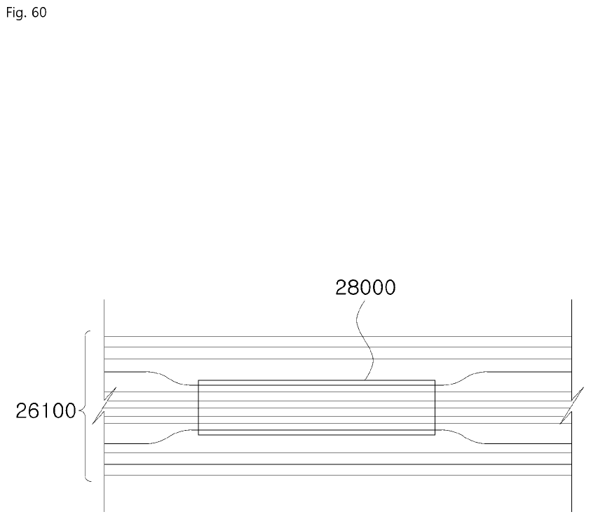

FIG. 60 is a view illustrating a ferrite placed in a magnetic field according to an embodiment of the present application.

Referring to FIG. 60, a ferrite 28000 placed in a magnetic field according to an embodiment of the present application may affect magnetic flux of a magnetic field. For example, the ferrite 28000 may act to draw the magnetic flux of the magnetic field formed around the ferrite 28000 toward the ferrite 28000 so that the density of magnetic flux of the magnetic field is high around the ferrite 28000.

In this case, the influence on the magnetic flux may vary according to a thickness of the ferrite 28000. As the thickness of the ferrite 28000 is larger, the amount of magnetic flux formed around the ferrite 28000 that may be affected may increase.

The ferrite 28000 may be disposed in a heating assembly according to the present application.

A ferrite 28000 disposed in a heating assembly according to an embodiment of the present application may have a magnetic field focusing attribute that increases an intensity change value of a dynamic magnetic field that affects the crucible 23000.

FIG. 61 is a view illustrating a ferrite, a coil, and a magnetic field formed around the coil according to an embodiment of the present application.

Referring to FIG. 61, when a ferrite 28000 according to the present application is disposed in the heating assembly, the ferrite 28000 may focus magnetic flux of a dynamic magnetic field so that the density of magnetic flux of the dynamic magnetic field is high at the outer wall 23100 of the crucible 23000.

The dynamic magnetic flux densely formed at the outer wall 23100 of the crucible 23000 may be due to the above-described attribute of the ferrite 28000. The ferrite 28000 disposed at an outer side of the coil 26000 may cause the density of magnetic flux to be high in the crucible 23000 by drawing the magnetic flux which is formed toward an inner side of the coil 26000 toward the ferrite 28000.

Alternatively, the dynamic magnetic flux densely formed at the outer wall 23100 of the crucible 23000 may be due to the magnetic field formation attribute as well as the attribute of the ferrite 28000. The ferrite 28000 disposed at the outer side of the coil 26000 may draw the magnetic flux which is formed toward the outer side of the coil 26000 toward the ferrite 28000 according to the attribute of the ferrite 28000. Simultaneously, according to the magnetic formation attribute in that magnetic fields are symmetrically formed around the coil 26000, the magnetic flux formed toward the inner side of the coil 26000 may also be drawn symmetrically toward the crucible 23000 and formed. Accordingly, the density of magnetic flux of the dynamic magnetic field is high at the outer wall 23100 of the crucible 23000.

Since the density of magnetic flux is high, the intensity in the positive (+) direction and the intensity in the negative (−) direction of the dynamic magnetic field around the coil 26000 that is formed at the outer wall of the crucible 23000 simultaneously increase. As the intensity of the magnetic field increases in both directions, the dynamic range of the intensity of the dynamic magnetic field that fluctuates also increases corresponding to the increase. That is, the intensity change value of the dynamic magnetic field generated at the outer wall 23100 of the crucible 23000 increases as compared with the case in which the ferrite 28000 is not disposed.

1.1.1.2 Improvement of Heating Efficiency

Hereinafter, improvement of the efficiency of heating a crucible 23000 that occurs when a ferrite 28000 is implemented in a heating assembly according to an embodiment of the present application will be described. The heating efficiency mentioned herein refers to a quantity of heat generated in the crucible 23000 relative to electrical energy input to the coil, which is the heating means 25000 according to the present application. That is, when the electrical energy input to the coil is the same, it can be said that the heating efficiency (or thermal efficiency) is higher as the quantity of heat generated in the crucible 23000 is larger.

An efficiency of heating a crucible 23000 may be improved in the case in which a ferrite 28000 is disposed in a heating assembly according to an embodiment of the present application, as compared with the case in which a ferrite 28000 is not disposed therein.

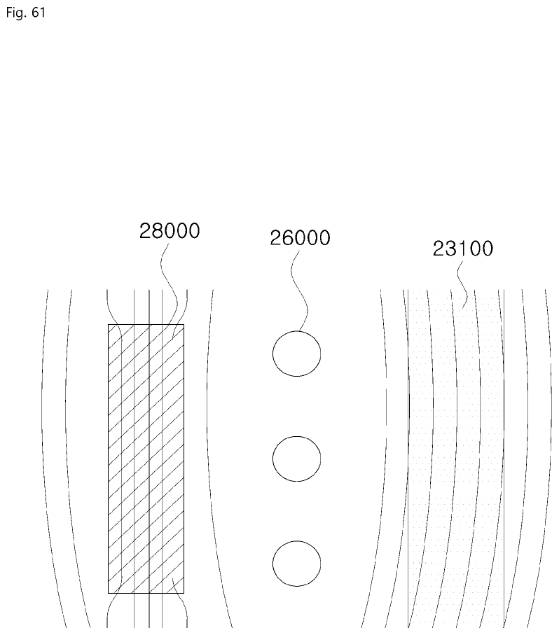

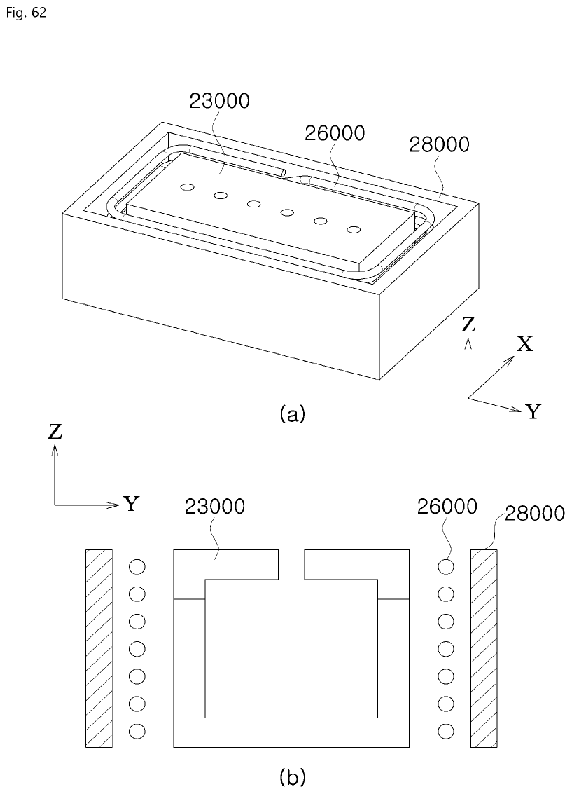

FIG. 62 is a view illustrating a ferrite disposed in a heating assembly according to an embodiment of the present application.

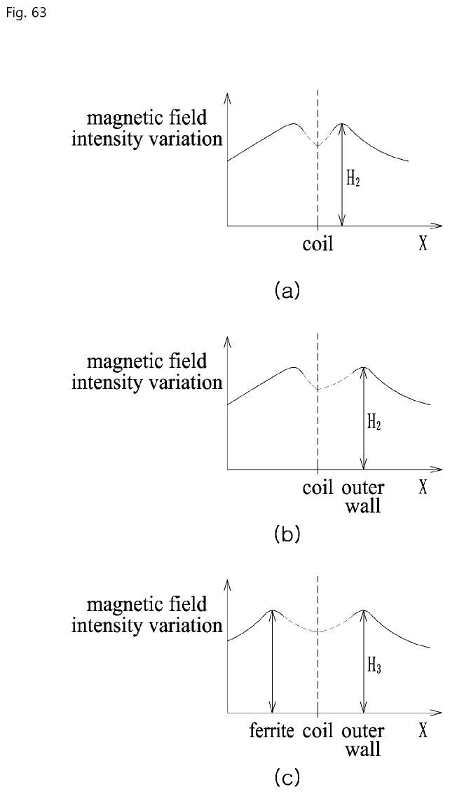

FIG. 63 is a graph showing a distribution of intensity change values of a magnetic field according to an embodiment of the present application.

Referring to FIGS. 62(a) and (b), a ferrite 28000 according to an embodiment of the present application may be formed in the form of surrounding a coil 26000 disposed at an outer side of a crucible 23000. For example, the ferrite 28000 which has a form corresponding to that of the coil 26000 disposed at the crucible 23000 may be disposed. Specifically, as illustrated in FIG. 58, corresponding to side portions of the closed-shape coil 26000 formed in a rectangular parallelepiped shape that is disposed at the outer side of the crucible 23000, the ferrite 28000 formed in a hollow rectangular parallelepiped shape may be disposed in which four surfaces opposite to each side portion are formed.

As illustrated in FIG. 62, when the ferrite 28000 is disposed at the outer side of the coil 26000, an efficiency of heating a crucible 23000 according to an embodiment of the present application may be improved. Referring to FIGS. 63(a) and (b), a distribution of intensity change values of a dynamic magnetic field formed around a coil according to an embodiment of the present application may be changed due to a crucible disposed in a heating assembly. For example, the distribution of the intensity change values of the dynamic magnetic field formed toward the inner side of the coil may be shifted in a direction toward the outer wall of the crucible. However, the maximum size of the change value of the magnetic field satisfies H1≈H2, and the crucible 23000 being disposed may not cause a significant change in the distribution.

Meanwhile, referring to FIG. 63(c), the distribution of the intensity change values of the dynamic magnetic field formed around the coil may be changed due to the ferrite 28000 disposed in the heating assembly. For example, as illustrated in FIGS. 62(a) and (b), as the ferrite 28000 is disposed, a magnetic field may be focused to the outer wall of the crucible due to the ferrite 28000. Accordingly, the intensity in the positive (+) direction and the intensity in the negative (−) direction of the dynamic magnetic field around the coil 26000 formed at the outer wall of the crucible 23000 increase simultaneously. As the intensity of the magnetic field increases in both directions, the dynamic range of the intensity of the dynamic magnetic field that fluctuates also increases corresponding to the increase. That is, the intensity change value of the magnetic field satisfies H3>>H1,H2, and, when the ferrite 28000 is disposed, the intensity change value of the magnetic field may be higher at the outer wall as compared with when the ferrite 28000 is not disposed.

As the intensity change value of the magnetic field becomes higher as described above, the induction current intensity may further increase in the crucible 23000 in which the ferrite 28000 is disposed as compared with the crucible 23000 in which the ferrite 28000 is not disposed.

Due to the above-described induction heating attribute, as the induction current intensity increases as described above, the quantity of heat generated in the crucible 23000 may increase. As a result, a quantity of heat generated due to the coil 26000 in which the ferrite 28000 is disposed is larger than that generated due to the coil 26000 in which the ferrite 28000 is not disposed, and thus the efficiency of heating the crucible 23000 may be improved.

Hereinafter, an example of disposing a ferrite 28000 so that an efficiency of heating a crucible 23000 is improved will be described.

Referring to FIG. 62(b), a ferrite 28000 according to an embodiment of the present application may be implemented in a form of surrounding an upper portion and a lower portion of a coil 26000 disposed in a crucible 23000. For example, in the case of the closed-shape coil 26000 which is disposed so that the crucible 23000 is disposed at the inner portion thereof, the ferrite 28000 may be disposed up to the upper portion and the lower portion of the closed-shape coil 26000.

When a ferrite 28000 is implemented as described above according to an embodiment of the present application, an effect of focusing to a crucible 23000 even a dynamic magnetic flux exiting through an upper surface or a lower surface of a coil 26000 may be achieved. Since the dynamic magnetic field is focused to the crucible 23000, the efficiency of heating the crucible 23000 is improved.

Other than being disposed at an outer portion of a crucible 28000, a ferrite 28000 according to an embodiment of the present application may also be disposed in a form of being included in an inner portion of a crucible 23000 in order to improve an efficiency of heating a crucible 23000.

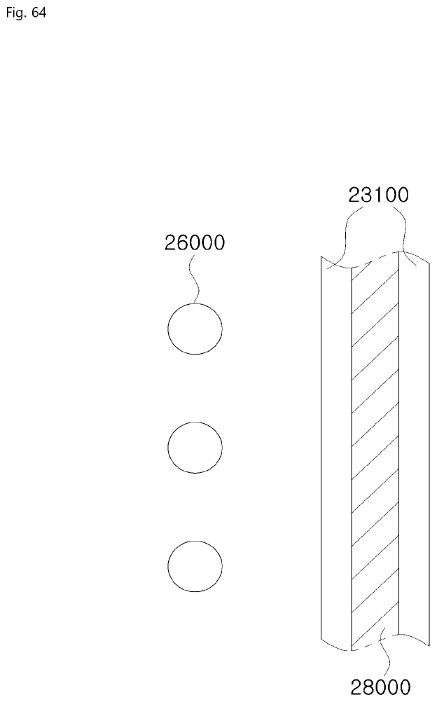

FIG. 64 is a cut side view illustrating a ferrite included in an outer wall of a crucible according to an embodiment of the present application.

As illustrated in FIG. 64, as the ferrite 28000 is formed at the outer wall 23100 of the crucible 23000, a dynamic magnetic field may be focused to the outer wall 23100 of the crucible 23000. As the dynamic magnetic field is focused, an effect of further improving the efficiency of heating the crucible 23000 may be achieved.

Also, in order to improve an efficiency of heating a crucible 23000, a ferrite 28000 according to an embodiment of the present invention may be implemented in a form of being applied to a crucible 23000.

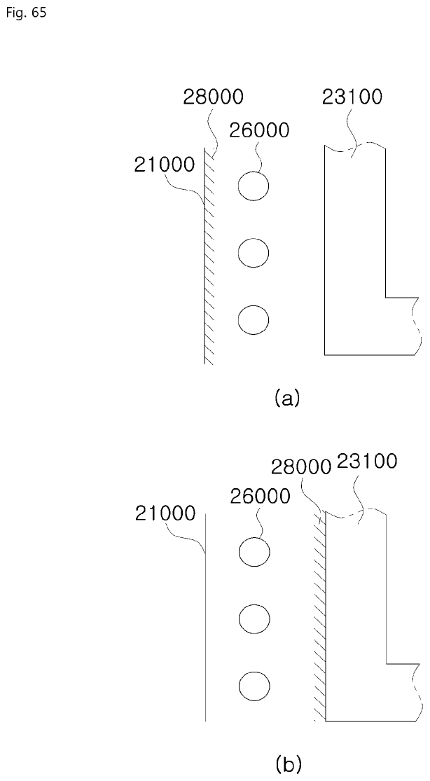

FIG. 65 is a view illustrating a shape implemented by applying a ferrite to a deposition apparatus 20000 according to an embodiment of the present application.

Referring to FIGS. 65(a) to (d), a ferrite 28000 according to an embodiment of the present application may be implemented in a form of being applied on a heating assembly and coated to a configuration of a heating assembly.

For example, a ferrite 28000 according to an embodiment of the present application may be applied to an inner surface of an outer wall of a housing 21000 surrounding the crucible 23000. Referring to FIG. 61(2a), the ferrite 28000 may be applied on the inner surface of the outer wall of the housing 21000 which surrounds a side surface portion of the crucible 23000.

A ferrite 28000 according to an embodiment of the present application may also be applied on a crucible 23000. As illustrated in FIG. 65(b), the ferrite 28000 may be applied on the outer wall 23100 at a side surface of the crucible 23000.

Various thicknesses may be selected as a thickness of a ferrite 28000 applied to a heating assembly 20000 according to an embodiment of the present application, according to a design purpose.

When a ferrite 28000 is disposed in a heating assembly as described above according to an embodiment of the present application, a thermal efficiency of a crucible 23000 may be improved, and, as a result, a quantity of heat transferred from a crucible 23000 to a deposition material may increase. As a result, by the ferrite 28000 being disposed in the deposition apparatus 20000, the deposition apparatus 20000 may have high heat output relative to the same input energy, and thus an effect of allowing efficient energy use may be achieved. Also, since the deposition apparatus 20000 has sufficient energy that allows the deposition material to actively move according to the high heat output, the deposition apparatus 20000 may have an effect of increasing a success rate in which the deposition material is formed on a deposition target surface.

Hereinafter, a method of improving the actual deposition efficiency (or deposition success rate) of the deposition material by controlling a heat distribution in a crucible 23000 by varying the configuration of the deposition apparatus 20000 according to the present application will be described.

In this case, the actual deposition efficiency may refer to the efficiency at which the deposition material is formed at a uniform thickness or concentration on a deposition target surface as well as the efficiency at which the deposition material is properly formed on the deposition target surface.

### 2. Control of Heat Distribution in Crucible

For the deposition apparatus 20000 that deposits a deposition material on a deposition target surface, improving the actual deposition efficiency at which the deposition material is deposited on the deposition target surface may be an important issue. In order to improve the deposition success rate, a method of controlling a spatial distribution of quantities of heat provided to the deposition material accommodated in an inner space of the crucible 23000 may be used.

For example, (1) the quantities of heat distributed in each space of the crucible 23000 may be controlled to be different from each other. As a specific example, by relatively increasing the distribution of quantities of heat around the nozzle 23200 of the crucible 23000, the temperature of the deposition material passing through the nozzle 23200 may be increased. As a result, the deposition material is smoothly discharged via the nozzle 23200 to the deposition target surface and formed thereon, and the deposition apparatus 20000 may have an effect of improving the actual deposition efficiency.

Also, (2) the quantities of heat distributed in a space of the crucible 23000 may be controlled to be uniform. By causing the heat distribution in the crucible to be uniform, the heat distribution allows deposition materials discharged from each nozzle formed in the crucible to move together toward the deposition target surface. Accordingly, the deposition material may be uniformly formed on the deposition target surface, and the actual deposition efficiency may be improved.

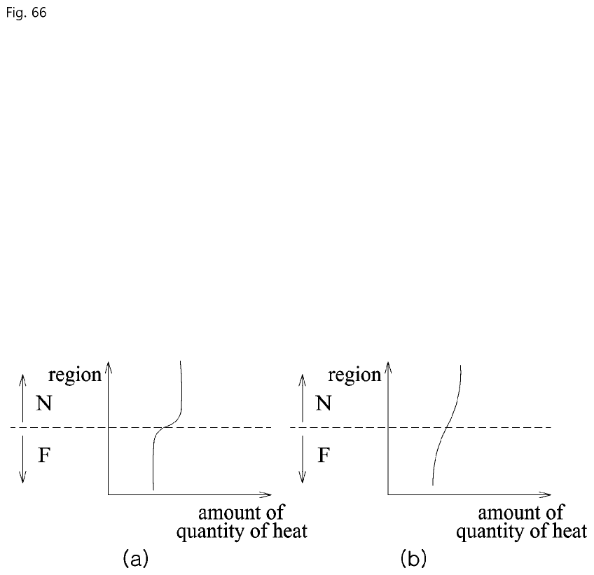

FIG. 66 is a schematic diagram illustrating a heat distribution in a crucible according to an embodiment of the present application.

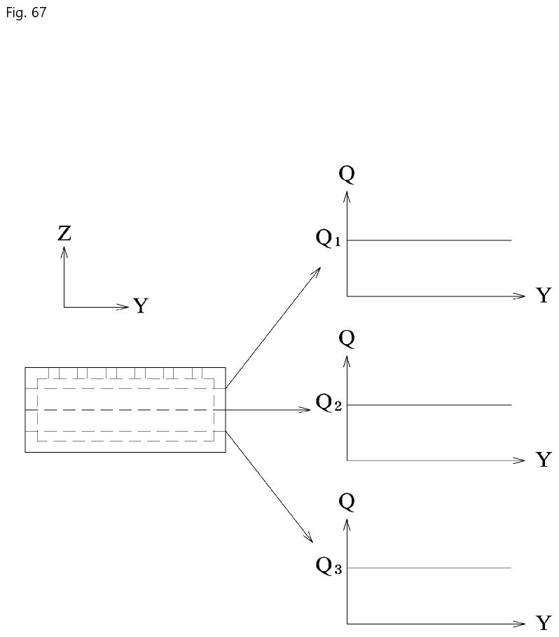

FIG. 67 is a schematic diagram illustrating a heat distribution in a crucible according to an embodiment of the present application.

For convenience of description, a region of a side surface relatively nearer to an upper surface of the crucible 23000 at which the nozzle 23200 is formed will be referred to as “N-region,” and a region relatively further from the upper surface will be referred to as “F-region.”

As described above, the heat distribution in the crucible 23000 to be achieved in the present invention may be a heat distribution in which a heat distribution of quantities of heat at the N-region of the side surface of the crucible 23000 is relatively higher than a heat distribution of quantities of heat at the F-region.

In the case of the heat distribution illustrated in FIG. 66(a), the deposition material may receive a sufficient quantity of heat from the N-region of the side surface of the crucible 23000 and smoothly pass through the nozzle 23200 to move to the deposition target surface.

In the case of the heat distribution illustrated in FIG. 66(b), when the deposition material moves toward the nozzle 23200 inside the crucible 23000, an effect in which the deposition material receives a quantity of heat with a natural heat distribution and smoothly moves to the deposition target surface may be achieved.

Controlling each configuration of the heating assembly so that a heat distribution in which a quantity of heat generated in the side surface of the crucible varies in the Z-axis direction is achieved has been described with reference to FIGS. 66(a) and (b). Also, implementing each configuration of the heating assembly so that, while the side surface of the crucible is divided in the Z-axis direction into the N-region near the nozzle and the F-region far from the nozzle, a heat distribution in which different quantities of heat are generated in each region is achieved has been described.

However, the heat distributions are merely examples, and the heat distribution in the crucible 23000 is not limited thereto. The configurations of the heating assembly may be implemented so that a heat distribution in which various quantities of heat are generated in different regions is achieved in the X-axis and Y-axis directions.

Also, the heat distribution in the crucible 23000 to be achieved in the present invention may be a heat distribution illustrated in FIG. 67 in which quantities of heat generated at the side surface of the crucible 23000 are uniform in the X-axis direction. In this case, the quantities of heat generated in the Z-axis direction may vary. The heat distribution in the crucible may satisfy Q1>>Q2>>Q3 so that a quantity of heat generated at the side surface of the crucible at which the nozzle is formed is large as described above. Also, the heat distribution in the crucible may be controlled to satisfy Q1≈Q2≈Q3 so that a quantity of heat generated in the Z-axis direction is uniform.

For the spatial distribution of quantities of heat provided to the deposition material accommodated in the inner space of the crucible 23000 to be controlled to a predetermined distribution as described above, a distribution of intensities of induction current induced to the outer wall 23100 of the crucible 23000 may be appropriately controlled. For example, when a horizontal direction and a vertical direction are defined with respect to one heating surface of four heating surfaces of the crucible 23000, the distribution of the induction current with respect to the one heating surface may be appropriately controlled in the horizontal direction or appropriately controlled in the vertical direction.

According to some embodiments of the present application, the crucible 23000 may be manufactured so that the induction current distribution is controlled using the shape of the outer wall 23100 of the crucible 23000.

According to some embodiments of the present application, the heating assembly may be manufactured so that the induction current distribution is controlled using a distance between the crucible 23000 and the coil 26000.

According to some embodiments of the present application, the heating assembly may be manufactured so that the induction current distribution is controlled using disposition or distribution of magnetic field focusing units.

According to some embodiments of the present application, the heating assembly may be manufactured so that the induction current distribution is controlled using independent control of the coil 26000.

Hereinafter, the above-described embodiments will be described in detail.

Meanwhile, although the nozzles 23200 are illustrated in the drawings and described below as being formed in an upward direction, this does not mean that the deposition apparatus is aupward type or downward type apparatus.

Also, although the crucible is illustrated in the drawings and described herein as having a rectangular parallelepiped shape in the longitudinal direction, this is merely an example as described above. The implementation examples described below may also apply to heating assemblies having crucibles of various other shapes.

2.1 Crucible

A method of controlling a heat distribution in a crucible 23000 in order to improve the actual deposition efficiency according to an embodiment of the present application may include a method of varying the shape of a crucible 23000. For example, the method may include a method of varying a distance between the side portion of the crucible 23000 and the coil 26000, a method of varying the thickness of the crucible 23000, and the like.

Hereinafter, embodiments in which a heat distribution in the crucible 23000 is controlled by varying the shape of the crucible 23000 will be described in detail.

2.1.1 Adjusting Distance Between Crucible and Coil

In order to control a heat distribution in a crucible 23000 according to an embodiment of the present application, a crucible 23000 may be formed to have various distance relationships with the coil 26000, which is the heating means 25000 formed.

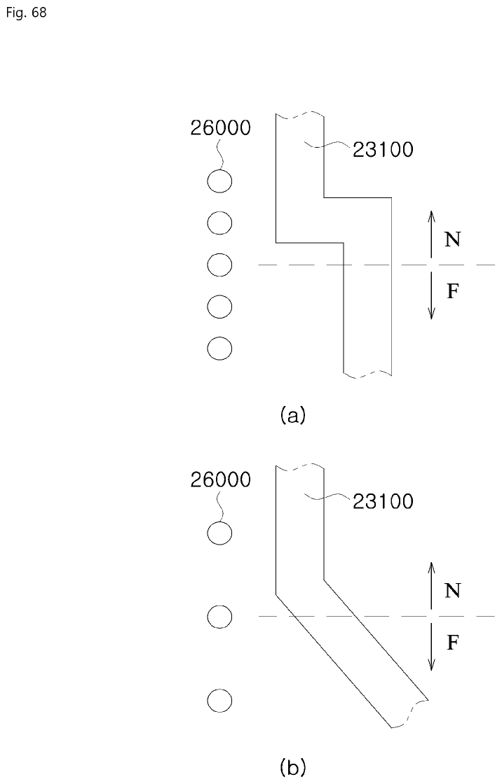

FIG. 68 is a cut side view illustrating an example in which the shape of a crucible is varied according to an embodiment of the present application.

Referring to FIGS. 68(a) and (b), the crucible 23000 may be implemented so that side portion regions included in the side surface of the crucible 23000 have different distance relationships with the coil 26000 disposed around the crucible 23000. Specifically, the crucible 23000 may be implemented so that a region of the side surface of the crucible 23000 relatively nearer to a lower surface of the crucible 23000 which is opposite to an upper surface thereof at which the nozzle 23200 is formed (hereinafter referred to as “F-region) is more depressed than a region of the side surface of the crucible 23000 relatively nearer to the upper portion of the crucible 23000 (hereinafter referred to as “N-region”).

Also, referring to FIG. 68(b), the region of the side surface of the crucible 23000 relatively nearer to the lower surface of the crucible 23000 may be formed to have a predetermined inclination. Specifically, the crucible 23000 may be formed so that the side surface of the crucible 23000 at the largest distance from the nozzle 23200 formed at the crucible 23000 may be at the largest distance from the coil 26000, and a side portion of the crucible 23000 relatively nearer to the nozzle 23200 is at a relatively smaller distance from the coil 26000 formed.

As described above according to an embodiment of the present application, the crucible 23000 may be controlled so that, when the crucible 23000 is implemented, a heat distribution is achieved in which a heat distribution of quantities of heat in the N-region of the side surface of the crucible 23000 is higher than a heat distribution of quantities of heat in the F-region thereof According to the above-described magnetic field formation attribute

$$( H ∝ k \cdot \frac{I}{r}$$

which is described above), an intensity change value of a dynamic magnetic field may be larger in the N-region of the side surface of the crucible 23000 that is implemented nearer to the coil 26000 than the F-region of the side surface of the crucible 23000. Therefore, the intensity of induction current formed in the crucible 23000 that corresponds to the intensity change value of the magnetic field is higher at the N-region than at the F-region. Therefore, as a result, referring to FIG. 66(a), as described above, the crucible 23000 may be controlled so that, when the crucible 23000 is implemented, a heat distribution is achieved in which a heat distribution of quantities of heat in the N-region is higher than a heat distribution of quantities of heat in the F-region.

Accordingly, the quantity of heat generated at an upper end portion of the crucible 23000 increases, and a temperature at the upper end portion may become relatively higher than that at a lower end portion of the crucible 23000. As a result, an effect of allowing the deposition material, which is discharged from the crucible 23000, to move at a high velocity with high activation energy toward the deposition target surface via the nozzle 23200 of the crucible 23000 may be achieved.

Meanwhile, referring to FIG. 66(b), when the outer wall 23100 of the crucible 23000 is implemented to have an inclination in the F-region of the side surface of the crucible 23000, since a distance between the crucible 23000 and the coil 26000 continuously changes, a heat distribution in the crucible may be controlled to be more natural in the F-region.

Accordingly, when the deposition material moves toward the nozzle 23200 in the crucible 23000, the deposition material may naturally receive an increased quantity of heat. Therefore, as compared with when the deposition material discontinuously receives a quantity of heat, an effect of allowing the deposition material to naturally move toward the deposition target surface may be achieved.

2.1.2 Adjusting Thickness of Outer Wall of Crucible

A heat distribution in a crucible 23000 may be controlled by implementing the outer wall 23100 of a crucible 23000 according to an embodiment of the present invention to have various thicknesses.

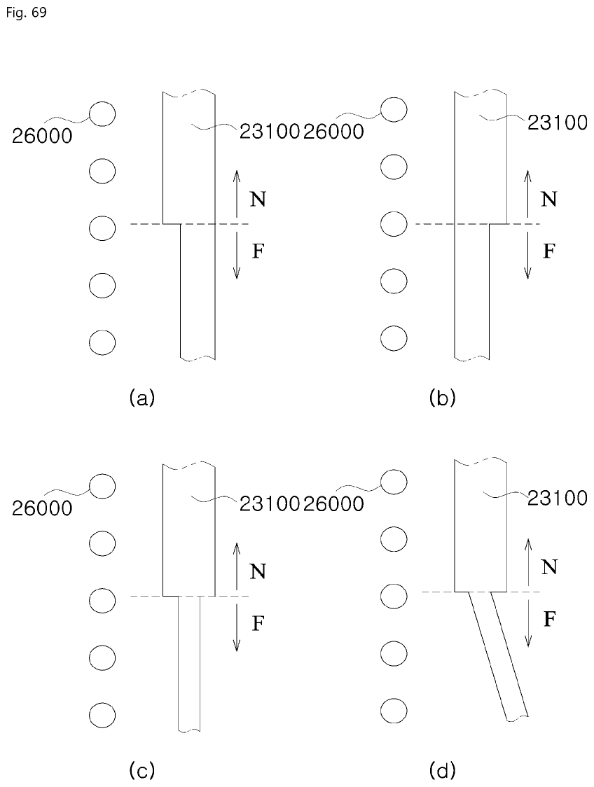

FIG. 69 is a cut side view illustrating examples in which a thickness of a crucible is varied according to an embodiment of the present application.

Referring to FIGS. 69(a) to (d), a crucible 13000 according to an embodiment of the present application may be formed so that regions having different thicknesses are present therein.

For example, in the crucible 23000, a portion relatively nearer to the nozzle 23200 formed in the crucible 23000 (N-region of the side surface of the crucible 23000) and a portion relatively further therefrom (F-region of the side surface of the crucible 23000) may be formed with different thicknesses. Specifically, the F-region of the side surface of the crucible 23000 may be formed with a smaller thickness. Referring to FIG. 69(a), an outer side of the F-region of the side surface of the crucible 23000 may be depressed toward the inner side of the crucible 23000 such that the thickness of the F-region is smaller than that of the N-region. Referring to FIG. 59(b), an inner wall of the F-region of the side surface of the crucible 23000 may be depressed toward the outer side of the crucible 23000 such that the thickness of the F-region is relatively smaller than the thickness of the N-region. Also, referring to FIG. 69(c), the F-region of the side surface of the crucible 23000 may have a form in which the above-described forms are combined, and the F-region may be depressed from the outer wall 23100 toward the inner side and from the inner wall toward the outer side such that the thickness of the F-region is relatively smaller than the thickness of the N-region.

As the thickness of the crucible 23000 is varied as described above, the distance between the crucible 23000 and the coil 26000 may also vary. Referring to FIGS. 69(a) and (c), since the F-region of the side surface of the crucible 23000 according to an embodiment of the present application is depressed toward the inner side from the outer side and has a relatively smaller thickness than the N-region, the distance between the crucible 23000 and the coil 26000 may also increase in the F-region.

As described above according to an embodiment of the present application, the crucible 23000 may be controlled so that, when the crucible 23000 is implemented, the heat distribution illustrated in FIG. 66(a) is achieved in which a heat distribution of quantities of heat in the N-region is higher than a heat distribution of quantities of heat in the F-region, due to the magnetic field formation attribute

$$( H ∝ k \cdot \frac{I}{r}$$

which is described above) or the induction current attribute (the thickness of the crucible 23000 which is described above). A dynamic magnetic field with a large magnetic field intensity change value may be formed in the N-region of the side surface of the crucible 23000. Corresponding to the magnetic field intensity change value, induction current with a relatively high intensity may flow in a side portion of the crucible 23000 with a relatively large thickness (the N-region). Since a quantity of heat generated in the N-region increases due to the induction current with a relatively high intensity, the heat distribution in the crucible 23000 may be controlled as described above.

Meanwhile, referring to FIG. 69(d), as an example in which the above-described shapes of the crucible 23000 are combined, a crucible 23000 according to an embodiment of the present application may have regions with different thicknesses that have a predetermined angle of inclination.

When the crucible 23000 is implemented as described above, the distance between the F-region of the side surface of the crucible 23000 and the coil 26000 may continuously change. Therefore, the crucible 23000 may be controlled so that a heat distribution is achieved in which a heat distribution of quantities of heat in the N-region is higher than a heat distribution of quantities of heat in the F-region while, as illustrated in FIG. 66(b), the heat distribution is more natural in the F-region.

When the crucible 23000 is implemented as described above, the quantity of heat supplied to the deposition material passing through the N-region increases, and the deposition material is smoothly guided to the deposition target surface such that it is possible to improve the actual deposition efficiency.

The method of controlling a heat distribution in the crucible 23000 by varying the implementation shape of the crucible 23000 according to an embodiment of the present application has been described above. A method of controlling a heat distribution in the crucible 23000 by varying a method of implementing the coil 26000 will be described below.

Meanwhile, although the crucible 23000 is illustrated in the drawings referenced above as being present at an inner portion of the closed-shape coil 26000 formed, embodiments may not be limited thereto.

2.2 Coil

A method of controlling a heat distribution in a crucible 23000 in order to improve the actual deposition efficiency according to an embodiment of the present application may include a method of varying the implementation of a coil 26000. For example, the method may include a method of adjusting the number of windings of the coil 26000, a method of varying the distance between the crucible 23000 and the coil 26000, and the like.

Embodiments in which the coil 26000 is implemented in various ways will be described below.

2.2.1 Adjusting Number of Windings of Coil

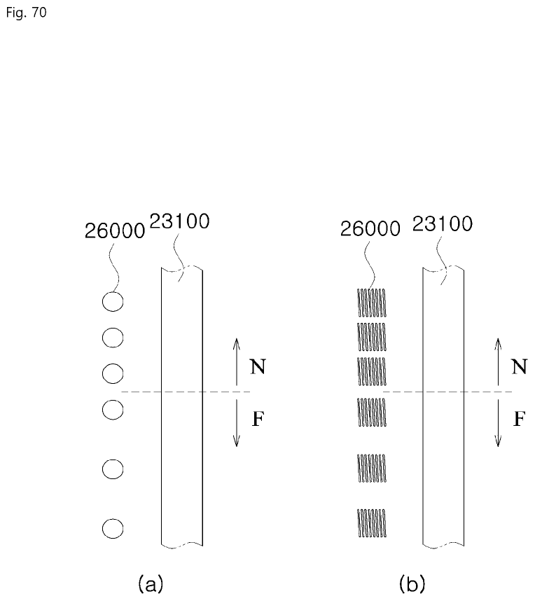

FIG. 70 is a view illustrating a coil formed at an outer side of a crucible according to an embodiment of the present application.

Referring to FIG. 70(a), the number of windings of a coil 26000 may be different in different regions of the side surface of a crucible 23000 according to an embodiment of the present application. For example, the number of windings of the closed-shape coil 26000 that affects the region of the side surface of the crucible 23000 (the N-region) present at a relatively smaller distance from the nozzle 23200 of the crucible 23000 may be larger than the number of windings of the coil 26000 formed at the region of the side surface of the crucible 23000 (the F-region) present at a relatively larger distance from the nozzle 23200.

Also, referring to FIG. 70(b), the crucible 23000 may be implemented so that upper portions or lower portions of a plurality of closed-shape coils 26000 are disposed in the N-region of the side surface of the crucible 23000. The number of windings of the coil 26000 disposed in the N-region may be larger than the number of windings of the coil 26000 disposed in the F-region.

When a coil 26000 is implemented as described above according to an embodiment of the present application, a crucible 23000 may be controlled so that a heat distribution is achieved in which a heat distribution of quantities of heat in the N-region is higher than a heat distribution of quantities of heat in the F-region. According to the above-described magnetic field formation attribute (H∝N which is described above), an intensity change value of a dynamic magnetic field formed in the N-region of the side surface of the crucible 23000 in which the number of windings of the coil 26000 is larger than that in the F-region may be larger than an intensity change value of a dynamic magnetic field formed in the F-region. As a result, an intensity of induction current formed in the crucible 23000 is also higher in the N-region than in the F-region. Therefore, as a result, referring to FIG. 66(a), as described above, the crucible 23000 may be controlled so that, when the crucible 23000 is implemented, a heat distribution is achieved in which a heat distribution of quantities of heat in the N-region is higher than a heat distribution of quantities of heat in the F-region.

Accordingly, the quantity of heat generated at the upper end portion of the crucible 23000 increases, and the temperature at the upper end portion may become relatively higher than that at the lower end portion of the crucible 23000. As a result, an effect of allowing the deposition material, which is discharged from the crucible 23000, to move at a high velocity with high activation energy toward the deposition target surface via the nozzle 23200 of the crucible 23000 may be achieved.

2.2.2 Adjusting Distance Between Coil and Crucible

A coil 26000 according to an embodiment of the present application may be implemented in various ways in terms of a positional relationship with the outer wall 23100 of a crucible 23000.

For example, a coil 26000 according to an embodiment of the present application may be disposed so that, as compared with a distance at which the coil 26000 is formed at one surface of a crucible 23000, a distance at which the coil 26000 is formed at another surface of the crucible 23000 is smaller.

FIG. 71 is a view illustrating a coil formed at an outer side of a crucible according to an embodiment of the present application.

Referring to FIG. 71(a), the coil 26000 may be disposed so that a distance between the crucible 23000 and the coil 26000 is different in each region of the side surface of the crucible 23000 according to an embodiment of the present application. For example, a distance between the crucible 23000 and the closed-shape coil 26000 that affects the region of the side surface of the crucible 23000 (the N-region) present at a relatively smaller distance from the nozzle 23200 of the crucible 23000 may be smaller than the distance between the crucible 23000 and the coil 26000 formed at the region of the side surface of the crucible 23000 (the F-region) present at a relatively larger distance from the nozzle 23200.

Also, referring to FIG. 71(b), for example, in an embodiment in which coils 26000 are densely disposed, the crucible 23000 may be formed so that upper portions or lower portions of a plurality of closed-shape coils 26000 are disposed at a relatively smaller distance from the N-region of the side surface of the crucible 23000 than from the F-region of the side surface of the crucible 23000.

When a coil 26000 is implemented as described above according to an embodiment of the present application, a crucible 23000 may be controlled so that a heat distribution is achieved in which a heat distribution of quantities of heat in the N-region is higher than a heat distribution of quantities of heat in the F-region. According to the above-described magnetic field formation attribute

$$( H ∝ k \cdot \frac{I}{r}$$

which is described above), an intensity change value of a magnetic field formed in the N-region of the side surface of the crucible 23000 which is at a relatively smaller distance from the coil 26000 than the F-region may be larger than an intensity change value of a magnetic field formed in the F-region. As a result, an intensity of induction current formed in the crucible 23000 is also higher in the N-region than in the F-region. Therefore, as a result, referring to FIG. 71(a), as described above, the crucible 23000 may be controlled so that, when the crucible 23000 is implemented, a heat distribution is achieved in which a heat distribution of quantities of heat in the N-region is higher than a heat distribution of quantities of heat in the F-region.

The method of controlling a heat distribution in the crucible 23000 by varying the implementation shape of the coil 26000 according to an embodiment of the present application has been described above. A method of controlling a heat distribution in the crucible 23000 by disposing the magnetic field focusing member 27000 in the heating assembly will be described below.

2.2.3 Separately Driven Coils

A coil 26000 implemented in a deposition apparatus 20000 according to an embodiment of the present application may be separately driven in order to control a heat distribution in a crucible 23000.

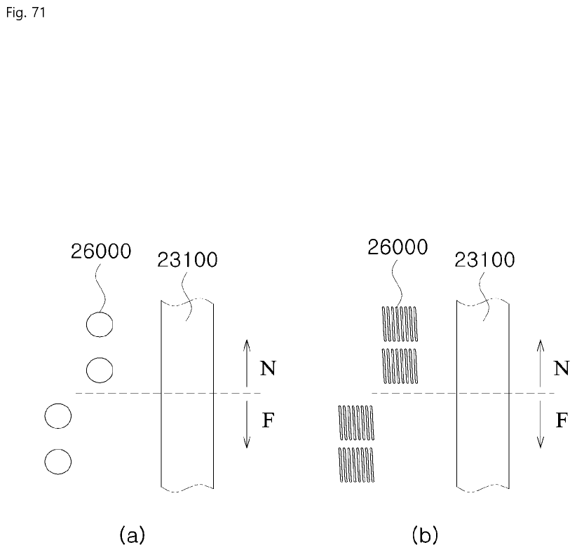

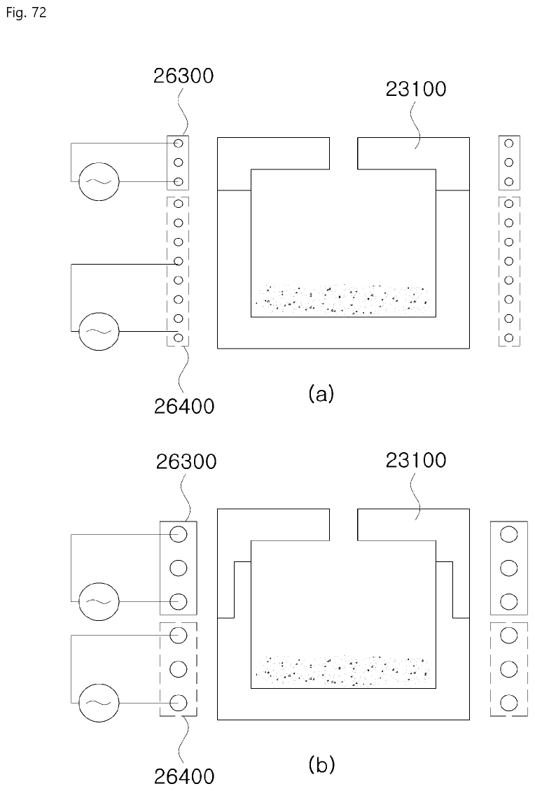

FIG. 72 is a conceptual diagram illustrating an example in which coils implemented in a deposition apparatus 20000 are separately driven according to an embodiment of the present application.

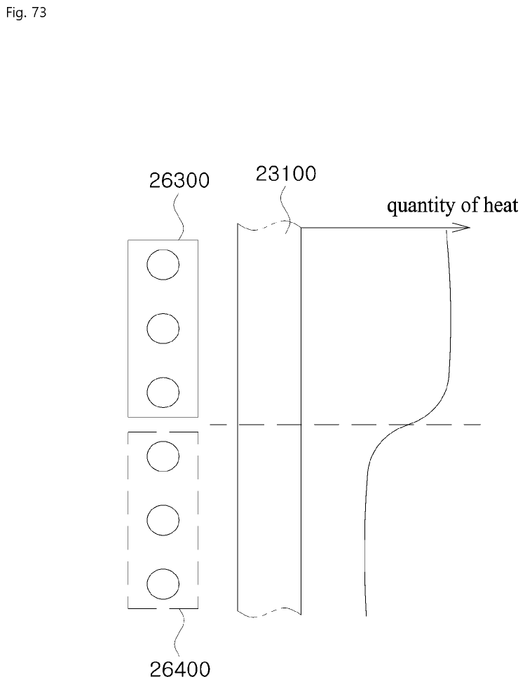

FIG. 73 is a view conceptually illustrating a heat distribution in a crucible according to an embodiment of the present invention.

Referring to FIG. 72, coils 26000 according to an embodiment of the present application may be separately driven. Attributes of variable power applied to separately driven coils 26300 and 26400 may be different from each other. The attributes of the variable power may include a frequency attribute, an intensity attribute, and the like of the power.

Powers having different attributes that are applied to the coils 26000 may be applied by power supply devices which are as many as the number of powers.

Alternatively, a plurality of powers whose attributes are different from each other that are applied to the coils 26300 and 26400 for each of the separately driven coils 26300 and 26400 may be applied by power supply devices, the number of which is less than the number of powers. When the power supply devices, the number of which is less than the number of plurality of powers, apply the powers, an electrical process of distributing output wires or the like may be required to supply powers having attributes different from each other to each of the separately driven coils 26300 and 26400.

Separately driven coils according to an embodiment of the present application may be disposed corresponding to various implementation examples of the crucible.

Referring to FIG. 72(a), the separately driven coils 26300 and 26400 may be disposed in different regions of the crucible. The crucible may be divided into an upper region and a lower region on the basis of a structure configured to separate the implemented crucible. A separately-driven first coil 26300 may be disposed in the upper region of the crucible, and a separately-driven second coil 26400 may be disposed in the lower region of the crucible. Accordingly, attributes of magnetic fields that affect each region of the crucible may vary, and thus quantities of heat generated in the upper region and the lower region of the crucible may be different from each other.

Also, as illustrated in FIG. 72(b), the structure configured to separate the crucible may be implemented in the crucible. As an implementation example of the structure configured to separate the crucible, the crucible may be divided into an upper region and a lower region on the basis of the structure configured to separate the crucible that is formed at an outer surface of the crucible. As described above, the separately driven coils 26300 and 26400 may be respectively disposed in the upper region and the lower region of the crucible.

In this case, in order to increase a quantity of heat generated in a portion of the crucible 23000 that is near the nozzle 23200, coils 26000 disposed in the above-described crucible 23000 according to an embodiment of the present application may be separately driven. A frequency and an intensity of power applied to the coil 26000 disposed at the portion near the nozzle 23200 may be relatively higher than those of power applied to the coil 26000 disposed at other portions of the crucible 23000.

When a frequency and/or an intensity of power applied to the separately-driven first coil 26300 are higher than a frequency and/or an intensity of power applied to the separately-driven second coil 26400, a quantity of heat generated in the crucible 23000 that corresponds to the separately-driven first coil 26300 may become higher than a quantity of heat generated in the crucible 23000 that corresponds to the separately-driven second coil 26400. According to the magnetic field formation attribute, the separately-driven second coil 26400 may form therearound a magnetic field with a relatively higher intensity than the separately-driven first coil 26300. Due to the magnetic field with a relatively higher intensity, the intensity of induction current formed at the portion of the crucible 23000 near the nozzle 23200 may increase. As a result, the separately driven coils 26300 and 26400 may be controlled so that the heat distribution in the crucible 23000 that is illustrated in FIG. 73 is achieved.

According to the heat distribution in the crucible 23000, the deposition material discharged via the nozzle 23200 of the crucible 23000 may receive a sufficient quantity of heat. Accordingly, the deposition material may be smoothly guided to a deposition target surface.

Meanwhile, when frequencies of powers applied to the coils 23000 vary as described above, magnetic fields generated around the separately driven coils 26300 and 26400 may interfere with, interrupt, and/or affect each other. Since the magnetic fields affect each other, the intensity of the magnetic field formed in the crucible 23000 may decrease. As a result, since the intensity of the induction current formed in the crucible 23000 decreases, an issue in that the efficiency of heating the crucible 23000 decreases may occur.

To address the issue that may occur, the separately driven coils 26300 and 26400 according to an embodiment of the present application may be implemented to not affect each other.

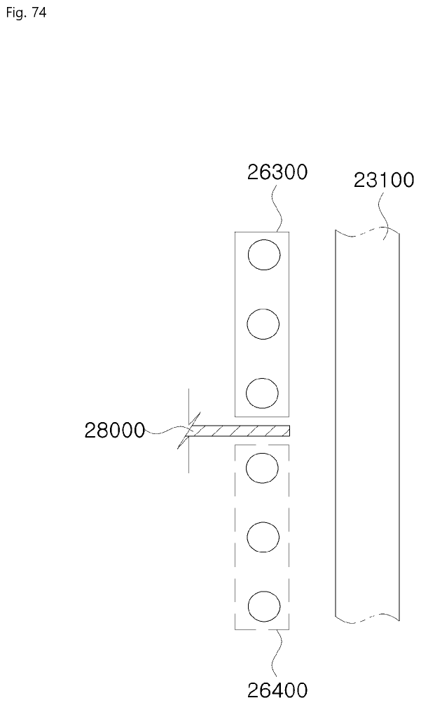

FIG. 74 is a view illustrating a ferrite inserted between coils according to an embodiment of the present application.

Referring to FIG. 74, in order to eliminate the mutual interference between separately driven coils 26300 and 26400 according to an embodiment of the present application, a ferrite 28000 may be inserted between the separately driven coils 26300 and 26400. Magnetic fields that interfere with each other may be magnetic fields formed between the separately driven coils 26300 and 26400. The magnetic fields formed between the separately driven coils 26300 and 26400 are formed toward other coils 26000 and affect magnetic fields formed in the other coils 26000. Therefore, by the ferrite 28000 being inserted between the coils 26300 and 26400, the magnetic fields formed between the separately driven coils may be focused to the ferrite 28000. By the magnetic fields being focused to the ferrite 28000, a kind of shielding effect in that a magnetic field cannot be formed toward another coil 26000 may occur. As a result, the inserted ferrite 28000 may eliminate the mutual interference between the separately driven coils 26300 and 26400.

2.3 Ferrite

A ferrite 28000 according to an embodiment of the present application may affect attributes of a magnetic field. For example, the ferrite 28000 may affect an intensity of a generated magnetic field. Specifically, the ferrite 28000 may affect an intensity of a magnetic field by affecting magnetic flux constituting the magnetic field, thereby increasing or decreasing the number of magnetic field lines passing through a predetermined area.

Hereinafter, as examples of a method of controlling a heat distribution in a crucible 23000 in order to improve the deposition efficiency according to an embodiment of the present application, various methods in which the ferrite 28000 is disposed in the heating assembly will be described. For example, the examples of the method may include a method of disposing the ferrite 28000 by varying the shape of the ferrite 28000, a method of disposing the ferrite 28000 at an inner portion of the outer wall 23100 of the crucible 23000, a method of applying the ferrite 28000, a method of disposing the ferrite 28000 in each region, a method of forming a window in the ferrite 28000, and the like.

Meanwhile, although the ferrite 28000 is described below and/or illustrated in the drawings as being implemented in a form having four sides, this is merely an example, and embodiments are not limited thereto. The ferrite 28000 may be implemented in various other forms such as a circular shape, an elliptical shape, or a spherical shape.

2.3.1 Varying Disposition of Ferrite

A ferrite 28000 according to an embodiment of the present application may be disposed in a crucible 23000 in various forms of surrounding a coil 26000.

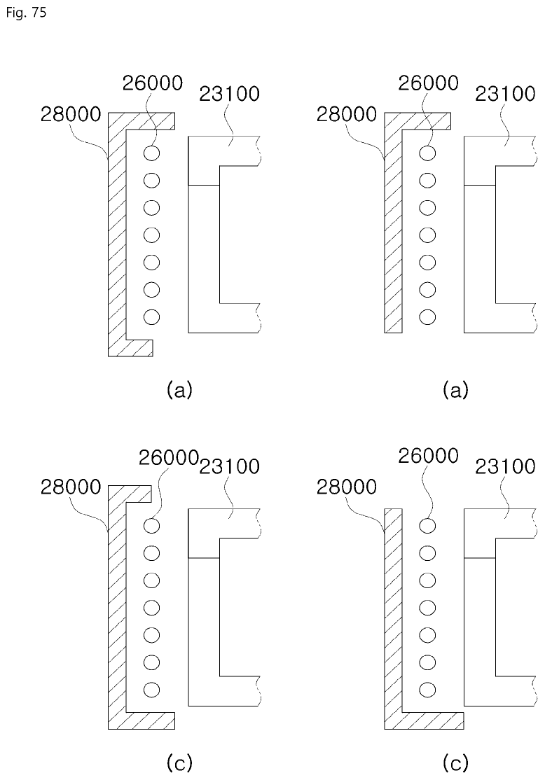

FIG. 75 is a view illustrating various shapes of a ferrite according to an embodiment of the present application.

Referring to FIGS. 75(a) to (d), a ferrite 28000 according to an embodiment of the present application may be disposed to partially cover conductive wires at an upper portion and/or a lower portion of a closed-shape coil 26000. For example, as illustrated in FIGS. 75(a) and (b), the ferrite 28000 may be disposed so that the lower portion of the closed-shape coil 26000 is partially open. For example, as illustrated in FIGS. 75(c) and (d), the ferrite 28000 may be disposed so that the upper portion of the closed-shape coil 26000 is partially open.

When a ferrite 28000 is disposed in a heating assembly as described above according to an embodiment of the present application, a heat distribution may be achieved in which a heat distribution of quantities of heat in the N-region or the F-region of the side surface of a crucible 23000 is relatively higher. According to the above-described magnetic field focusing attribute, an intensity of a magnetic field formed in the N-region or the F-region of the side surface of the implemented crucible 23000 may increase. As a result, the intensity of induction current formed in the crucible 23000 may also be relatively higher in the N-region or the F-region. Therefore, as a result, when the ferrite 28000 is disposed in the heating assembly as described above, the crucible 23000 may be controlled so that the above-described heat distribution is achieved by a quantity of heat generated in the N-region, which is relatively nearer to the nozzle 23200, being larger than a quantity of heat generated in the F-region or the quantity of heat generated in the F-region being larger than a quantity of heat generated in the N-region.

Accordingly, the heat distribution in the crucible 23000, in which a heat distribution of quantities of heat in the N-region is higher than a heat distribution of quantities of heat in the F-region as described above, may have an effect of allowing the deposition material to move at a high velocity with high activation energy toward the deposition target surface via the nozzle 23200 of the crucible 23000 may be achieved. Meanwhile, the heat distribution in which a heat distribution of quantities of heat in the F-region is higher than a heat distribution of quantities of heat in the N-region may have an effect of allowing the deposition material to receive a sufficient quantity of heat so that a phase-change critical time is decreased.

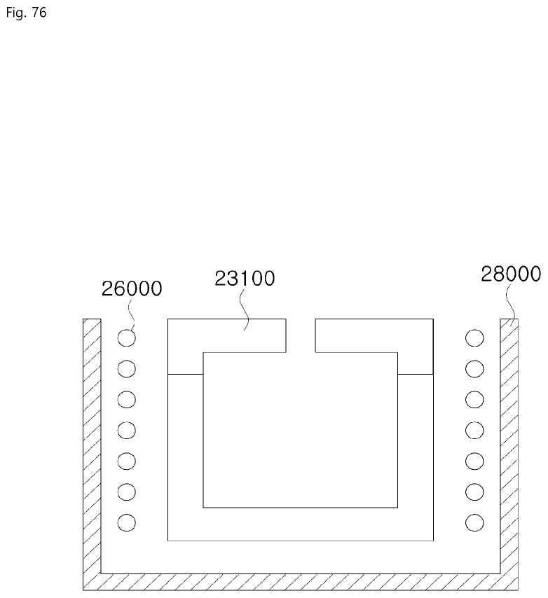

FIG. 76 is a view illustrating a ferrite disposed in a form of covering a lower surface of a crucible according to an embodiment of the present application.

Referring to FIG. 76, a ferrite 28000 according to an embodiment of the present invention may be disposed to completely cover a lower surface of a crucible 23000.

The above-described disposition of the ferrite 28000 may, according to the magnetic field focusing attribute of the ferrite 28000, allow a heat distribution to be achieved in which, in the crucible 23000, a quantity of heat at the lower surface of the crucible 23000 is relatively larger. Since the ferrite 28000 focuses a magnetic field to the lower surface of the crucible 23000, an intensity change value of a dynamic magnetic field generated at the lower surface of the crucible 23000 becomes relatively higher than that at other portions of the crucible 23000. In response to this, the intensity of induction current generated at the lower surface of the crucible 23000 also increases, and the quantity of heat generated according to the above-described induction heating attribute also increases. As a result, a heat distribution may be achieved in the crucible 23000 in which a quantity of heat generated at the lower surface of the crucible 23000 on which the deposition material is seated is relatively larger than quantities of heat generated at the upper surface and the side surface of the crucible 23000.

A ferrite 28000 according to an embodiment of the present application may be disposed so that a heat distribution is achieved in a crucible 23000 in which a heat distribution of quantities of heat in the N-region is higher than a heat distribution of quantities of heat in the F-region.

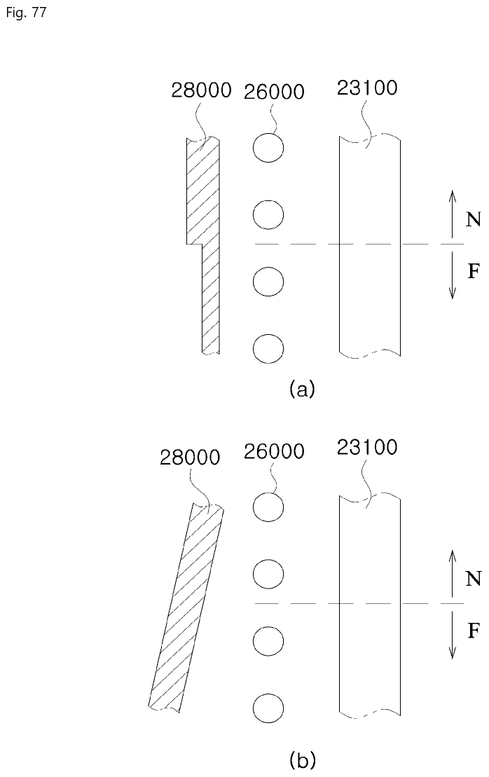

FIG. 77 is a view illustrating the shape of a ferrite according to an embodiment of the present application.

Referring to FIG. 77(a), a ferrite 28000 according to an embodiment of the present application may be disposed in a heating assembly by varying a thickness of the ferrite 28000. For example, the ferrite 28000 may be disposed so that the thickness of the ferrite 28000 is different for each region of the side surface of the crucible 23000. Specifically, the ferrite 28000 may be disposed so that a thickness of the ferrite 28000 disposed at a position corresponding to the N-region of the side surface of the crucible 23000 is relatively larger than a thickness of the ferrite 28000 disposed at a position corresponding to the F-region of the side surface of the crucible 23000.

The above-described disposition of the ferrite 28000 according to an embodiment of the present application may allow a heat distribution to be achieved in which, in the crucible 23000, a heat distribution of quantities of heat in the N-region is higher than a heat distribution of quantities of heat in the F-region. According to the magnetic field focusing attribute, an intensity change value of a magnetic field formed in the N-region may become relatively larger. Therefore, the intensity of induction current formed in the crucible 23000 also becomes relatively higher in the N-region than in the F-region. As a result, as illustrated in FIG. 76(a), according to the inducting heating attribute, a heat distribution may be achieved in which, in the crucible 23000, a heat distribution of quantities of heat is relatively higher in the N-region, in which the intensity of induction current is relatively higher, than in the F-region.

Meanwhile, although an example in which the thickness of the ferrite 28000 is varied in the case in which the ferrite 28000 is formed in a plate shape at an outer side of the closed-shape coil 26000 has been described above with reference to FIG. 77(a), the idea in that the thickness of the ferrite 28000 changes in a region of the crucible 23000 near the nozzle 23200 as described above may also apply to various other implementation examples such as an implementation example in which the ferrite 28000 is applied on the deposition apparatus 20000.

Also, referring to FIG. 77(b), the ferrite 28000 according to an embodiment of the present application may be disposed so that a distance between the crucible 23000 and the ferrite 28000 is different for each region of the side surface of the crucible 23000. For example, the ferrite 28000 may be disposed nearer to the N-region of the crucible 23000 than to the F-region thereof. For such disposition, the ferrite 28000 may be formed with a slight inclination so that the ferrite 28000 is near the portion of the crucible 23000 near the nozzle 23200 and is far from other portions of the crucible 23000.

Such disposition of the ferrite 28000 having the inclination according to an embodiment of the present application may allow a heat distribution to be achieved in which, in the crucible 23000, a heat distribution of quantities of heat is relatively higher in the N-region than in the F-region. According to the magnetic field focusing attribute of the ferrite 28000, the amount of magnetic flux focused to the N-region may become larger than the amount of magnetic flux focused to the F-region. Accordingly, an intensity change value of a magnetic field formed in the N-region may increase. As a result, the intensity of induction current formed in the crucible 23000 is also higher in the N-region than in the F-region. Therefore, referring to FIG. 62(a), when the crucible 23000 is implemented as described above, the crucible 23000 may be controlled so that a heat distribution is achieved in which a heat distribution of quantities of heat in the N-region, which is relatively nearer to the nozzle 23200, is higher than a heat distribution of quantities of heat in the F-region.

Although the ferrite 28000 has been described above as having a predetermined inclination so that the ferrite 28000 is formed relatively nearer to the portion of the crucible 23000 near the nozzle 23200, the shape of the ferrite 28000 is not limited, and the ferrite 28000 may have any shape other than that according to the embodiment in which the ferrite 28000 is implemented with an inclination as long as the shape allows the ferrite 28000 to be formed relatively nearer to the portion of the crucible 23000 near the nozzle 23200.

2.3.2 Varying Disposition of Ferrite at Inner Portion of Outer Wall of Crucible

A ferrite 28000 disposed in a form of being included inside a crucible 23000 according to an embodiment of the present application may be implemented so that the ferrite 28000 is disposed differently in each region inside the crucible 23000.

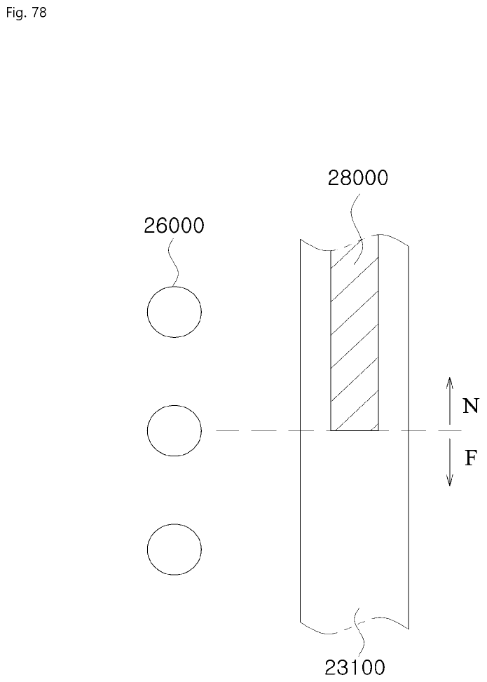

FIG. 78 is a cut side view illustrating a ferrite included in an outer wall of a crucible according to an embodiment of the present application.

Referring to FIG. 78, when a ferrite 28000 according to an embodiment of the present application is disposed in a form of being inserted into a side surface of a crucible 23000, the ferrite 28000 may be formed to be differently disposed in each region of the side surface. For example, the ferrite 28000 may be disposed in a form in which the ferrite 28000 is inserted into the N-region of the side surface of the crucible 23000.

As described above, a ferrite 28000 disposed according to an embodiment of the present invention may allow a heat distribution to be achieved in which, in a crucible 23000, a heat distribution of quantities of heat is higher in the N-region than in the F-region. According to the magnetic field focusing attribute of the ferrite 28000, the ferrite 28000 may cause an intensity change value of a dynamic magnetic field formed at the N-region of the side surface of the crucible 23000 to be relatively increased. As a result, the intensity of induction current formed in the crucible 23000 may also be higher in the N-region than in the F-region. Therefore, as illustrated in FIG. 66(a), the crucible 23000 may be controlled so that a heat distribution is achieved in which a quantity of heat in the N-region, which is relatively nearer to the nozzle 23200, is larger than a quantity of heat in the F-region.

2.3.3 Varying Application of Ferrite

When a ferrite is applied according to an embodiment of the present application, the ferrite may be implemented in a form in which the ferrite is applied only on a partial region of a heating assembly.

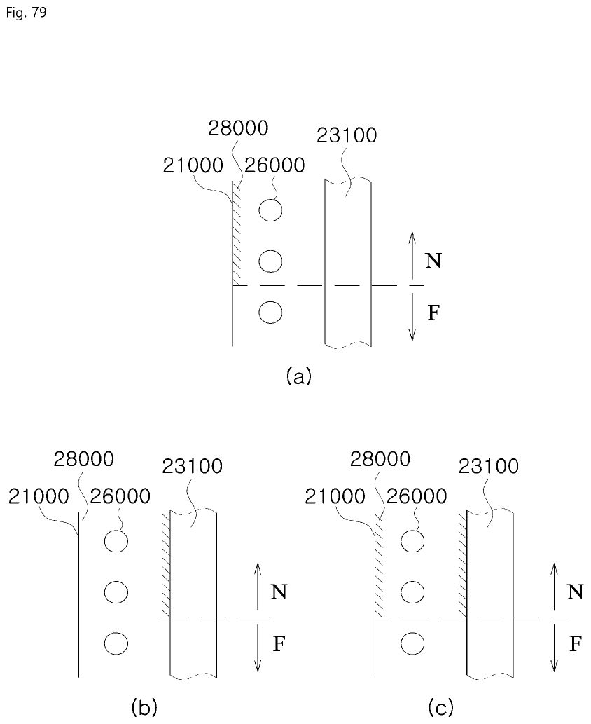

FIG. 79 is a view illustrating a ferrite 28000 applied to a heating assembly according to an embodiment of the present application.

Referring to FIGS. 79(a) to (c), in order to control a heat distribution in the crucible 23000, the ferrite 28000 may be applied only on partial regions of an inner surface of the outer wall of the housing 21000 and/or the outer wall 23100 of the crucible 23000. When the ferrite 28000 is applied only on the partial regions as described above, an intensity change value of a magnetic field may increase in partial regions of the crucible 23000 corresponding to positions at which the ferrite 28000 is applied. Accordingly, a distribution of intensities of current induced to the crucible 23000 may change, and by varying a quantity of heat generated in the crucible 23000, a heat distribution in the crucible 23000 may be controlled as illustrated in FIG. 66(a).

2.3.4 Disposing Ferrite Only in Partial Regions

A ferrite 28000 according to an embodiment of the present application may be disposed only in regions corresponding to portions of the side surface of a crucible 23000.

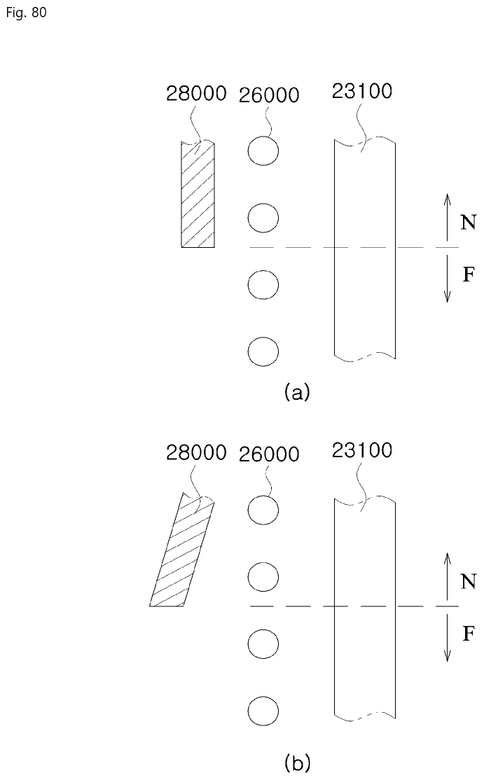

FIG. 80 is a view illustrating a state in which a ferrite is formed in a portion located near a nozzle of a crucible according to an embodiment of the present application.

Referring to FIG. 494(a), a ferrite 28000 according to an embodiment of the present application may be disposed only in a region corresponding to the N-region of the side surface of a crucible 23000. In this case, referring to FIG. 494(b), the ferrite 28000 may also be disposed with an inclination at a position corresponding to the N-region.

When the ferrite 28000 is disposed as described above, the ferrite 28000 may allow a heat distribution to be achieved in which, in the crucible 23000, a heat distribution of quantities of heat is higher in the N-region than in the F-region. According to the magnetic field focusing attribute of the ferrite 28000, the ferrite 28000 may cause an intensity change value of a magnetic field formed at the N-region to be relatively increased. Accordingly, the intensity of induction current formed in the crucible 23000 may also be higher in the N-region than in the F-region. Therefore, as a result, referring to FIG. 66, as described above, the crucible 23000 may be controlled so that, when the crucible 23000 is implemented, a heat distribution is achieved in which a heat distribution of quantities of heat is higher in the N-region, which is relatively nearer to the nozzle 23200, than in the F-region. Accordingly, as the heat distribution in the crucible 23000 is controlled as described above, it is possible to improve the actual deposition efficiency.

### 3. Combination Examples

As described above, in order to control a heat distribution in a crucible 23000 according to an embodiment of the present application, a heating assembly may have various implementation examples and/or disposition examples.

The technical ideas of the above-described implementation examples and/or disposition examples according to an embodiment of the present application may be combined and implemented in the heating assembly. In this case, the technical idea may refer to how the above-described examples will be specifically implemented and/or disposed. That is, the combinations of implementation examples may refer to applications of combinations of the implementation examples of the crucible 23000, the implementation examples of the coil 26000, and/or the disposition examples of the ferrite 28000, which are implemented in various shapes that have been described above in detail, to the heating assembly.

The various embodiments described above may be practiced in combination. Hereinafter, it will be described that the embodiments of the heating assembly design in the Z-axis direction which have been specifically described above can also apply in the X-axis and Y-axis directions.

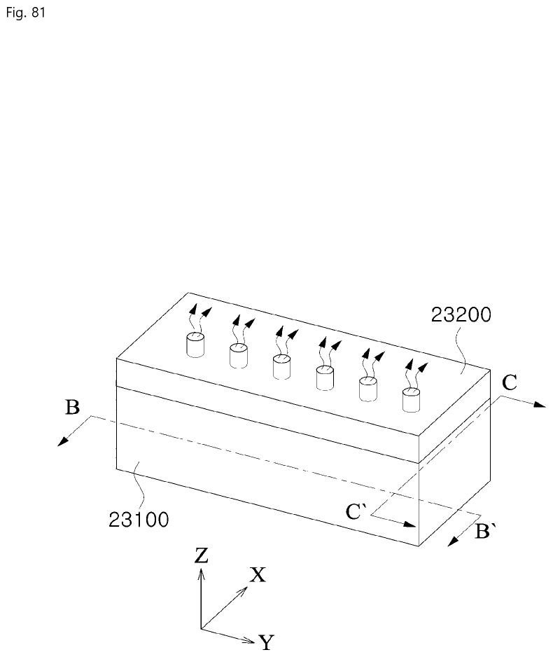

FIG. 81 is a view illustrating a side surface of a crucible according to an embodiment of the present application.

Referring to FIG. 81, the embodiments of the heating assembly in the Z-axis direction may also apply in the X-axis or Y-axis direction to implement the heating assembly.

For example, an example in which the heating assembly is implemented by applying the above-described embodiments in the Y-axis direction will be described.

A plurality of regions may be distinguished in the Y-axis direction of the crucible. The region of the crucible in the Y-axis direction may be divided into N regions, and each region will be referred to as a first Y-region to an Nth Y-region hereinafter.

For implementation of a heating assembly according to embodiments of the present application, the heating assembly may be designed on the basis of the various embodiments described above so that a heat distribution attribute is assigned to each of the first Y-region to the Nth Y-region.

Examples of the heating assembly design in the Y-axis direction will be described below.

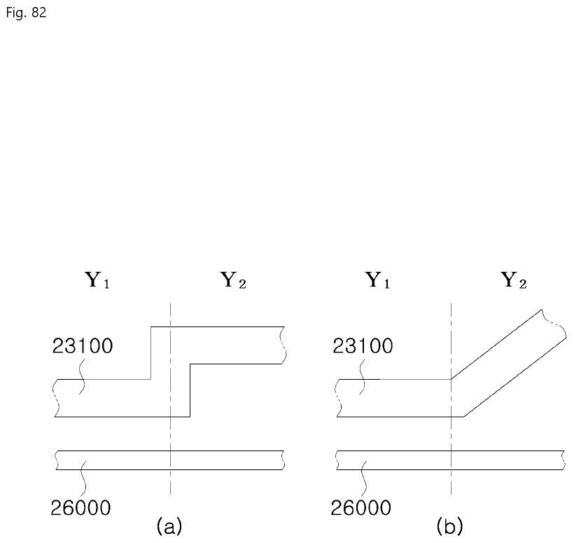

FIGS. 82 to 39 are views related to design of a heating assembly in the Y-axis direction according to an embodiment of the present application.

As illustrated in FIG. 82, the crucible may be implemented to protrude so that a side surface of the first Y-region is formed nearer to the coil than a side surface of the second Y-region.

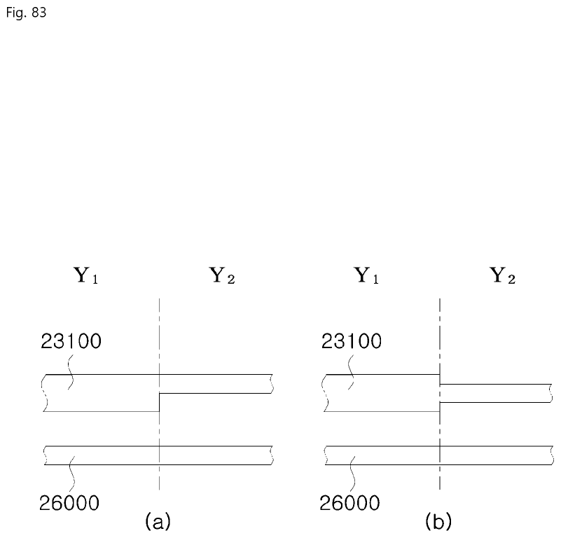

Also, referring to FIG. 83, the thickness of the outer wall of the crucible may be implemented to vary in the Y-direction so that the thickness of the outer wall of the crucible in the first Y-region is larger than the thickness of the outer wall of the crucible in the second Y-region. Also, as illustrated in FIG. 83(b), by the thickness of the outer wall of the crucible being adjusted in the second Y-region, a distance of the crucible from the coil may also increase.

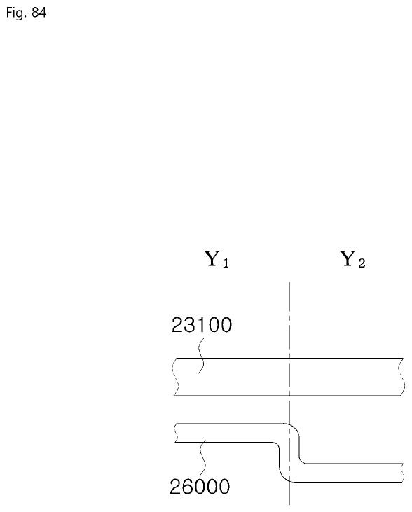

The coil disposed in the Y-direction may be disposed so that a distance thereof from the outer wall of the crucible varies. Referring to FIG. 84, the coil may be disposed near the outer wall of the crucible in the first Y-region and disposed far from the outer wall of the crucible in the second Y-region.

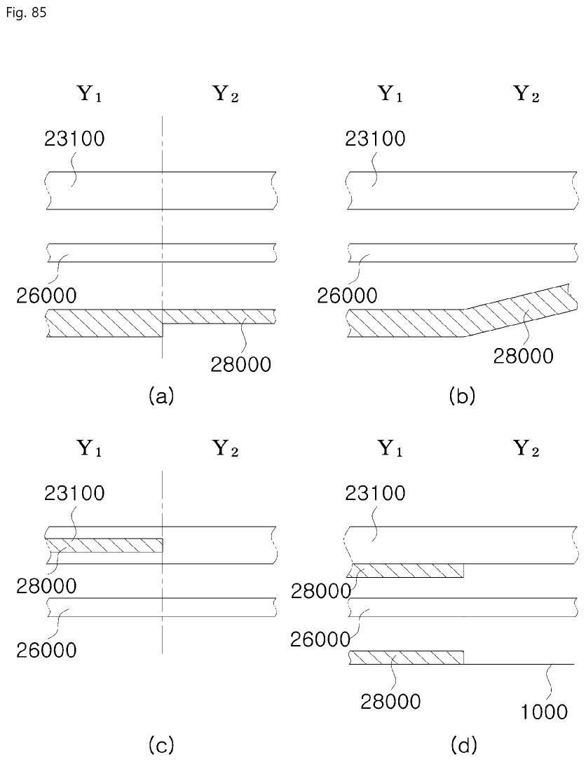

Referring to FIG. 85, the implementation example and/or disposition example of the ferrite disposed in the Y-direction may vary according to a Y-region. The thickness of the ferrite disposed in the first Y-region may be implemented to be larger than the thickness of the ferrite disposed in the second Y-region as illustrated in FIG. 85(a), and the inclination of the ferrite may be implemented so that the ferrite is relatively further from the first Y-region than the second Y-region as illustrated in FIG. 85(b). As illustrated in FIGS. 85(c) and (d), the ferrite may be applied or disposed only in a region corresponding to the first Y-region.

When the heating assembly is designed according to the above implementation examples, according to the above-described idea, an affected intensity change value of a magnetic field is larger at a side surface of the first Y-region of the crucible than at a side surface of the second Y-region of the crucible. Also, corresponding to the intensity change value of the magnetic field, an intensity of induction current may also be relatively higher at the side surface of the first Y-region of the crucible than in the second Y-region.

As a result, since a quantity of heat generated at the side surface of the first Y-region becomes relatively larger than a quantity of heat generated at the side surface of the second Y-region, the crucible may be designed so that a heat distribution is achieved in which a first heat distribution in the first Y-region is higher than a second heat distribution in the second Y-region.

Meanwhile, although the heating assembly has been described above as being designed in the Y-axis direction, embodiments are not limited thereto, and the above design examples may also be utilized in designing the heating assembly in a region in the X-axis direction.

Although examples in which the heating assembly is designed in order to control heat distributions only in two regions of the plurality of Y-regions have been described above, embodiments are not limited thereto, and the above-described design may be utilized in designing the heating assembly in order to control a heat distribution in each of the N regions. Meanwhile, the regions may be disposed at various intervals such as equal intervals, different intervals, or random intervals.

The designs described above may be applied solely or in combination to the heating assembly for each region along each axis. A deposition apparatus 20000 according to the present application may be implemented by combining all of the above-described implementation examples or implemented by combining only some of the above-described implementation examples in order to achieve an optimal implementation example.

Hereinafter, the heating assembly designed by combining the embodiments described above will be described.

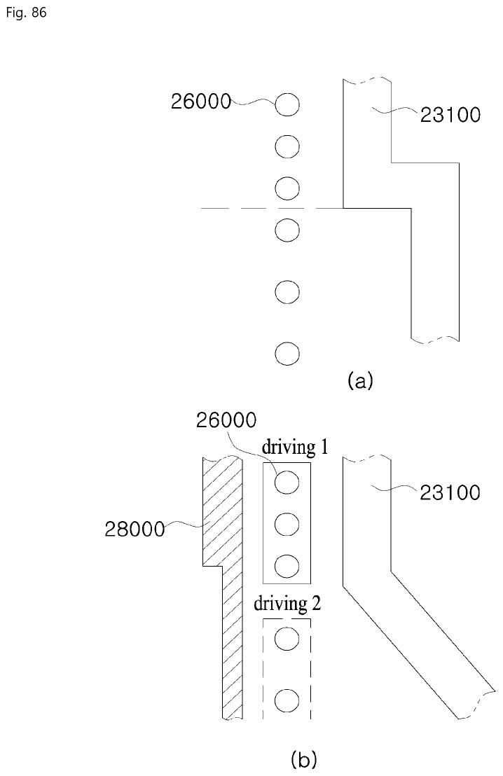

FIG. 86 is a view illustrating a heating assembly implemented by combining embodiments in the Z-direction of a crucible according to an embodiment of the present application.

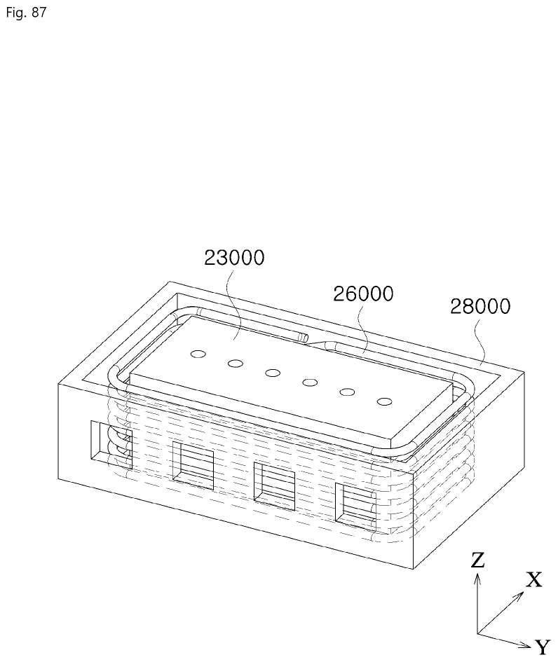

FIG. 87 is a view illustrating a heating assembly implemented by combining embodiments in the X-, Y-, and Z-directions of a crucible according to an embodiment of the present application.

Referring to FIG. 86(a), the implementation example of the crucible 23000 and the implementation example of the coil 26000 described above may be combined by being applied to a Z1 region and a Z2 region. In the Z1 region which is a region of the side surface of the crucible 23000 relatively nearer to the nozzle 23200, the side surface of the crucible 23000 may protrude further and the crucible 23000 may be implemented to be relatively nearer to the coil 26000 than in the Z2 region which is a region of the side surface of the crucible 23000 relatively further from the nozzle 23200. Also, the coil 26000 with a relatively larger number of windings may be disposed at a position corresponding to the Z1 region. Accordingly, a heat distribution may be achieved in which, in the crucible, a quantity of heat generated in the Z1 region, which is a region of the side surface of the crucible 23000 relatively nearer to the nozzle 23200, is relatively larger.

Also, as illustrated in FIG. 86(b), the deposition apparatus 20000 may be implemented by combining an implementation example in which separately driven coils 26000 are implemented, an implementation example of the coil 26000, and an implementation example of the ferrite 28000. The side surface of the crucible may further protrude in the Z1 region than in the Z2 region such that the crucible is implemented to be relatively nearer to the coil 26000 in the Z1 region than in the Z2 region, the coils 26000 disposed in the Z1 and Z2 regions of the crucible 23000 may be separately driven, and the ferrite 28000 may be disposed across the Z1 and Z2 regions so that the thickness of the ferrite 28000 disposed in the Y1 region is larger than the thickness of the ferrite 28000 disposed in the Z2 region. Accordingly, a heat distribution may be achieved in which, in the crucible, a heat distribution of quantities of heat generated in the Z1 region, which is a region of the side surface of the crucible 23000 relatively nearer to the nozzle 23200, is higher than a heat distribution of quantities of heat generated in the Z2 region.

Hereinafter, the heating assembly designed for each region in the three-dimensional X-, Y-, and Z-directions will be described.

When a crucible 23000 according to an embodiment of the present application is formed in a rectangular parallelepiped shape with the Y-direction as the longitudinal direction, a quantity of heat generated in the crucible 23000 may be larger at a side surface in the longitudinal direction. Therefore, quantities of heat generated in an X-axis region and a Y-axis region of the crucible 23000 may be different, and thus a heat distribution in the crucible may be a non-uniform heat distribution in which the heat distribution becomes lower at both ends in the longitudinal direction. Due to the non-uniform heat distribution in the crucible, the deposition material may be unable to receive a sufficient quantity of heat uniformly. Accordingly, since the deposition material is unable to move to be uniformly formed on a deposition target surface, the actual deposition efficiency may decrease as a result.

A ferrite 28000 according to an embodiment of the present application may be controlled so that a heat distribution in a crucible 23000 is uniform.

A heating assembly may be designed so that a ferrite 28000 according to an embodiment of the present application is disposed in partial regions of the Y-axis region and the Z-axis region and is disposed in the entire region of the X-axis region. As a result, as illustrated in FIG. 83, the ferrite 28000 having a window formed may be disposed at the side surface of the crucible in the longitudinal direction in the heating assembly.

An intensity change value of a magnetic field that affects a region of the side surface of the crucible 23000 in the Y-direction becomes smaller as compared with when the window is not formed. Accordingly, an intensity of induction current in the region of the side surface of the crucible 23000 in the Y-axis direction may be relatively decrease as compared with when the window is not formed. As a result, since a quantity of heat generated at the side surface of the crucible 23000 in the longitudinal direction decreases, as illustrated in FIG. 63, the crucible 23000 may be controlled so that a heat distribution in the side surface of the crucible 23000 in the Y-direction is uniform.

The heating assembly designed by combining various embodiments, which have been described above, has been described above. Meanwhile, implementation examples applied by being combined in order to implement a deposition apparatus 20000 according to an embodiment of the present application may be combined with various modifications thereof as long as the technical ideas of the implementation examples are not changed.

Various embodiments of implementing the deposition apparatus 20000 in order to improve the deposition success rate at which the deposition material is deposited on a deposition target surface, which is an important issue of the deposition apparatus 20000, has been described above.

### 4. Thermal Equilibrium Control in Crucible

Methods of controlling a heat distribution in each region of a crucible in the X-, Y-, and Z-directions by designing a heating assembly according to embodiments of the present application have been described above.

Hereinafter, a method of controlling thermal equilibrium in a crucible according to the present application will be described.

The thermal equilibrium in a crucible should be controlled so that a deposition material according to an embodiment of the present application is able to be smoothly discharged from the crucible.

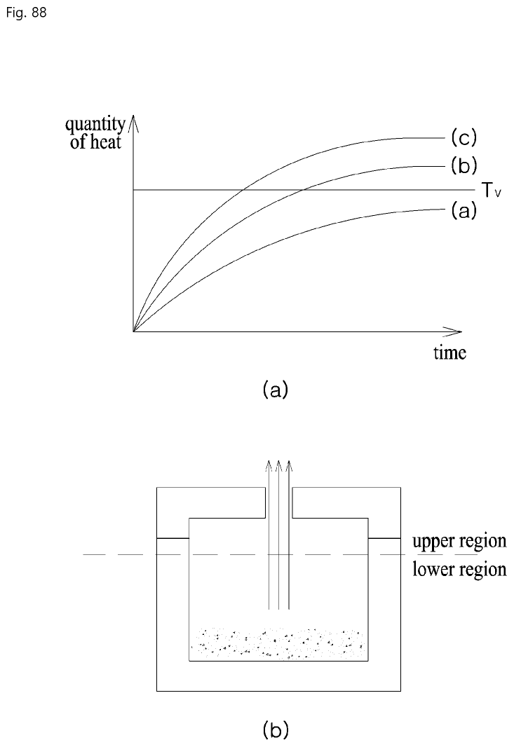

FIG. 88 is a view illustrating thermal equilibrium at a lower surface of a crucible according to an embodiment of the present application.

Referring to FIG. 88, the thermal equilibrium at the lower surface of the crucible may be achieved by quantities of heat having various numerical values. For example, as illustrated in (b) and (c), the thermal equilibrium may be achieved with a quantity of heat larger than a phase-change quantity of heat Tv of the deposition material, or, as illustrated in (a), the thermal equilibrium may be achieved with a quantity of heat smaller than the phase-change quantity of heat.

In this case, the thermal equilibrium may refer to a state in which a quantity of supplied heat and a quantity of discharged heat are equal and thus the same quantity of heat is maintained over time. Since, even in such a thermal equilibrium state, a quantity of heat is continuously supplied to the lower surface of the crucible and continuously discharged therefrom, the equilibrium state may also be referred to as, specifically, “dynamic equilibrium state.”

Referring back to FIG. 88, for the deposition material to change phase and move to the deposition target surface, the thermal equilibrium at the lower surface of the crucible should be achieved with a quantity of heat larger than the phase-change quantity of heat Tv of the deposition material as illustrated in (b) and (c). By the quantity of heat larger than the phase-change quantity of heat being continuously supplied to the deposition material, the deposition material may continuously change phase and move. Accordingly, since the phase-changed deposition material continuously moves to the deposition target surface, deposition may continuously occur.

However, when the thermal equilibrium at the lower surface of the crucible is achieved as illustrated in (c), a quantity of heat that is excessively larger than the phase-change quantity of heat Tv of the deposition material may be supplied. Accordingly, (1) since the deposition material is discharged with an excessively high velocity from the nozzle of the crucible, the deposition material which is deposited on the deposition target surface may not have sufficient time for being properly seated on the deposition target surface, and thus uniformity of deposition may be decreased. Also, (2) wasted energy may be increased. Therefore, when the thermal equilibrium is achieved as illustrated in (c), it can be said that the thermal equilibrium at the lower surface of the crucible has been controlled inefficiently.

That is, in the thermal equilibrium at the lower surface of the crucible, as illustrated in (b), the supplied quantity of heat may be moderately larger than the phase-change quantity of heat Tv of the deposition material. According to the above-described thermal equilibrium control in the crucible, the deposition material may be deposited on the deposition target surface by efficiently providing energy to the deposition material.

Meanwhile, in controlling the thermal equilibrium in the crucible, thermal equilibrium at an upper surface of the crucible may be a problem. This is because, in an operation of the deposition apparatus, the most controversial issue is whether the deposition material, which received a sufficient quantity of heat from the upper portion of the crucible, is able to be smoothly discharged from the nozzle of the crucible and be deposited on the deposition target surface.

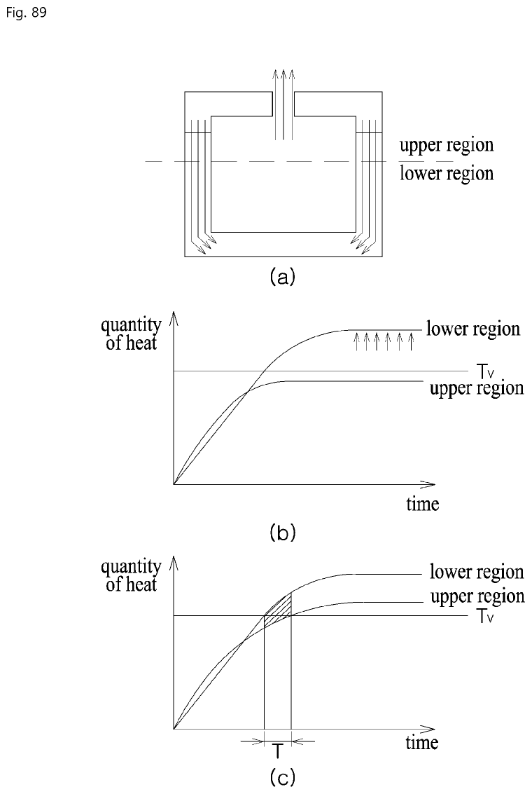

FIG. 89 is a view illustrating thermal equilibriums at an upper portion and a lower portion of a crucible according to an embodiment of the present application.

Referring to FIG. 89(a), regarding a quantity of heat generated at the upper portion of the crucible, (1) as the crucible is continuously heated, a large quantity of heat generated at the upper portion of the crucible may be conducted to the lower portion of the crucible and accumulated thereon, and (2) the large quantity of heat generated at the upper portion of the crucible may be discharged via the nozzle.

Since heat conduction continuously occurs at the lower portion and the upper portion of the crucible as described above, thermal equilibrium may be achieved at the lower portion and the upper portion of the crucible, with quantities of heat having different numerical values.

As illustrated in FIG. 89(b), a quantity of heat for achieving thermal equilibrium at the lower portion of the crucible may be larger than a quantity of heat for achieving thermal equilibrium that has been appropriately designed previously. Conversely, a quantity of heat for achieving thermal equilibrium at the upper portion of the crucible may be a quantity of heat smaller than the phase-change quantity of heat Tv of the deposition material since the quantity of heat at the upper portion is discharged to another space.

That is, even when the deposition material change phase and move by receiving a sufficient quantity of heat from the lower surface of the crucible, the deposition material may solidify or liquefy at the upper portion of the crucible at which the quantity of heat is smaller than the phase-change quantity of heat Tv of the deposition material. The solidified or liquefied deposition material may block the nozzle formed at the upper portion of the crucible, and thus a problem may occur in which the deposition material is unable to be smoothly discharged via the nozzle of the crucible.

Alternatively, as illustrated in FIG. 89(c), the above-described issue in that the nozzle of the crucible is blocked may occur even when thermal equilibrium is achieved in the crucible.

That is, although the deposition material at the lower surface of the crucible is able to change phase and move by receiving a sufficient quantity of heat in a T-section, since the quantity of heat at the upper surface of the crucible is smaller than the phase-change quantity of heat Tv of the deposition material, the deposition material may solidify or liquefy at the upper portion of the crucible. Accordingly, the problem occurs in which the solidified or liquefied deposition material blocks the nozzle formed at the upper portion of the crucible.

According to the thermal equilibrium achieved in the crucible, a configuration for addressing the problem in which the nozzle of the crucible is blocked may be disposed in the heating assembly.

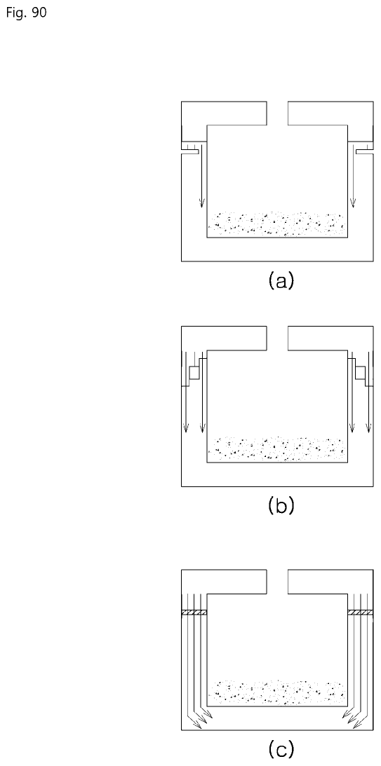

FIG. 90 is a view illustrating a heating assembly in which a heat conduction suppressing element is formed according to an embodiment of the present application.

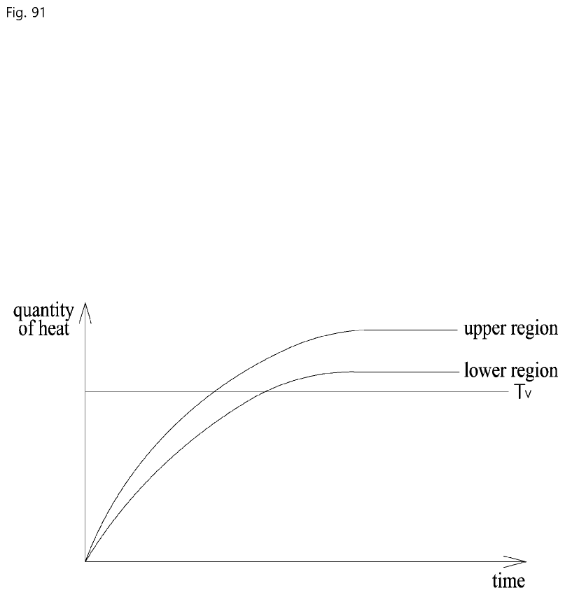

FIG. 91 is a graph showing thermal equilibrium controlled according to an embodiment of the present application.

In order to address the problem in which the nozzle is blocked, a heat conduction suppressing element may be formed in the heating assembly according to an embodiment of the present application.

A heat conduction suppressing configuration according to an embodiment of the present application may decrease a quantity of heat transferred from the upper portion of a crucible to the lower portion thereof. Accordingly, the quantity of heat accumulated on the lower surface of the crucible may decrease.

Referring to FIG. 90, a heat conduction suppressing configuration according to an embodiment of the present application may include a slit, a shielding space, an insulating material, or the like. However, the heat conduction suppressing configuration is not limited thereto and may include various other configurations.

Hereinafter, the heat conduction suppressing configuration will be described in detail.

Referring to FIG. 90(a), a slit may be formed in the outer wall of the crucible according to an embodiment of the present application.

By the slit being formed, a quantity of heat generated at the upper portion of the crucible is not able to be conducted to the lower portion of the crucible via the slit and is only able to be transferred to the lower portion of the crucible by radiation. That is, a path via which the heat accumulated on the upper portion of the crucible may be transferred to the lower portion of the crucible is reduced. As the heat transferred to the lower portion of the crucible is reduced, the quantity of heat accumulated on the lower portion of the crucible may be reduced.

The slit formed in the crucible may be preferably formed at a position in the vicinity of the structure configured to separate the crucible. However, embodiments are not limited thereto, and the slit may be formed in various other positions in the crucible. That is, a plurality of slits may be formed, and although, preferably, the plurality of slits may be formed in the vicinity of the structure configured to separate the crucible, the plurality of slits may be disposed in the outer wall of the crucible at various intervals.

Also, the slit may be designed in various shapes. Although a quadrangular slit may be formed in the crucible as illustrated, embodiments are not limited thereto, and the slit may be formed in various other shapes such as triangular, circular, elliptical, and rhombic. Also, the slit may be implemented to have various widths and lengths.

Also, the slit may be designed in various directions. The slit may be formed in a direction from an inner side of the crucible toward the outer surface thereof or may be formed in a direction from the outer side of the crucible to the inner surface thereof. Also, although the slit may be formed at an angle perpendicular to a surface of the crucible as illustrated, embodiments are not limited thereto, and the slit may be formed at various other angles.

Also, referring to FIG. 90(b), a shielding space may be formed at an inner portion of the outer wall of the crucible according to an embodiment of the present application. A quantity of heat generated at the upper portion of the crucible is not able to be conducted to the lower portion of the crucible via the shielding space formed at the inner portion of the outer wall of the crucible and is only able to be transferred to the lower portion of the crucible by radiation. That is, a path via which the heat accumulated on the upper portion of the crucible may be transferred to the lower portion of the crucible is reduced. As the heat transferred to the lower portion of the crucible is reduced, the quantity of heat accumulated on the lower portion of the crucible may be reduced.

The shielding space may be implemented in various forms at the inner portion of the outer wall of the crucible.

For example, referring to FIG. 90(b), the structure configured to separate the crucible may be formed so that, while the upper portion and the lower portion of the crucible fit well together when the upper portion and the lower portion of the crucible are assembled, the shielding space may be formed at the inner portion of the outer wall of the crucible. Accordingly, the shielding space may be implemented at the inner portion of the outer wall of the crucible.

The shielding space may be designed in various shapes. Although a quadrangular empty space may be formed in the crucible as illustrated, embodiments are not limited thereto, and the shielding space may be formed in various other shapes such as triangular, circular, elliptical, and rhombic.

The shielding space may be implemented to have various widths and lengths.

A plurality of shielding spaces may be present. The plurality of shielding spaces may be properly disposed at the inner portion of the outer wall of the crucible.

The above implementation example is merely an example, and embodiments are not limited thereto. Various other implementation examples in which the shielding space is formed at the outer wall of the crucible may be present.

Also, referring to FIG. 90(c), an insulating member capable of decreasing heat conduction may be formed at the outer wall of a crucible according to an embodiment of the present application. The insulating member decreases a quantity of heat conducted from the upper portion of the crucible to the lower portion thereof by being disposed therebetween. As the quantity of heat conducted to the lower portion of the crucible is reduced, the quantity of heat accumulated on the lower portion of the crucible may be reduced.

The insulating member may be implemented in various forms at the outer wall of the crucible.

For example, referring to FIG. 90(c), the insulating member may be implemented in a form of being inserted between the upper portion of the crucible and the lower portion of the crucible, wherein the crucible is divided on the basis of the structure configured to separate the crucible.

The insulating member may be designed in various shapes. Although a quadrangular member may be implemented in a form of being inserted into the outer wall of the crucible as illustrated, embodiments are not limited thereto, and the insulating member may be formed in various other shapes such as triangular, circular, elliptical, and rhombic.

A material with low heat conductivity may be selected as a material of the insulating member, and a material having a melting point that allows the insulating member to function without melting even when a quantity of heat in the heating assembly is at a high temperature may be selected.

The insulating member may be implemented to have various widths and lengths.

A plurality of insulating members may be present. The plurality of insulating members may be properly disposed at the inner portion of the outer wall of the crucible.

The above implementation example is merely an example, and embodiments are not limited thereto. Various other implementation examples in which the insulating member is formed at the outer wall of the crucible may be present.

Also, a heating assembly may be designed so that a quantity of heat is smoothly discharged from the lower surface of a crucible according to an embodiment of the present application.

For example, a heat dissipating fin, a heat dissipating body, or the like may be disposed at the lower surface of the crucible, or a heat dissipating paint may be applied on the lower surface of the crucible. Since the heat dissipating means have extremely high heat conductivity, a quantity of heat may be smoothly conducted. That is, a quantity of heat accumulated at the lower portion of the crucible may be smoothly discharged via the heat dissipating means implemented at the lower surface of the crucible.

Alternatively, by implementing the lower surface of the crucible to have a large surface area, a quantity of heat may be smoothly discharged via the large surface area. For example, the lower surface of the crucible may be implemented to be rough. The lower surface of the crucible that is implemented to be rough may have a larger surface area than the lower surface of the crucible that is implemented to be smooth.

Alternatively, a black body may be formed at an inner surface of the housing that is opposite to the lower surface of the crucible. The black body may absorb radiant heat radiated therearound. Accordingly, radiant heat discharged from the lower portion of the crucible via the inner surface of the housing may be absorbed into the black body, and the radiant heat may be smoothly discharged via the housing.

Meanwhile, the present invention is not limited to the embodiments described above, and there may be a method of controlling a heat distribution in a crucible over time. The method may be practiced by combining the embodiments described above related to maintaining a heat distribution in the crucible.

Referring to FIG. 91, thermal equilibrium in each region of the crucible may be appropriately controlled according to the above-described implementation example in which a quantity of heat conducted to the lower surface and the upper surface of the crucible is controlled. At the lower portion of the crucible, thermal equilibrium may be achieved with a quantity of heat that is moderately larger than the phase-change quantity of heat Tv of the deposition material. Meanwhile, at the upper portion of the crucible, thermal equilibrium may be achieved with a quantity of heat that is not only larger than the phase-change quantity of heat Tv of the deposition material but also larger than the quantity of heat at the lower portion of the crucible.

Accordingly, the crucible according to an embodiment of the present application is controlled so that, not only the effect of addressing the above-mentioned problem in which the nozzle is blocked is achieved, but also thermal equilibrium is achieved that allows the deposition material to be smoothly discharged from the upper portion of the crucible.

A transformer or a current transformer of a deposition apparatus 20000 and a disposition example of the transformer or the current transformer will be described below.

### 5. Transformer or Current Transformer

Hereinafter, a transformer or a current transformer according to an embodiment of the present application will be described.

In order to drive a coil of a heating assembly according to the present application, the transformer and/or the current transformer may output a high-frequency voltage or current whose direction and intensity change over time. For example, the transformer and/or the current transformer may receive direct-current (DC) power, convert the received DC power to AC power, and apply the AC power to the coil.

That is, the transformer or the current transformer is an apparatus that is essential in order to drive the deposition apparatus according to the present application. Hereinafter, for convenience of description, the transformer, among the transformer and the current transformer, will be described as an example.

Also, current of power applied to the coil by the transformer according to some embodiments of the present application may have a relatively higher value than current of DC power provided to the transformer. That is, power output by the transformer may have extremely high current. This is to heat the crucible by increasing a current value of induction current in the deposition apparatus according to embodiments of the present application that utilizes induction current whose direction and intensity suddenly changes over time at the outer wall of the crucible.

A conductive wire (hereinafter referred to as “output wire 29120”) for applying the high current to the coil and a conductive wire (hereinafter referred to as “input wire 29110”) for supplying external DT power to the transformer may be included in the transformer. Power output from the transformer may be provided to the coil via the output wire 29120. The DC power input to the transformer may be provided to the transformer via the input wire 29110.

However, as described above, high current may flow through the output wire 29120. In this case, the high current may combine with a resistance component of the output wire 29120 and generate heat such that a high heat emission phenomenon occurs in the output wire 29120. Accordingly, when the output wire 29120 is used in the deposition apparatus according to an embodiment of the present application, a problem may occur in which the output wire 29120 is broken. Therefore, in order to prevent the breakage of the output wire 29120, there is a need to suppress the high heat emission phenomenon, and accordingly, the output wire 29120 of the transformer is formed to have a large thickness in order to further decrease a resistance value of the output wire 29120.

Conversely, there is no need to further decrease a resistance value of the input wire 29110. Accordingly, since there is no need to implement the input wire 29110 to have a large thickness with high cost, the input wire 29110 is formed to be relatively thinner than the output wire 29120.

The transformer may be disposed in various spaces. This will be described below.

A space according to an embodiment of the present application may be separated into an outer space and an inner space. The outer space is a space differentiated from the inner space in which the deposition target surface, the heating assembly, and the like of the present application are disposed. The inner space may have a vacuum environment attribute. This is to eliminate impurities that may affect the process in which the phase-changed deposition material is deposited on the deposition target surface using the heating assembly. Since there is no need to eliminate impurities from the outer space differentiated from the inner space, unlike the inner space, the outer space is a space having a general air pressure attribute.

In the inner space of the deposition apparatus, the heating assembly and/or the deposition target surface move relative to each other such that a deposition operation is performed. The deposition operation refers to an operational process in which the deposition material is formed on the deposition target surface. The relative movement may refer to movement of the deposition target surface while the heating assembly is fixed, simultaneous movement of the deposition target surface and the heating assembly while velocities thereof are different, or movement of the heating assembly while the deposition target surface is fixed.

A transformer according to an embodiment of the present application may be disposed to be fixed to the outer space of a deposition apparatus.

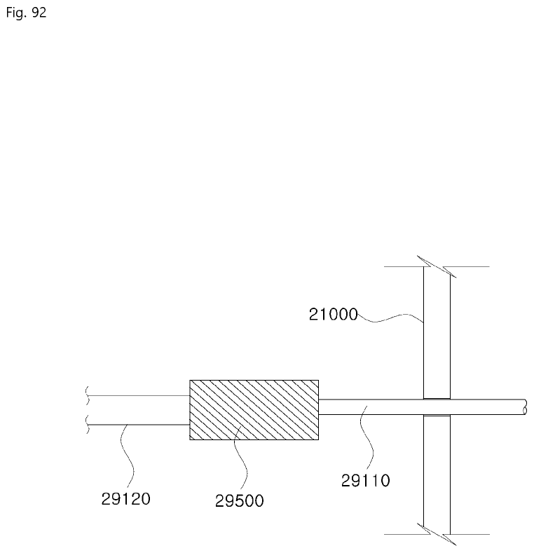

FIG. 92 is a view illustrating a transformer, an input wire, and an output wire in an outer space according to an embodiment of the present application.

Referring to FIG. 92, the transformer fixed to the outer space may supply AC power to a coil implemented in the inner space. The transformer fixed to the outer space may receive DC power generated by a DC power generation source included in the outer space via the input wire 29110. The transformer may convert the received DC power to high-frequency AC power. The high-frequency AC power is applied to the output wire 29120 of the transformer, and the output wire 29120 is connected to the coil via a partition or an outer wall that differentiates the outer space and the inner space from each other. In this way, the transformer provides the AC power to the coil via the output wire 29120.

When the transformer is disposed to be fixed to the outer space as described above, some problems may occur.

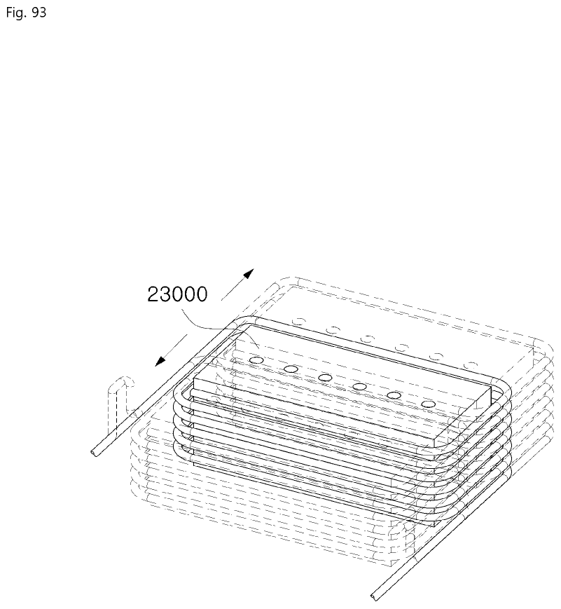

FIG. 93 is a view illustrating a moving heating assembly according to an embodiment of the present application.

Referring to FIG. 93, when the transformer is disposed in the outer space, a problem in that the output wire 29120 of the transformer is broken may also occur. Since the transformer is disposed to be fixed to the outer space, when the heating assembly moves as the deposition operation is performed in the inner space, the output wire 29120 connected to the coil may be deformed such as being extended or bent. The above-described output wire 29120 may wear out due to being continuously deformed due to the continued deposition operation. Due to the output wire 29120 being worn out continuously, a problem in that the output wire 29120 is broken may occur.

Meanwhile, to address the problem, a mover configured to move the transformer disposed in the outer space corresponding to movement of the heating assembly may be disposed in the outer space.

Even when the mover is disposed, referring back to FIG. 92, when the transformer is disposed in the outer space, a problem in that it is difficult to implement the outer wall that differentiates the inner space and the outer space from each other may also occur.

A structure in which the output wire 29120 may be disposed from the outer space to the inner space should be formed at the outer wall that differentiates the inner space and the outer space from each other. Meanwhile, the structure of the outer wall should be formed to be able to maintain the vacuum environment attribute of the inner space. However, the structure should be formed as a through-structure in which the outer space and the inner space communicate with each other and the output wire 29120 may be disposed from the outer space to the inner space, and the size of the through-structure should be selected in consideration of the output wire 29120 which is formed to have a large thickness as described above. Therefore, it is very difficult to implement in the outer wall a structure through which the output wire 29120 may pass while the vacuum environment attribute of the inner space is not eliminated.

Accordingly, implementing the mover, another driver for driving the mover, a power generation source, and through-structures of the outer wall in the outer space may cause a cost problem.

In order to address the above-described problems, some embodiments of the present application disclose a deposition apparatus in which: 1) a transformer according to the present application is disposed inside the deposition apparatus; and 2) a relative positional relationship between the crucible (heating assembly) and the transformer may be fixed.

In order to implement a deposition apparatus according to an embodiment of the present application, the transformer may be fixed to one side of the heating assembly.

In this way, the transformer may be installed inside the deposition apparatus together with the heating assembly while the positional relationship between the heating assembly and the transformer may be fixed. That is, when the heating assembly moves inside the deposition apparatus in order to implement movements of the heating assembly and the deposition target surface relative to each other, the transformer may move together according to the movement of the heating assembly.

In this case, since the positions of the transformer and the heating assembly relative to each other are fixed, the problem in which the output wire 29120 is broken does not occur anymore.

Meanwhile, since there is no problem in terms of implementing power, which is for supplying DC power to the transformer, to have flexibility, the problem in which the input wire 29110 is broken due to movement of the transformer may hardly occur.

However, in another embodiment, it is not essential for the transformer and the heating assembly to be fixed to each other.

For example, the deposition apparatus may be implemented so that, as the heating assembly moves, the transformer also moves in synchronization with the heating assembly. To this end, a driver which is separately configured from a driver for movement of the heating assembly may be included in the deposition apparatus.

Also, even when the transformer is disposed in the inner space, some little problems may remain. When the transformer is disposed in a high-vacuum environment, which is the inner space, a problem in that the vacuum environment is damaged due to the movement of the transformer may occur.

Therefore, according to some other embodiments of the present application, the deposition apparatus may further include a separate vacuum box for allowing the transformer to be disposed in the inner space.

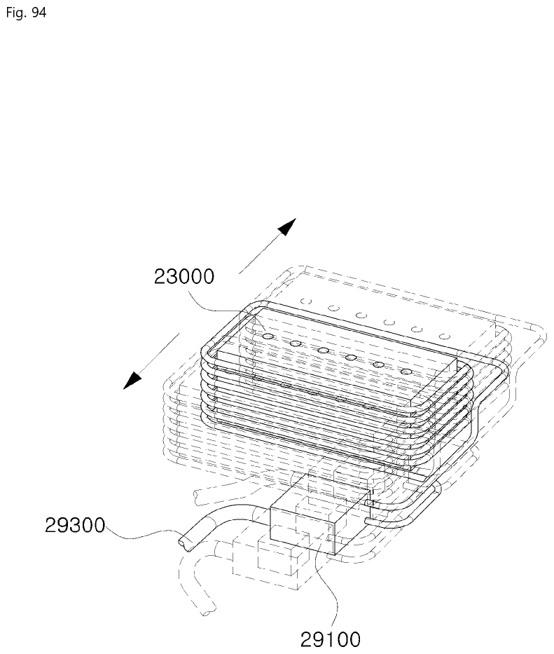

FIG. 94 is a view illustrating a transformer, a vacuum box, and a heating assembly according to an embodiment of the present application.

Referring to FIG. 94, the vacuum box in which the transformer is disposed may receive power from the driver included and move in synchronization with the heating assembly. Accordingly, since an inner space of the box is separated from the vacuum environment, the problem in that the coil is broken when the heating assembly moves as well as the problem in that the vacuum environment is damaged when the transformer moves may not occur.

Hereinafter, a deposition apparatus according to some embodiments of the present application will be described in detail below.

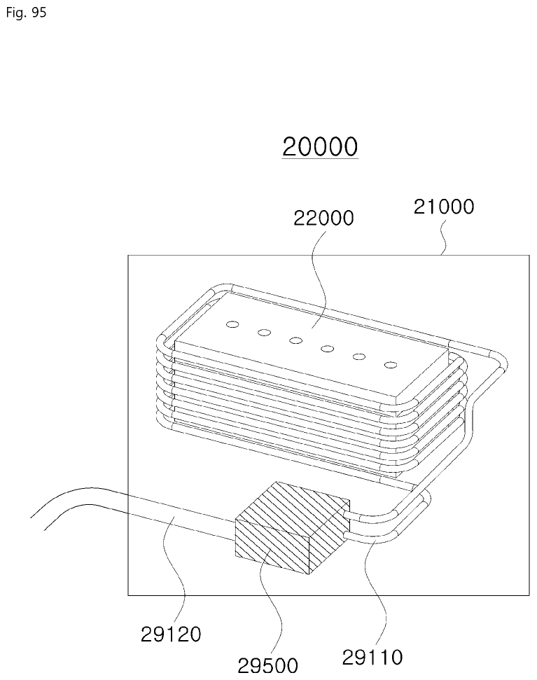

FIG. 95 is a view illustrating a deposition apparatus according to an embodiment of the present application.

Referring to FIG. 95, a deposition apparatus according to some embodiments of the present application may include a housing, a heating assembly, and a transformer.

The housing may provide a space in which configurations related to deposition may be implemented. The heating assembly, the transformer, and the like may be disposed in the space. The housing may have an outer wall with high sealability that is capable of differentiating an inner space and an outer space of the housing from each other. Thus, the housing may maintain the inner space of the housing in a high-vacuum environment state.

The heating assembly may heat the deposition material placed in the crucible by using a coil, thereby changing a phase of the deposition material and allowing the phase-changed deposition material to be deposited on the deposition target surface.

Although the heating assembly may have the above-described configuration of the heating assembly according to some embodiments of the present application, the heating assembly is not necessarily limited thereto.

The transformer may be disposed inside the housing and, as described above, may be fixed to one side of the heating assembly.

The transformer will be described in more detail below.

Since the output wire 29120 disposed in the transformer has a high stiffness as described above, the output wire 29120 may be connected to the coil while having a fixed shape. Also, since the transformer is present by being fixed to one side of the heating assembly, the output wire 29120 may also be connected to the coil such that, even while deposition of the deposition material is performed, the fixed shape is hardly changed.

Meanwhile, the input wire 29110 disposed in the transformer may extend from the transformer and be connected to external DC power in the outer space via a through-hole formed in the outer wall of the housing.

Since, as described above, relatively less power is applied to the input wire 29110 than to the output wire 29120, for the input wire 29110, it is not required to separately implement a thick conductive wire as for the output wire 29120, and a conductive wire disposed inside the housing may serve as the input wire 29110. Even when a conductive wire disposed in advance is not used as the input wire 29110, the input wire 29110 having a small thickness may be disposed in the housing via a small through-hole formed in advance. Also, corresponding to the case in which the transformer moves, the input wire 29110 may be implemented to have a long length.

In addition to being relatively easier to implement than the output wire 29120, since the input wire 29110 is more flexible than the output wire 29120 as described above, unlike the output wire 29120, the input wire 29110 may hardly cause a problem due to breakage.

Also, when the heating assembly moves by the driver as described above, the driver may be separately disposed, and the transformer may also move with the positional relationship of being fixed to one side of the heating assembly.

Hereinafter, a deposition apparatus including a vacuum box according to an embodiment of the present application will be described.

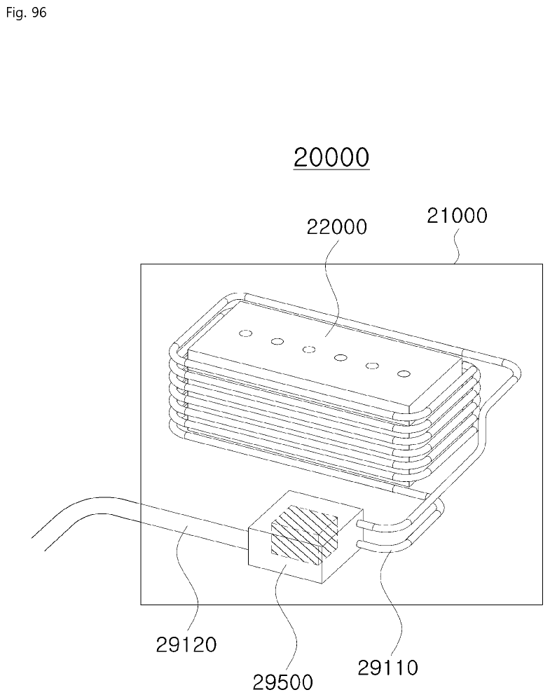

FIG. 96 is a view illustrating a deposition apparatus according to an embodiment of the present application.

Referring to FIG. 96, a deposition apparatus according to some embodiments of the present application may include a housing, a heating assembly, a transformer, and a vacuum box.

Repeated description of configurations which have been described above will be omitted.

The vacuum box may form a space therein. The space of the vacuum box may be a vacuum environment which is the same as the environment inside the housing.

Also, the vacuum box may include various kinds of drivers, conductive wires, connecting members, and the like.

According to the present embodiment, since movement of the transformer may destroy the vacuum environment inside the housing, the transformer may be disposed in the inner space of the vacuum box.

The output wire 29120 of the transformer may extend via a through-hole implemented in the vacuum box and be connected to the coil.

Alternatively, a bellows or an arm-shaped connecting member having a high stiffness corresponding to the stiffness of the output wire 29120 may be included in the vacuum box and allow the output wire 29120 to be connected to the coil. The connecting member may be implemented in a form of extending to the coil, and the output wire 29120 may be connected to the coil via the connecting member.

The input wire 29110 of the transformer may also extend via the through-hole implemented in the vacuum box and be connected to external power via the through-hole in the outer wall of the housing.

Alternatively, a connecting member having a low stiffness corresponding to the stiffness of the input wire 29110 may be disposed in the vacuum box and allow the input wire 29110 to communicate with the outer space. The connecting member may be implemented to have a sufficient length corresponding to movement of the heating assembly. Also, the connecting member may flexibly move due to having a low stiffness.

Therefore, the connecting member disposed in the vacuum box may have an inner space formed therein for a conductive wire to be disposed therein.

Also, when the heating assembly moves by the driver as described above, the driver may be separately disposed, and the vacuum box including the transformer may also move with the positional relationship of being fixed to one side of the heating assembly.

Meanwhile, a problem in that the transformer malfunctions in a high-vacuum environment may sometimes occur. Therefore, the inner space of the box may have a predetermined air pressure attribute. In this case, the air pressure environment may be an atmospheric pressure environment.

A deposition apparatus according to an embodiment of the present application may further include an atmospheric pressure box, in addition to the above-described elements.

The atmospheric pressure box may be separated from an external environment, and generally, an internal environment of the atmospheric pressure box may be created as an air pressure environment at an atmospheric pressure level.

Also, the atmospheric pressure box may include the above-described connecting members, drivers, conductive wires, and the like.

In addition, the atmospheric pressure box may further include various kinds of sensors in order to sense an environmental change.

The transformer of the deposition apparatus according to the above embodiment may be disposed inside the atmospheric pressure box disposed in the deposition apparatus. By disposing the transformer according to the present application in the atmospheric pressure box, all the problems mentioned herein may be addressed. That is, such a disposition example of the transformer may be stated as the most efficient and ideal disposition example of the transformer according to the present application.

Specifically, when the transformer is disposed in the atmospheric pressure box: (1) there is no need to form the complex through-structure, driver, power generating unit, and the like at the outer wall; (2) since the driver or the like is already implemented, there is no need to include a separate configuration for moving the transformer; (3) since the atmospheric pressure box may have the positional relationship of being fixed to one side of the heating assembly and is movable, the problem in that the output wire 19120 is broken does not occur; (4) since, in the inner portion of the atmospheric pressure box, the transformer moves while being separated from the vacuum environment, the vacuum environment is not damaged; and (5) since the transformer operates while a predetermined air pressure environment is applied to the atmospheric pressure box, the problem in that the transformer malfunctions does not occur.

In the above-described heating assembly according to the present invention, steps constituting each embodiment are not essential, and thus, each embodiment may selectively include the above-described steps. Also, the steps constituting each embodiment do not necessarily have to be performed in the described order, and a step described later may also be performed prior to a step described earlier. Also, any one step may be repeatedly performed while each step is performed.

The configurations and features of the present invention have been described above on the basis of embodiments according to the present invention, but the present invention is not limited thereto, and it should be apparent to those of ordinary skill in the art to which the present invention pertains that various changes or modifications are possible within the idea and scope of the present invention and that such changes or modifications also belong to the scope of the attached claims.

1. A heating assembly for a deposition apparatus, the heating assembly comprising:
a crucible having a space, which is configured to accommodate a deposition material, formed therein and in which at least one or more nozzles configured to guide the deposition material to an outside are implemented;
a coil disposed at an outer side of the crucible and around which a dynamic magnetic field is formed according to a flow of a coil current corresponding to high-frequency power applied to the coil; and
a magnetic field focusing member disposed around the coil,
wherein an induction current is formed at an outer wall of the crucible due to the dynamic magnetic field, and the crucible is heated by heat generated based on the induction current and an electrical resistance element of the crucible, and
the dynamic magnetic field formed around the coil is focused by the magnetic field focusing member so that a quantity of heat generated in the crucible increases.

2. The heating assembly of claim 1, wherein the induction current formed at the outer wall of the crucible changes over time.

3. The heating assembly of claim 1, wherein:
a change amount of a magnetic flux density of the dynamic magnetic field increases due to the magnetic field focusing member; and
the increased quantity of heat in the crucible is increased based on the increased change amount.

4. The heating assembly of claim 1, wherein:
an electric charge per unit time of the induction current increases due to the magnetic field focusing member; and
the increased quantity of heat in the crucible is increased based on the increased electric charge per unit time.

5. The heating assembly of claim 1, wherein:
a change amount of a magnetic flux density of the dynamic magnetic field and an electric charge per unit time of the induction current increase due to the magnetic field focusing member; and
the increased quantity of heat in the crucible is increased based on the increased change amount and the electric charge per unit time.

6. The heating assembly of claim 1, wherein the nozzle implemented in the crucible has a form of protruding toward an outside of the crucible.

7. The heating assembly of claim 1, wherein the coil is disposed so that a first coil and a second coil included in the coil are present at an outer side of the outer wall of the crucible.

8. The heating assembly of claim 1, wherein the heating assembly is disposed inside a housing of the deposition apparatus.

9. The heating assembly of claim 8, wherein the magnetic field focusing member is disposed in a space between the coil and an inner wall of the housing.

10. The heating assembly of claim 9, wherein the magnetic field focusing member is implemented in a form of being applied.

11. The heating assembly of claim 1, wherein:
the magnetic field focusing member is implemented in a plate shape,
the magnetic field focusing member includes a first region and a second region, and
a thickness of the first region of the magnetic field focusing member is greater than a thickness of the second region thereof.

12. The heating assembly of claim 1, wherein a degree at which the dynamic magnetic field is focused changes based on a thickness of the magnetic field focusing member.

13. The heating assembly of claim 1, wherein:
a region of the magnetic field focusing member includes a first region and a second region, and
a distance between the first region and the housing is greater than a distance between the second region and the housing.

14. The heating assembly of claim 1, wherein:
the magnetic field focusing member includes a first region and a second region, and
the first region and the second region are regions perpendicular to each other.

15. The heating assembly of claim 1, wherein:
a heat conduction suppressing element is implemented at the outer wall of the crucible, and
a quantity of heat transferred from an upper portion of the outer wall of the crucible to a lower portion thereof decreases due to the heat conduction suppressing element.

16. A deposition apparatus comprising:
a housing having a space formed therein;
a crucible having a space, which is configured to accommodate a deposition material, formed therein and in which at least one or more nozzles configured to guide the deposition material to an outside are implemented;
a coil disposed at an outer side of the crucible and around which a dynamic magnetic field is formed according to a flow of a coil current corresponding to high-frequency power applied to the coil; and
a magnetic field focusing member disposed around the coil,
wherein the crucible, the coil, and the magnetic field focusing member are disposed in an inner space of the housing,
an induction current is formed at an outer wall of the crucible due to the dynamic magnetic field, and the crucible is heated by heat generated based on the induction current and an electrical resistance element of the crucible, and
the dynamic magnetic field formed around the coil is focused by the magnetic field focusing member so that a quantity of heat generated in the crucible increases.
